(19) United States
(12) Patent Application Publication
(10) Pub. No.: US 2024/0420884 A1
(43) Pub. Date: Dec. 19, 2024

(54) INSULATED CHIP AND SIGNAL TRANSMITTING DEVICE

(71) Applicant: ROHM CO., LTD., Kyoto (JP)

(72) Inventor: Bungo TANAKA, Kyoto-shi (JP)

(73) Assignee: ROHM CO., LTD., Kyoto (JP)

(21) Appl. No.: 18/820,324

(22) Filed: Aug. 30, 2024

Related U.S. Application Data
(63) Continuation of application No. PCT/JP2023/006472, filed on Feb. 22, 2023.

(30) Foreign Application Priority Data
Mar. 9, 2022 (JP) 2022-036062
Mar. 9, 2022 (JP) 2022-036063

(51) Int. Cl. H01F 27/32; H01L 23/00; H01L 25/065

(52) U.S. Cl. CPC H01F 27/324; H01L 25/0655; H01L 24/48; H01L 2224/4814; H01L 2924/1904

(57) ABSTRACT

This transformer chip includes an element insulating layer and a high-voltage coil and a low-voltage coil embedded in the element insulating layer. The high-voltage coil includes a first end face facing the low-voltage coil side in the z-direction, a second end face opposite the first end face, and a first side face. The element insulating layer includes a third insulating layer, a second insulating layer laminated on the third insulating layer and having a higher relative dielectric constant than the third insulating layer, and a first insulating layer laminated on the second insulating layer and having a lower relative dielectric constant than the second insulating layer. The high-voltage coil is provided within the first insulating layer with the first end face in contact with the second insulating layer.

### CROSS-REFERENCE TO RELATED APPLICATIONS

This application is a continuation of and claims the benefit of priority from International Application No. PCT/JP2023/006472, filed on Feb. 22, 2023, which claims the benefit of priority from Japanese Patent Application No. 2022-036062, filed on Mar. 9, 2022, and Japanese Patent Application No. 2022-036063, filed on Mar. 9, 2022, the entire contents of each of which are incorporated herein by reference.

### BACKGROUND

### 1. Field

The present disclosure relates to an insulated chip and a signal transmitting device.

### 2. Description of Related Art

As an example of a signal transmitting device, an insulating gate driver that applies a gate voltage to the gate of a switching element such as a transistor is known. Such a gate driver may use an insulated chip, for example, having a known structure in which a first coil and a second coil are arranged in an element insulation layer and opposed to each other in a thickness-wise direction (refer to, for example, Japanese Laid-Open Patent Publication No. 2018-78169).

### BRIEF DESCRIPTION OF DRAWINGS

FIG. 1 is a circuit diagram schematically illustrating a circuit configuration of a signal transmitting device according to a first embodiment.

FIG. 2 is a schematic cross-sectional view of the signal transmitting device according to the first embodiment.

FIG. 3 is a schematic cross-sectional view of an insulated chip included in the signal transmitting device illustrated in FIG. 2.

FIG. 4 is an enlarged view of the first coil and components around the first coil in FIG. 3.

FIG. 5 is an enlarged view of a second coil and components around the second coil in FIG. 3.

FIG. 6 is a schematic cross-sectional view illustrating an insulated chip manufacturing process according to the first embodiment.

FIG. 7 is a schematic cross-sectional view illustrating a manufacturing process subsequent to FIG. 6.

FIG. 8 is a schematic cross-sectional view illustrating a manufacturing process subsequent to FIG. 7.

FIG. 9 is a schematic cross-sectional view illustrating a manufacturing process subsequent to FIG. 8.

FIG. 10 is a schematic cross-sectional view illustrating a manufacturing process subsequent to FIG. 9.

FIG. 11 is a schematic cross-sectional view illustrating a manufacturing process subsequent to FIG. 10.

FIG. 12 is a schematic cross-sectional view illustrating a manufacturing process subsequent to FIG. 11.

FIG. 13 is a schematic cross-sectional view illustrating a manufacturing process subsequent to FIG. 12.

FIG. 14 is a schematic cross-sectional view illustrating a manufacturing process subsequent to FIG. 13.

FIG. 15 is a schematic cross-sectional view illustrating a manufacturing process subsequent to FIG. 14.

FIG. 16 is a schematic cross-sectional view illustrating a manufacturing process subsequent to FIG. 15.

FIG. 17 is an enlarged schematic cross-sectional view illustrating a first coil and components around the first coil included in an insulated chip according to a second embodiment.

FIG. 18 is a schematic cross-sectional view illustrating an insulated chip manufacturing process according to the second embodiment.

FIG. 19 is a schematic cross-sectional view illustrating a manufacturing process subsequent to FIG. 18.

FIG. 20 is a schematic cross-sectional view illustrating a manufacturing process subsequent to FIG. 19.

FIG. 21 is a schematic cross-sectional view illustrating a manufacturing process subsequent to FIG. 20.

FIG. 22 is a schematic cross-sectional view illustrating a manufacturing process subsequent to FIG. 21.

FIG. 23 is a schematic cross-sectional view illustrating a manufacturing process subsequent to FIG. 22.

FIG. 24 is a schematic cross-sectional view illustrating a manufacturing process subsequent to FIG. 23.

FIG. 25 is a schematic cross-sectional view illustrating a manufacturing process subsequent to FIG. 24.

FIG. 26 is a schematic cross-sectional view illustrating a manufacturing process subsequent to FIG. 25.

FIG. 27 is a schematic cross-sectional view illustrating a manufacturing process subsequent to FIG. 26.

FIG. 28 is a circuit diagram schematically illustrating a circuit configuration of a signal transmitting device according to a third embodiment.

FIG. 29 is a schematic cross-sectional view of the signal transmitting device according to the third embodiment.

FIG. 30 is a schematic cross-sectional view of an insulated chip included in the signal transmitting device illustrated in FIG. 29.

FIG. 31 is an enlarged schematic cross-sectional view illustrating a first coil and components around the first coil included in an insulated chip according to a modified example.

FIG. 32 is an enlarged schematic cross-sectional view illustrating the first coil and components around the first coil included in the insulated chip according to a modified example.

FIG. 33 is a schematic cross-sectional view of the insulated chip according to the modified example.

FIG. 34 is a schematic cross-sectional view of the signal transmitting device according to the modified example.

FIG. 35 is a schematic cross-sectional view of an insulated chip included in a signal transmitting device according to a fourth embodiment.

FIG. 36 is an enlarged view of the first coil and components around the first coil in FIG. 35.

FIG. 37 is an enlarged view of a part of the first coil and element around the first coil in FIG. 36

FIG. 38 is an enlarged view of the second coil and components around the second coil in FIG. 35.

FIG. 39 is a schematic cross-sectional view illustrating an insulated chip manufacturing process according to the fourth embodiment.

FIG. 40 is a schematic cross-sectional view illustrating a manufacturing process subsequent to FIG. 39.

FIG. 41 is a schematic cross-sectional view illustrating a manufacturing process subsequent to FIG. 40.

FIG. 42 is a schematic cross-sectional view illustrating a manufacturing process subsequent to FIG. 41.

FIG. 43 is a schematic cross-sectional view illustrating a manufacturing process subsequent to FIG. 42.

FIG. 44 is a schematic cross-sectional view illustrating a manufacturing process subsequent to FIG. 43.

FIG. 45 is a schematic cross-sectional view illustrating a manufacturing process subsequent to FIG. 44.

FIG. 46 is a schematic cross-sectional view illustrating a manufacturing process subsequent to FIG. 45.

FIG. 47 is a schematic cross-sectional view illustrating a manufacturing process subsequent to FIG. 46.

FIG. 48 is a schematic cross-sectional view illustrating a manufacturing process subsequent to FIG. 47.

FIG. 49 is a schematic cross-sectional view illustrating a manufacturing process subsequent to FIG. 48.

FIG. 50 is a schematic cross-sectional view illustrating a manufacturing process subsequent to FIG. 49.

FIG. 51 is a schematic cross-sectional view illustrating a manufacturing process subsequent to FIG. 50.

FIG. 52 is a schematic cross-sectional view illustrating a manufacturing process subsequent to FIG. 51.

FIG. 53 is an enlarged schematic cross-sectional view illustrating a first coil and components around the first coil included in an insulated chip according to a fifth embodiment.

FIG. 54 is an enlarged view of a part of the first coil and components around the first coil in FIG. 53.

FIG. 55 is an enlarged schematic cross-sectional view illustrating a first coil and components around the first coil included in an insulated chip according to a modified example.

### DETAILED DESCRIPTION

Some embodiments of an insulated chip and a signal transmitting device according to the present disclosure will now be described with reference to the accompanying drawings.

For simplicity and clarity of description, the components illustrated in the drawings are not necessarily depicted to scale. To facilitate understanding, hatching lines are omitted in some of the cross-sectional views. The accompanying drawings illustrate only embodiments of the present disclosure and should not be construed as limiting the present disclosure.

The following detailed description includes a device, a system, and a method for specifically implementing exemplary embodiments of the present disclosure. This detailed description is provided for the illustrative purpose only and is not intended to limit the embodiments of the disclosure and applications or use of the embodiments.

### First Embodiment

### Configuration of Signal Transmitting Device

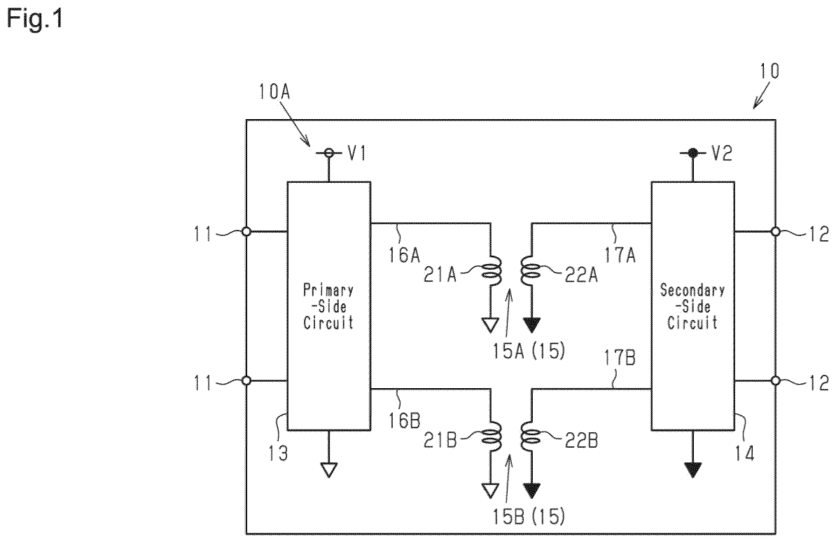

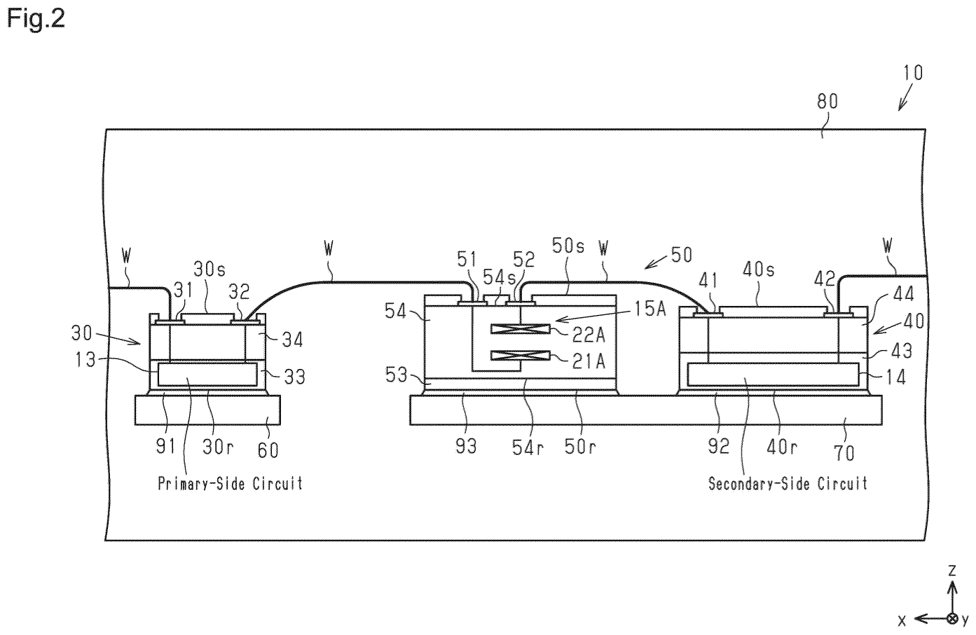

A schematic configuration of a signal transmitting device 10 according to a first embodiment will now be described with reference to FIGS. 1 and 2. FIG. 1 illustrates an example of a circuit configuration of the signal transmitting device 10 in a simplified manner. FIG. 2 illustrates an example of a schematic cross-sectional structure illustrating an internal configuration of a part of the signal transmitting device 10. In FIG. 2, hatching lines are omitted for convenience.

As illustrated in FIG. 1, the signal transmitting device 10 transmits a pulse signal while electrically insulating a primary-side terminal 11 and a secondary-side terminal 12 from each other. The signal transmitting device 10 is, for example, a digital isolator. One example of the digital isolator includes a DC/DC converter. The signal transmitting device 10 includes a signal transmitting circuit 10A including a primary-side circuit 13 that is electrically connected to the primary-side terminal 11, a secondary-side circuit 14 that is electrically connected to the secondary-side terminal 12, and a transformer 15 that electrically insulates the primary-side circuit 13 and the secondary-side circuit 14 from each other. In the present embodiment, the primary-side circuit 13 corresponds to a “first circuit”, and the secondary-side circuit 14 corresponds to a “second circuit”.

The primary-side circuit 13 is a circuit configured to operate by receiving a first voltage V1. The primary-side circuit 13 is electrically connected to, for example, an external control device (not illustrated).

The secondary-side circuit 14 is a circuit configured to operate by receiving a second voltage V2 that is different from the first voltage V1. The second voltage V2 is, for example, higher than the first voltage V1. The first voltage V1 and the second voltage V2 are DC voltages. The secondary-side circuit 14 is electrically connected to a driving circuit that is to be controlled by, for example, the control device. One example of the driving circuit includes a switching circuit.

In the signal transmitting circuit 10A, when a control signal from the control device is input to the primary-side circuit 13 via the primary-side terminal 11, the signal is transmitted from the primary-side circuit 13 to the secondary-side circuit 14 through the transformer 15. The signal transmitted to the secondary-side circuit 14 is then output from the secondary-side circuit 14 to the driving circuit via the secondary-side terminal 12.

As described above, in the signal transmitting circuit 10A, the transformer 15 electrically insulates the primary-side circuit 13 and the secondary-side circuit 14 from each other. More specifically, while transmission of a DC voltage is restricted by the transformer 15, transmission of a pulse signal between the primary-side circuit 13 and the secondary-side circuit 14 is permitted.

That is, the primary-side circuit 13 and the secondary-side circuit 14 being insulated means that, while transmission of a DC voltage between the primary-side circuit 13 and the secondary-side circuit 14 is blocked, transmission of a pulse signal from the primary-side circuit 13 to the secondary-side circuit 14 is permitted. In this manner, the secondary-side circuit 14 is configured to receive a signal from the primary-side circuit 13.

The withstand voltage of the signal transmitting device 10 is, for example, 2500 Vrms or higher and 7500 Vrms or lower. The withstand voltage of the signal transmitting device 10 according to the present embodiment is approximately 5700 Vrms. However, the specific withstand voltage of the signal transmitting device 10 is not limited thereto, and may have any value. In the present embodiment, the ground of the primary-side circuit 13 is provided separately from the ground of the secondary-side circuit 14.

A detailed configuration of the signal transmitting device 10 will now be described.

The signal transmitting device 10 according to the present embodiment includes two transformers 15 correspondingly to two types of signals being transmitted from the primary-side circuit 13 to the secondary-side circuit 14. More specifically, the signal transmitting device 10 includes a transformer 15 used in transmitting a first signal from the primary-side circuit 13 to the secondary-side circuit 14, and a transformer 15 used in transmitting a second signal from the primary-side circuit 13 to the secondary-side circuit 14. In the present embodiment, the first signal is a signal including rise information of an external signal input to the signal transmitting device 10, and the second signal is a signal including fall information of the external signal. With the first signal and the second signal, a pulse signal is generated.

For the convenience of description, the transformer 15 used in transmitting the first signal will be referred to as a “transformer 15A”, and the transformer 15 used in transmitting the second signal will be referred to as a “transformer 15B”. In the present embodiment, the transformer 15A corresponds to a “first signal transformer”, and the transformer 15B corresponds to a “second signal transformer”.

The signal transmitting device 10 includes a primary-side signal line 16A that connects the primary-side circuit 13 and the transformer 15A, a primary-side signal line 16B that connects the primary-side circuit 13 and the transformer 15B, a secondary-side signal line 17A that connects the transformer 15A and the secondary-side circuit 14, and a secondary-side signal line 17B that connects the secondary-side circuit 14 and the transformer 15B. The primary-side signal line 16A transmits the first signal from the primary-side circuit 13 to the transformer 15A, and the primary-side signal line 16B transmits the second signal from the primary-side circuit 13 to the transformer 15B. The secondary-side signal line 17A transmits the first signal from the transformer 15A to the secondary-side circuit 14, and the secondary-side signal line 17B transmits the second signal from the transformer 15B to the secondary-side circuit 14. In this manner, the first signal is transmitted from the primary-side circuit 13 to the secondary-side circuit 14 via the primary-side signal line 16A, the transformer 15A, and the secondary-side signal line 17A, sequentially. The second signal is transmitted from the primary-side circuit 13 to the secondary-side circuit 14 via the primary-side signal line 16B, the transformer 15B, and the secondary-side signal line 17B, sequentially.

The transformer 15A transmits the first signal from the primary-side circuit 13 to the secondary-side circuit 14 while electrically insulating the primary-side circuit 13 from the secondary-side circuit 14. The transformer 15B transmits the second signal from the primary-side circuit 13 to the secondary-side circuit 14 while electrically insulating the primary-side circuit 13 from the secondary-side circuit 14.

The withstand voltage of the transformers 15A and 15B in the present embodiment is, for example, 2500 Vrms or higher and 7500 Vrms or lower. The withstand voltage of the transformers 15A and 15B may be 2500 Vrms or higher and 5700 Vrms or lower. However, the specific withstand voltage of the transformers 15A and 15B is not limited thereto, and may have any value.

The transformer 15A includes a low-voltage coil 21A and a high-voltage coil 22A that is electrically insulated from the low-voltage coil 21A and can be magnetically coupled to the low-voltage coil 21A.

The low-voltage coil 21A is connected by the primary-side signal line 16A to the primary-side circuit 13 and is also connected to the ground of the primary-side circuit 13. More specifically, a first end portion of the low-voltage coil 21A is electrically connected to the primary-side circuit 13, and a second end portion of the low-voltage coil 21A is electrically connected to the ground of the primary-side circuit 13.

The high-voltage coil 22A is connected by the secondary-side signal line 17A to the secondary-side circuit 14 and is also connected to the ground of the secondary-side circuit 14. More specifically, a first end portion of the high-voltage coil 22A is electrically connected to the secondary-side circuit 14, and a second end portion of the high-voltage coil 22A is electrically connected to the ground of the secondary-side circuit 14.

The transformer 15B includes a low-voltage coil 21B and a high-voltage coil 22B that is electrically insulated from the low-voltage coil 21B and can be magnetically coupled to the low-voltage coil 21B. As illustrated in FIG. 1, the connection configuration of the low-voltage coil 21B and the high-voltage coil 22B is the same as the connection configuration of the low-voltage coil 21A and the high-voltage coil 22A, and therefore the detailed description thereof will be omitted.

As illustrated in FIG. 2, the signal transmitting device 10 is a semiconductor device in which multiple semiconductor chips are arranged in a single package. Although not illustrated, the package type of the signal transmitting device 10 is, for example, a small outline (SO) type, and is a small outline package (SOP) in the present embodiment. The package type of the signal transmitting device 10 may be changed in any manner.

The signal transmitting device 10 includes a first chip 30, a second chip 40, and a transformer chip 50, as semiconductor chips. The signal transmitting device 10 also includes a primary-side die pad 60 on which the first chip 30 is mounted, a secondary-side die pad 70 on which the second chip 40 is mounted, and an encapsulation resin 80 for encapsulating the die pads 60 and 70 and the chips 30, 40, and 50. At this time, in the present embodiment, the transformer chip 50 corresponds to an “insulated chip”; the primary-side die pad 60 corresponds to a″ first die pad “; and the secondary-side die pad 70 corresponds to a “second die pad”.

The encapsulation resin 80 is formed of an electrically insulating material. As an example of such a material, a black epoxy resin is used. The encapsulation resin 80 has the form of a rectangular plate having a thickness-wise direction conforming to the z direction.

The primary-side die pad 60 and the secondary-side die pad 70 each have the form of a flat plate. The primary-side die pad 60 and the secondary-side die pad 70 are both formed from a conductive material. In the present embodiment, the die pads 60 and 70 are formed from a material including copper (Cu). Alternatively, the die pads 60 and 70 may be formed from another metal material such as aluminum (Al). Furthermore, the material forming each of the die pads 60 and 70 is not limited to a conductive material. For example, the die pads 60 and 70 may be formed from a ceramic such as alumina. That is, the die pads 60 and 70 may be formed from an electrically-insulative material.

As viewed in the z direction, the primary-side die pad 60 and the secondary-side die pad 70 are arranged side by side and separated from each other. The direction along which the primary-side die pad 60 and the secondary-side die pad 70 are arranged as viewed in the z direction will be referred to as an x direction. A direction orthogonal to the x direction in the view from the z direction will be referred to as a y direction.

In the present embodiment, the transformer chip 50 is mounted on the secondary-side die pad 70. That is, the transformer chip 50 and the second chip 40 are both mounted on the secondary-side die pad 70. On the secondary-side die pad 70, the transformer chip 50 and the second chip 40 are separated from each other in the x direction. Thus, the chips 30, 40, and 50 are separated from one another in the x direction. In the present embodiment, the chips 30, 40, and 50 are arranged in the order of the first chip 30, the transformer chip 50, and the second chip 40, in the x direction from the primary-side die pad 60 toward the secondary-side die pad 70. In other words, the transformer chip 50 is sandwiched between the first chip 30 and the second chip 40 in the x direction.

In order to set the withstand voltage of the signal transmitting device 10 to a predetermined withstand voltage, the die pads 60 and 70 need to be separated from each other. In the present embodiment, as viewed from the z direction, the distance between the primary-side die pad 60 and the secondary-side die pad 70 in the x direction is greater than the distance between the second chip 40 and the transformer chip 50 in the x direction. Thus, as viewed from the z direction, the distance between the first chip 30 and the transformer chip 50 in the x direction is greater than the distance between the second chip 40 and the transformer chip 50 in the x direction. In other words, the transformer chip 50 is disposed closer to the second chip 40 than to the first chip 30.

The first chip 30 has a chip head surface 30s and a chip back surface 30r that face opposite directions in the z direction. The chip back surface 30r faces the side of the primary-side die pad 60. For the sake of convenience, the direction from the chip back surface 30r toward the chip head surface 30s is defined as an upward direction, and the direction from the chip head surface 30s toward the chip back surface 30r is defined as a downward direction.

A plurality of first electrode pads 31 and a plurality of second electrode pads 32 are provided on the chip head surface 30s of the first chip 30 in a manner exposed from the chip head surface 30s.

The first chip 30 includes a first substrate 33 provided with the primary-side circuit 13. The first substrate 33 is, for example, a semiconductor substrate. One example of the semiconductor substrate is a substrate formed from a material including silicon (Si). A wiring layer 34 is arranged on the first substrate 33. The first substrate 33 includes the chip back surface 30r, and the wiring layer 34 includes the chip head surface 30s.

The wiring layer 34 includes, for example, a plurality of insulation films stacked in the z direction, and a metal layer arranged between adjacent ones of the insulation films in the z direction. The metal layer forms a wiring pattern of the first chip 30. The metal layer is electrically connected to, for example, both of the primary-side circuit 13 and the electrode pads 31 and 32. That is, the electrode pads 31 and 32 are electrically connected to the primary-side circuit 13 via the wiring layer 34. The metal layer is formed from a material including Cu, Al, or the like.

The first chip 30 is bonded to the primary-side die pad 60 with a primary bonding material 91. The primary bonding material 91 is in contact with the chip back surface 30r and the primary-side die pad 60. The primary bonding material 91 is a conductive bonding material such as solder or Ag (silver) paste. Thus, the first substrate 33 and the primary-side die pad 60 are electrically connected. The primary-side die pad 60 forms the ground. Therefore, in other words, the primary-side circuit 13 is electrically connected to the ground.

The second chip 40 has a chip head surface 40s and a chip back surface 40r that face opposite directions in the z direction. The chip head surface 40s faces in the same direction as the chip head surface 30s of the first chip 30, and the chip back surface 40r faces in the same direction as the chip back surface 30r of the first chip 30. Thus, the chip back surface 40r faces the side of the secondary-side die pad 70.

A plurality of first electrode pads 41 and a plurality of second electrode pads 42 are arranged at the side of the chip head surface 40s of the second chip 40 in a manner exposed from the chip head surface 40s.

The second chip 40 includes a second substrate 43 provided with the secondary-side circuit 14. The second substrate 43 is, for example, a semiconductor substrate. One example of the semiconductor substrate is a substrate formed from a material including Si. A wiring layer 44 is arranged on the second substrate 43. The second substrate 43 includes the chip back surface 40r, and the wiring layer 44 includes the chip head surface 40s.

In the same manner as the wiring layer 34, the wiring layer 44 includes a plurality of insulation films and a metal layer. The metal layer forms a wiring pattern of the second chip 40. The metal layer is electrically connected to, for example, both of the secondary-side circuit 14 and the electrode pads 41 and 42. That is, the electrode pads 41 and 42 are electrically connected to the secondary-side circuit 14 via the wiring layer 44.

The second chip 40 is bonded to the secondary-side die pad 70 with a secondary bonding material 92. The secondary bonding material 92 is in contact with the chip back surface 40r and the secondary-side die pad 70. The secondary bonding material 92 is a conductive bonding material. Thus, the second substrate 43 and the secondary-side die pad 70 are electrically connected. The secondary-side die pad 70 forms the ground. Therefore, in other words, the secondary-side circuit 14 is electrically connected to the ground.

The transformer chip 50 is a single chip having the transformers 15A and 15B (refer to FIG. 1) integrated thereto. That is, the transformer chip 50 differs from the first chip 30 and the second chip 40 and is dedicated to the transformers 15A and 15B. The transformer chip 50 has a chip head surface 50s and a chip back surface 50r that face opposite directions in the z direction. The chip head surface 50s faces in the same direction as the chip head surface 40s of the second chip 40, and the chip back surface 50r faces in the same direction as the chip back surface 40r of the second chip 40.

A plurality of first electrode pads 51 and a plurality of second electrode pads 52 are arranged on the chip head surface 50s of the transformer chip 50 in a manner exposed from the chip head surface 50s. The plurality of first electrode pads 51 are electrode pads that are electrically connected to the low-voltage coil 21A (21B), and the plurality of second electrode pads 52 are electrode pads that are electrically connected to the high-voltage coil 22A (22B).

The transformer chip 50 is bonded to the secondary-side die pad 70 by a third bonding material 93 when the chip back surface 50r faces the side of the secondary-side die pad 70. The third bonding material 93 is in contact with the chip back surface 50r and the secondary-side die pad 70. The third bonding material 93 is an insulative bonding material such as an epoxy resin.

The plurality of first electrode pads 31 of the first chip 30 are respectively connected by a plurality of wires W to a plurality of primary-side leads, which are not illustrated. The primary-side leads are components forming the primary-side terminal 11 shown in FIG. 1. Thus, the primary-side circuit 13 and the primary-side terminal 11 are electrically connected. Each of the primary leads includes a portion protruding outside from the encapsulation resin 80.

The plurality of second electrode pads 32 on the first chip 30 are respectively connected by a plurality of wires W to the plurality of first electrode pads 51 on the transformer chip 50. Thus, the primary-side circuit 13 and the low-voltage coil 21A (21B) are electrically connected.

The plurality of second electrode pads 52 on the transformer chip 50 are respectively connected by a plurality of wires W to the plurality of first electrode pads 41 on the second chip 40. Thus, the high-voltage coil 22A (22B) and the secondary-side circuit 14 are electrically connected.

The plurality of second electrode pads 42 on the second chip 40 are respectively connected by a plurality of wires W to a plurality of secondary leads, which are not illustrated. The secondary leads are components forming the secondary-side terminal 12 shown in FIG. 1. Thus, the secondary-side circuit 14 and the secondary-side terminal 12 are electrically connected. Each of the secondary leads includes a portion protruding outside from the encapsulation resin 80. Each of the wires W described above is a bonding wire formed using a wire bonding device. The wires W are formed of a conductor such as, for example, Au (gold), Al, or Cu.

### Schematic Configuration of Transformer Chip

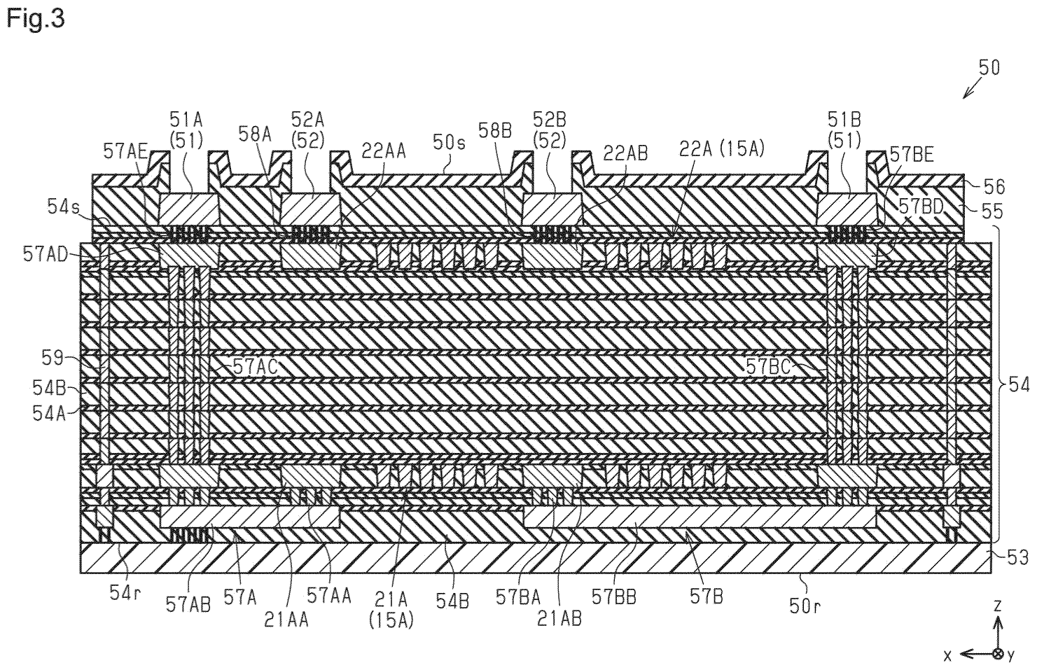

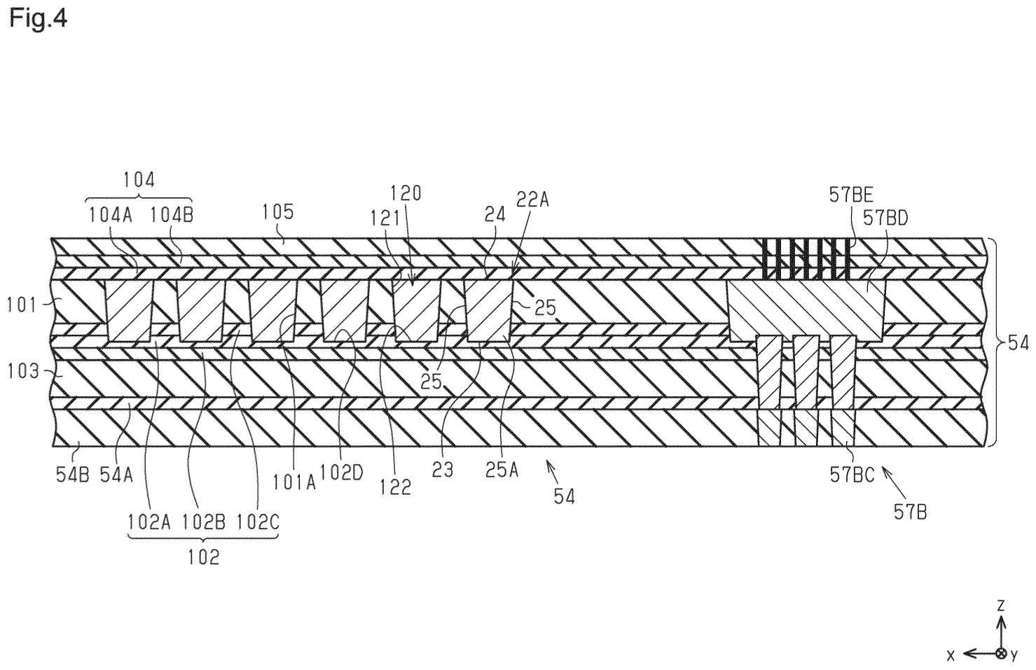

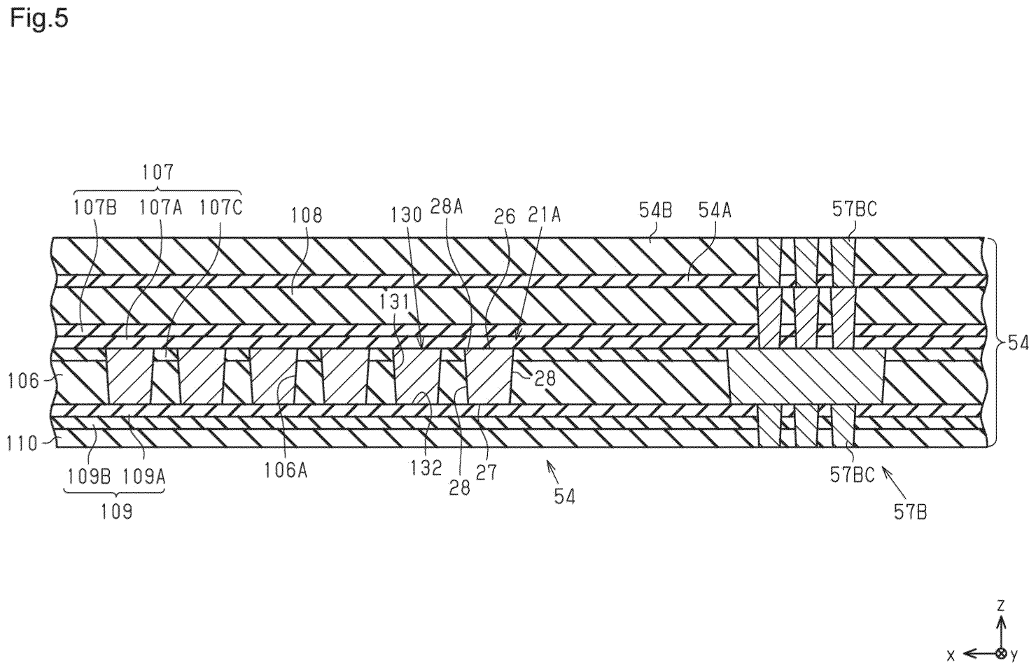

One example of an internal configuration of the transformer chip 50 will now be described with reference to FIG. 3. FIG. 3 is a cross-sectional view schematically illustrating a cross-sectional structure of the transformer chip 50 taken along an xz-plane. To facilitate understanding, the cross-sectional structure of the transformer chip 50 in FIG. 2 is a simplified version of the cross-sectional structure of the transformer chip 50 in FIG. 3. Hence, the cross-sectional structure of the transformer chip 50 illustrated in FIG. 3 is different from the cross-sectional structure of the transformer chip 50 illustrated in FIG. 2. FIG. 4 is an enlarged view of the high-voltage coil 22A and components around the high-voltage coil 22A in FIG. 3. FIG. 5 is an enlarged view of the low-voltage coil 21A and components around the low-voltage coil 21A in FIG. 3. The transformer 15A is illustrated in FIGS. 3 to 5. The transformer 15B in the transformer chip 50 has a similar configuration as that of the transformer 15A.

As illustrated in FIG. 3, the transformer chip 50 includes a substrate 53 and an element insulation layer 54 arranged on the substrate 53.

The substrate 53 is, for example, a semiconductor substrate. In the present embodiment, the substrate 53 is a semiconductor substrate formed from a material including Si. The semiconductor substrate for the substrate 53 may be a wide-bandgap semiconductor or a compound semiconductor. Furthermore, instead of using the semiconductor substrate, an insulative substrate formed of a material containing glass or an insulative substrate formed of a material containing a ceramic such as alumina may be used as the substrate 53.

The wide-bandgap semiconductor is a semiconductor substrate with a bandgap of 2.0 eV or greater. The wide-bandgap semiconductor may be SiC (silicon carbide). The compound semiconductor may be a group III-V compound semiconductor. The compound semiconductor may include at least one of aluminum nitride (AlN), indium nitride (InN), gallium nitride (GaN), and gallium arsenide (GaAs).

The element insulation layer 54 includes a plurality of etching stopper films 54A and a plurality of interlayer insulation films 54B formed on the plurality of etching stopper films 54A. The plurality of etching stopper films 54A are stacked alternately with the plurality of interlayer insulation films 54B in the z direction. The z direction corresponds to the “thickness-wise direction of the element insulation layer”.

The etching stopper films 54A are formed from a material including silicon nitride (SiN), SiC, nitrogen-added silicon carbide (SiCN), or the like. In the present embodiment, the etching stopper films 54A are formed from a material including SiN. The etching stopper films 54A have a function of, for example, preventing diffusion of Cu. That is, the etching stopper films 54A may be referred to as a Cu diffusion prevention film.

The interlayer insulation film 54B is an oxide film formed from a material including SiO₂ (silicon oxide). Each of the interlayer insulation films 54B has a thickness greater than that of the etching stopper film 54A. The etching stopper film 54A has a thickness of 50 nm or more and less than 1000 nm. The interlayer insulation film 54B has a thickness of 500 nm or more and 5000 nm or less. In the present embodiment, the etching stopper film 54A has a thickness of about 300 nm, and the interlayer insulation film 54B has a thickness of about 2000 nm. From the viewpoint of the ease of viewing the drawings, the ratio of the thickness of the etching stopper film 54A to the thickness of the interlayer insulation film 54B in the drawings differs from the actual ratio of the thickness of the etching stopper film 54A with the thickness of the interlayer insulation film 54B.

The element insulation layer 54 has an element head surface 54s and an element back surface 54r that face opposite directions in the z direction. The element head surface 54s faces in the same direction as the chip head surface 50s of the transformer chip 50, and the element back surface 54r faces in the same direction as the chip back surface 50r of the transformer chip 50. In the present embodiment, the element back surface 54r of the element insulation layer 54 is in contact with the substrate 53.

A plurality of first electrode pads 51, a plurality of second electrode pads 52, a protective film 55, and a passivation film 56 are arranged on the element insulation layer 54.

Each of the electrode pads 51 and 52 is provided on the element head surface 54s of the element insulation layer 54. Each of the electrode pads 51 and 52 is covered by the protective film 55 and the passivation film 56. At the same time, both the protective film 55 and the passivation film 56 have openings through which the electrode pads 51 and 52 are exposed. Therefore, each of the electrode pads 51 and 52 has an exposed surface for connecting the wire W (refer to FIG. 2).

The protective film 55 is provided on the element head surface 54s of the element insulation layer 54. The protective film 55 is a film for protecting the element insulation layer 54, and is, for example, formed from a material including SiO₂. The passivation film 56 is provided on the protective film 55. The passivation film 56 is a film for protecting the surface of the transformer chip 50 and is formed from a material including, for example, SiN. The passivation film 56 includes the chip head surface 50s of the transformer chip 50.

The low-voltage coil 21A and the high-voltage coil 22A are both embedded in the element insulation layer 54. In other words, the coils 21A and 22A are both arranged in the element insulation layer 54. The high-voltage coil 22A is opposed to the low-voltage coil 21A in the z direction. A part of the element insulation layer 54 is sandwiched between the low-voltage coil 21A and the high-voltage coil 22A in the z direction. The high-voltage coil 22A is disposed closer to the element head surface 54s of the element insulation layer 54 than the low-voltage coil 21A is.

As the material forming the coils 21A and 22A, one or more elements are appropriately selected from titanium (Ti), titanium nitride (TiN), tantalum (Ta), tantalum nitride (TaN), Au, Ag, Cu, Al, and tungsten (W). In the present embodiment, the coils 21A and 22A are formed of a material including Cu.

The low-voltage coil 21A includes a first coil end 21AA and a second coil end 21 AB. The first coil end 21AA is arranged at an outer side of a winding portion of the low-voltage coil 21A as viewed from the z direction. The second coil end 21AB is also arranged at an inner side of the winding portion of the low-voltage coil 21A as viewed from the z direction.

The high-voltage coil 22A includes a first coil end 22AA and a second coil end 22AB. The first coil end 22AA is arranged at an outer side of the winding portion of the high-voltage coil 22A as viewed from the z direction. As viewed from the z direction, the first coil end 22AA is disposed at a position overlapping with the first coil end 21AA of the low-voltage coil 21A. The second coil end 22AB is arranged at an inner side of the winding portion of the high-voltage coil 22A as viewed from the z direction. As viewed from the z direction, the second coil end 22AB is disposed at a position overlapping with the second coil end 21AB of the low-voltage coil 21A.

The plurality of first electrode pads 51 include two first electrode pads 51A and 51B that are electrically connected to the low-voltage coil 21A. The plurality of second electrode pads 52 include two second electrode pads 52A and 52B that are electrically connected to the high-voltage coil 22A.

The first coil end 21AA of the low-voltage coil 21A is electrically connected to the first electrode pad 51A via the low-voltage side connection wiring 57A. The low-voltage side connection wiring 57A includes: a first via 57AA connected to the first coil end 21AA; a first wiring 57AB connected to the first via 57AA and extending in the x direction; a second via 57AC connected to the first wiring 57AB and extending in the z direction; a second wiring 57AD connected to the second via 57AC; and a third via 57AE connecting the second wiring 57AD and the first electrode pad 51A. The low-voltage side connection wiring 57A is electrically connected to the substrate 53. With this, the first coil end 21AA of the low-voltage coil 21A is electrically connected to the substrate 53. In the present embodiment, the first coil end 21AA of the low-voltage coil 21A is electrically connected to the ground of the primary-side circuit 13 (refer to FIG. 2). In the present embodiment, the first wiring 57AB is disposed closer to the substrate 53 than the low-voltage coil 21A is. The second wiring 57AD is aligned with the high-voltage coil 22A in the z direction.

The second coil end 21AB of the low-voltage coil 21A is electrically connected to the first electrode pad 51B via the low-voltage side connection wiring 57B. The low-voltage side connection wiring 57B includes: a first via 57BA connected to the second coil end 21AB; a first wiring 57BB connected to the first via 57BA and extending outwards from the low-voltage coil 21A in the x direction; a second via 57BC connected to the first wiring 57BB and provided along the z direction; a second wiring 57BD connected to the second via 57BC; and a third via 57BE connecting the second wiring 57BD and the first electrode pad 51B. In the present embodiment, the first wiring 57BB is disposed closer to the substrate 53 than the low-voltage coil 21A is. The first wiring 57BB is aligned with the first wiring 57AB of the low-voltage side connection wiring 57A in the z direction. The second wiring 57BD is aligned with the high-voltage coil 22A in the z direction. That is, the second wiring 57BD is aligned with the second wiring 57AD of the low-voltage side connection wiring 57A in the z direction.

The first coil end 22AA of the high-voltage coil 22A is electrically connected to the second electrode pad 52A via a via 58A. The second electrode pad 52A is disposed at a position overlapping with the first coil end 22AA as viewed from the z direction. The via 58A connects the second electrode pad 52A and the first coil end 22AA in the z direction.

The second coil end 22AB of the high-voltage coil 22A is electrically connected to the second electrode pad 52B via a via 58B. The second electrode pad 52B is disposed at a position overlapping with the second coil end 22AB as viewed from the z direction. The via 58B connects the second electrode pad 52B and the second coil end 22AB in the z direction.

As a material forming each of the low-voltage side connection wirings 57A and 57B and the vias 58A and 58B, one or more elements are appropriately selected from, for example, Ti, TiN, Ta, TaN, Au, Ag, Cu, Al, and W. In the present embodiment, the low-voltage side connection wirings 57A and 57B and the vias 58A and 58B are formed from a material including Cu.

Although not illustrated, the low-voltage coil 21B and the high-voltage coil 22B are both embedded in the element insulation layer 54. The low-voltage coil 21B is opposed to the high-voltage coil 22B in the z direction. The low-voltage coil 21B is aligned with the low-voltage coil 21A in the z direction. The low-voltage coil 21B is disposed separately from the low-voltage coil 21A in the y direction. The high-voltage coil 22B is aligned with the high-voltage coil 22A in the z direction. The high-voltage coil 22B is disposed separately from the high-voltage coil 22A in the y direction. The coils 21B and 22B are formed of the same material as that of the coils 21A and 22A.

The element insulation layer 54 is provided with a shield electrode 59. The shield electrode 59 limits entrance of moisture into the element insulation layer 54 and formation of cracks in the element insulation layer 54. The shield electrode 59 is arranged so as to surround the electrode pads 51 and 52, the coils 21A, 21B, 22A, and 22B, the low-voltage side connection wirings 57A and 57B, and the vias 58A and 58B as viewed from the z direction. The shield electrode 59 extends in the z direction. The shield electrode 59 is electrically connected to the substrate 53.

### Detailed Configuration of Coil and Components Around Coil

As illustrated in FIGS. 4 and 5, the configuration of the element insulation layer 54 around each of the coils 21A and 22A is different from the configuration of the element insulation layer 54 between the low-voltage coil 21A and the high-voltage coil 22A in the z direction. Specifically, the element insulation layer 54 includes, in addition to the etching stopper films 54A and the interlayer insulation films 54B, a structure that alleviates the concentration of an electric field on the coils 21A and 22A. The configuration of the coils 21A and 22A and the configuration of the coils 21A and 22A and the element insulation layer 54 around the coils 21A and 22A will now be described in detail.

As illustrated in FIG. 4, the high-voltage coil 22A includes a first end surface 23 facing toward the low-voltage coil 21A (refer to FIG. 5) in the z direction, a second end surface 24 facing toward the side opposite from the first end surface 23 in the z direction, and a first side surface 25. The first side surface 25 extends between the first end surface 23 and the second end surface 24 in the z direction. In the present embodiment, in the cross-sectional view shown in FIG. 4, the first side surface 25 is tapered from the second end surface 24 toward the first end surface 23. In the cross-sectional view shown in FIG. 4, each of the first end surface 23 and the second end surface 24 has a flat surface that is orthogonal to the z direction. The high-voltage coil 22A has a spiral shape as viewed from the z direction.

The number of turns in the high-voltage coil 22A may be changed to in any manner. In addition, the cross-sectional structure including the first end surface 23, the second end surface 24, and two first side surfaces 25 of the high-voltage coil 22A may be changed in any manner. As one example, two first side surfaces 25 may extend in the z direction. In other words, the high-voltage coil 22A including the first end surface 23, the second end surface 24, and the two first side surfaces 25 may have any rectangular cross-sectional structure.

The element insulation layer 54 around the high-voltage coil 22A includes a first insulation layer 101, a second insulation layer 102, a third insulation layer 103, a fourth insulation layer 104, and a fifth insulation layer 105. The second insulation layer 102 is arranged on the third insulation layer 103; the first insulation layer 101 is arranged on the second insulation layer 102; the fourth insulation layer 104 is arranged on first insulation layer 101; and the fifth insulation layer 105 is arranged on the fourth insulation layer 104. The high-voltage coil 22A is embedded in the first insulation layer 101. In the present embodiment, the high-voltage coil 22A extends in the second insulation layer 102 and the first insulation layer 101.

The second insulation layer 102 and the first insulation layer 101 have a first trench 120 corresponding to the high-voltage coil 22A. The first trench 120 includes a first trench side surface 121 and a first trench bottom surface 122. The first trench side surface 121 is tapered toward the first trench bottom surface 122. In other words, the first trench 120 includes a through hole 101A extending through the first insulation layer 101 in the z direction, and a groove 102D formed in the second insulation layer 102 and communicating with the through hole 101A. The first trench side surface 121 includes a side surface forming the through hole 101A, and a side surface of the groove 102D. The first trench bottom surface 122 includes a bottom surface of the groove 102D. As described above, the second insulation layer 102 and the first insulation layer 101 include the first trench side surface 121, and the second insulation layer 102 includes the first trench bottom surface 122.

The first end surface 23 of the high-voltage coil 22A is in contact with the first trench bottom surface 122. In other words, the second insulation layer 102 is in contact with the first end surface 23 of the high-voltage coil 22A. By contrast, the first insulation layer 101 is not in contact with the first end surface 23.

The first side surface 25 of the high-voltage coil 22A is in contact with the first trench side surface 121. In other words, the second insulation layer 102 and the first insulation layer 101 are both in contact with the first side surface 25. More specifically, the second insulation layer 102 covers a lower end portion 25A of the first side surface 25, the lower end portion 25A forming a corner with the first end surface 23. The first insulation layer 101 is in contact with a part of the first side surface 25 of the high-voltage coil 22A located closer to the second end surface 24 than the lower end portion 25A is. The entire first side surface 25 of the high-voltage coil 22A is covered by the second insulation layer 102 and the first insulation layer 101.

The element insulation layer 54 around the high-voltage coil 22A has a structure for alleviating the concentration of an electric field generated in a region between the high-voltage coil 22A and the low-voltage coil 21A. In one example, the element insulation layer 54 includes the third insulation layer 103 and the second insulation layer 102 as the structure for alleviating the concentration of an electric field in the region between the high-voltage coil 22A and the low-voltage coil 21A.

The third insulation layer 103 is provided below the high-voltage coil 22A. In other words, the third insulation layer 103 is arranged closer to the low-voltage coil 21A than the high-voltage coil 22A is. The third insulation layer 103 is arranged separately from the high-voltage coil 22A in the z direction. The third insulation layer 103 is formed from a material including SiO₂. Therefore, the third insulation layer 103 has a relative permittivity of approximately 3.8. In the present embodiment, the third insulation layer 103 includes the interlayer insulation film 54B.

The second insulation layer 102 has a relative permittivity higher than the relative permittivity of the third insulation layer 103. The second insulation layer 102 is formed from a material including any one of SiN, SiON, and SiC. The second insulation layer 102 has a thickness smaller than the thickness of the third insulation layer 103. In other words, the second insulation layer 102 has a thickness smaller than the thickness of the interlayer insulation film 54B. In the present embodiment, the second insulation layer 102 has a thickness greater than the thickness of the etching stopper film 54A.

The second insulation layer 102 includes: a first high permittivity film 102A in contact with the first end surface 23 of the high-voltage coil 22A; a second high permittivity film 102B in contact with the third insulation layer 103; and a third high permittivity film 102C arranged on the first high permittivity film 102A.

The first high permittivity film 102A is in contact with the lower end portion 25A of the first side surface 25 as well as with the first end surface 23. More specifically, the first high permittivity film 102A forms a part of the groove 102D. The lower end portion 25A of the first side surface 25 is in contact with the groove 102D. The first high permittivity film 102A is arranged on the second high permittivity film 102B. In the present embodiment, the first high permittivity film 102A is in contact with the second high permittivity film 102B. The first high permittivity film 102A has a thickness equal to the thickness of the second high permittivity film 102B. It is considered that the first high permittivity film 102A has a thickness equal to the thickness of the second high permittivity film 102B, for example, when the difference in the thickness between the first high permittivity film 102A and the second high permittivity film 102B is within 20% of the thickness of the first high permittivity film 102A. The first high permittivity film 102A is formed from a material including SiN. Therefore, the first high permittivity film 102A has a relative permittivity of approximately 7.

The second high permittivity film 102B covers the first end surface 23 of the high-voltage coil 22A. The second high permittivity film 102B is arranged separately from the high-voltage coil 22A and located closer to the low-voltage coil 21A than the high-voltage coil 22A is in the z direction. In the present embodiment, the second high permittivity film 102B is in contact with the first high permittivity film 102A.

The second high permittivity film 102B has a relative permittivity lower than the relative permittivity of the first high permittivity film 102A. By contrast, the second high permittivity film 102B has a relative permittivity higher than the relative permittivity of the third insulation layer 103. More specifically, the relative permittivity of the second high permittivity film 102B is within a range greater than 3.8 and less than 7. In one example, the relative permittivity of the second high permittivity film 102B may be within a range greater than 4 and less than 7. The second high permittivity film 102B is formed from a material including SiON. Hence, the relative permittivity of the second high permittivity film 102B is adjusted within the range described above in accordance with the concentration of N (nitrogen) in SiON.

The third high permittivity film 102C covers a part of the first side surface 25 of the high-voltage coil 22A located above the lower end portion 25A. In the present embodiment, the third high permittivity film 102C is in contact with the first high permittivity film 102A. The first insulation layer 101 is arranged on the third high permittivity film 102C. In the present embodiment, the third high permittivity film 102C is in contact with the first insulation layer 101. The first high permittivity film 102A has a thickness equal to the thickness of the third high permittivity film 102C. It is considered that the first high permittivity film 102A has a thickness equal to the thickness of the third high permittivity film 102C, for example, when the difference in the thickness between the first high permittivity film 102A and the third high permittivity film 102C is within 20% of the thickness of the first high permittivity film 102A. In one example, the thickness of the third high permittivity film 102C is equal to the thickness of the second high permittivity film 102B. It is considered that the third high permittivity film 102C has a thickness equal to the thickness of the second high permittivity film 102B, for example, when the difference in the thickness between the third high permittivity film 102C and the second high permittivity film 102B is within 20% of the thickness of the third high permittivity film 102C.

The third high permittivity film 102C has a relative permittivity higher than the relative permittivity of the second high permittivity film 102B. The third high permittivity film 102C is formed from a material including SiN. Therefore, the third high permittivity film 102C is the same as the relative permittivity of the first high permittivity film 102A, and has a relative permittivity of approximately 7. Thus, in other words, the third high permittivity film 102C includes the etching stopper film 54A.

The first insulation layer 101 has a relative permittivity lower than the relative permittivity of the second insulation layer 102. The first insulation layer 101 is formed from a material including SiO₂. The first insulation layer 101 has a thickness greater than the thickness of the second insulation layer 102. The thickness of the first insulation layer 101 is equal to the thickness of the third insulation layer 103. It is considered that the first insulation layer 101 has a thickness equal to the thickness of the third insulation layer 103, for example, when the difference between the thickness of the first insulation layer 101 and the thickness of the third insulation layer 103 is within 20% of the thickness of the third insulation layer 103. In the present embodiment, the first insulation layer 101 includes an interlayer insulation film 54B in the same manner as the third insulation layer 103.

As described above, in the structure for alleviating the concentration of an electric field on the high-voltage coil 22A with respect to the low-voltage coil 21A, the first high permittivity film 102A, the second high permittivity film 102B, and the third insulation layer 103 of the second insulation layer 102 are sequentially arranged in the direction from the first end surface 23 of the high-voltage coil 22A toward the low-voltage coil 21A. That is, the relative permittivity is configured to be decreased in the direction from the first end surface 23 of the high-voltage coil 22A toward the low-voltage coil 21A.

The element insulation layer 54 around the high-voltage coil 22A has a structure for alleviating the concentration of an electric field on the high-voltage coil 22A at a side opposite from the low-voltage coil 21A. In one example, the element insulation layer 54 includes the fourth insulation layer 104 and the fifth insulation layer 105 as the structure for alleviating the concentration of an electric field on the high-voltage coil 22A at a side opposite from the low-voltage coil 21A.

The fourth insulation layer 104 is arranged on the first insulation layer 101 so as to contact the second end surface 24 of the high-voltage coil 22A. As described above, in the present embodiment, the high-voltage coil 22A is covered by the second insulation layer 102, the first insulation layer 101, and the fourth insulation layer 104. The fourth insulation layer 104 has a relative permittivity higher than the relative permittivity of the first insulation layer 101. The fourth insulation layer 104 is formed from a material including any one of SIN, SiON, and SiC.

The fourth insulation layer 104 includes a high permittivity lower film 104A in contact with the second end surface 24 of the high-voltage coil 22A and a high permittivity upper film 104B arranged on the high permittivity lower film 104A.

The high permittivity lower film 104A is in contact with the first insulation layer 101 as well as with the second end surface 24. The high permittivity lower film 104A has a relative permittivity higher than the relative permittivity of the first insulation layer 101. The high permittivity lower film 104A is formed from a material including SiN. Therefore, the high permittivity lower film 104A has a relative permittivity of approximately 7.

The thickness of the high permittivity lower film 104A is equal to the thickness of the etching stopper film 54A. It is considered that the high permittivity lower film 104A has a thickness equal to the thickness of the etching stopper film 54A, for example, when the difference between the thickness of the high permittivity lower film 104A and the thickness of the etching stopper film 54A is within 20% of the thickness of the etching stopper film 54A. Thus, in other words, the high permittivity lower film 104A includes the etching stopper film 54A.

The high permittivity upper film 104B is in contact with the high permittivity lower film 104A. The high permittivity upper film 104B is arranged separately from the high-voltage coil 22A. The relative permittivity of the high permittivity upper film 104B is lower than the relative permittivity of the high permittivity lower film 104A. By contrast, the relative permittivity of the high permittivity upper film 104B is higher than the relative permittivity of the fifth insulation layer 105. In one example, the high permittivity upper film 104B has a relative permittivity within a range greater than 3.8 and less than 7. In another example, the relative permittivity of the high permittivity upper film 104B may be within a range greater than 4 and less than 7. The high permittivity upper film 104B is formed from a material including SiON. Hence, the relative permittivity of the high permittivity upper film 104B is adjusted within the range described above in accordance with the concentration of nitrogen in SiON.

The high permittivity upper film 104B has a thickness equal to the thickness of the high permittivity lower film 104A. It is considered that the high permittivity upper film 104B has a thickness equal to the thickness of the high permittivity lower film 104A, for example, when the difference between the thickness of the high permittivity upper film 104B and the thickness of the high permittivity lower film 104A is within 20% of the thickness of the high permittivity upper film 104B.

The fifth insulation layer 105 is arranged on the fourth insulation layer 104. Specifically, the fifth insulation layer 105 is arranged on the high permittivity upper film 104B. The fifth insulation layer 105 is in contact with the high permittivity upper film 104B. The fifth insulation layer 105 is arranged separately from the high-voltage coil 22A in the z direction.

The fifth insulation layer 105 has a relative permittivity lower than the relative permittivity of the fourth insulation layer 104. The fifth insulation layer 105 is formed from a material including SiO₂. Therefore, the relative permittivity of the fifth insulation layer 105 is the same as the relative permittivity of the third insulation layer 103, and is approximately 3.8. In the present embodiment, the fifth insulation layer 105 has a thickness smaller than the thickness of the third insulation layer 103. The fifth insulation layer 105 has a thickness greater than the thickness of each of the high permittivity lower film 104A and the high permittivity upper film 104B.

The fifth insulation layer 105 may have a thickness greater than or equal to the thickness of the fourth insulation layer 104. The fifth insulation layer 105 may have a thickness equal to the thickness of the third insulation layer 103. It is considered that the fifth insulation layer 105 has a thickness equal to the thickness of the third insulation layer 103, for example, when the difference between the thickness of the fifth insulation layer 105 and the thickness of the third insulation layer 103 is within 20% of the thickness of the third insulation layer 103. The fifth insulation layer 105 includes the interlayer insulation film 54B.

As described above, in the structure for alleviating the concentration of an electric field on the high-voltage coil 22A at a side opposite from the low-voltage coil 21A, the high permittivity lower film 104A and the high permittivity upper film 104B in the fourth insulation layer 104, and the fifth insulation layer 105 are sequentially formed in the direction upward from the second end surface 24 of the high-voltage coil 22A. That is, the relative permittivity is configured to be decreased in a direction upward from the second end surface 24 of the high-voltage coil 22A.

As illustrated in FIG. 5, the low-voltage coil 21A has the same configuration as the high-voltage coil 22A. The low-voltage coil 21A includes a third end surface 26 facing toward the high-voltage coil 22A (refer to FIG. 4) in the z direction, a fourth end surface 27 facing toward the side opposite from the third end surface 26 in the z direction, and a second side surface 28. The third end surface 26 faces in the same direction as the second end surface 24 (refer to FIG. 4) of the high-voltage coil 22A, and the fourth end surface 27 faces in the same direction as the first end surface 23 (refer to FIG. 4) of the high-voltage coil 22A. The second side surface 28 extends between the third end surface 26 and the fourth end surface 27 in the z direction. The second side surface 28 is tapered from the third end surface 26 toward the fourth end surface 27 in the cross-sectional view in FIG. 5. In the cross-sectional view in FIG. 5, each of the third end surface 26 and the fourth end surface 27 has a flat surface. The low-voltage coil 21A has a spiral shape as viewed from the z direction. The number of turns in the low-voltage coil 21A is the same as the number of turns in the high-voltage coil 22A.

The number of turns in the low-voltage coil 21A may be changed in any manner. Furthermore, the cross-sectional structure including the third end surface 26, the fourth end surface 27, and two second side surfaces 28 of the low-voltage coil 21A may be changed to any shape. In one example, the two second side surfaces 28 may extend along the z direction. That is, the low-voltage coil 21A including the third end surface 26, the fourth end surface 27, and the two second side surfaces 28 may have any rectangular cross-sectional structure.

The element insulation layer 54 around the low-voltage coil 21A includes a sixth insulation layer 106, a seventh insulation layer 107, an eighth insulation layer 108, a ninth insulation layer 109, and a tenth insulation layer 110. The ninth insulation layer 109 is arranged on the tenth insulation layer 110, the sixth insulation layer 106 is arranged on the ninth insulation layer 109, the seventh insulation layer 107 is arranged on the sixth insulation layer 106, and the eighth insulation layer 108 is arranged on the seventh insulation layer 107.

When the low-voltage coil 21A is in contact with the ninth insulation layer 109, the low-voltage coil 21A is arranged in the sixth insulation layer 106. A part of the low-voltage coil 21A is arranged in the seventh insulation layer 107. That is, the low-voltage coil 21A is arranged in the sixth insulation layer 106 and the seventh insulation layer 107.

More specifically, the sixth insulation layer 106 and the ninth insulation layer 109 have a second trench 130 corresponding to the low-voltage coil 21A. The second trench 130 includes a through hole 106A extending through the sixth insulation layer 106 in the z direction. The second trench 130 includes a second trench side surface 131 and a second trench bottom surface 132. The second trench side surface 131 is a tapered toward the second trench bottom surface 132. The sixth insulation layer 106 and the seventh insulation layer 107 define the entire second trench side surface 131. The second trench side surface 131 includes a side surface forming the through hole 106A. The ninth insulation layer 109 forms the second trench bottom surface 132. The ninth insulation layer 109 forms the entire second trench bottom surface 132.

The third end surface 26 of the low-voltage coil 21A is arranged above the sixth insulation layer 106. The third end surface 26 of the low-voltage coil 21A extends into the seventh insulation layer 107. That is, an upper portion of the low-voltage coil 21A is covered by the seventh insulation layer 107.

The fourth end surface 27 of the low-voltage coil 21A is in contact with the second trench bottom surface 132. In other words, the ninth insulation layer 109 is in contact with the fourth end surface 27 of the low-voltage coil 21A. By contrast, the sixth insulation layer 106 is not in contact with the fourth end surface 27.

The sixth insulation layer 106 is formed from a material including SiO₂. Therefore, the sixth insulation layer 106 has a relative permittivity of approximately 3.8. The sixth insulation layer 106 has a thickness greater than the thickness of the seventh insulation layer 107 (ninth insulation layer 109). The sixth insulation layer 106 has a thickness equal to the thickness of the first insulation layer 101 (refer to FIG. 4). It is considered that the sixth insulation layer 106 has a thickness equal to the thickness of the first insulation layer 101, for example, when the difference between the thickness of the sixth insulation layer 106 and the thickness of the first insulation layer 101 is within 20% of the thickness of the first insulation layer 101. In the present embodiment, the sixth insulation layer 106 includes the interlayer insulation film 54B in the same manner as the first insulation layer 101.

The second side surface 28 of the low-voltage coil 21A is in contact with the second trench side surface 131. In other words, the sixth insulation layer 106 and the seventh insulation layer 107 are in contact with the second side surface 28 of the low-voltage coil 21A. More specifically, the sixth insulation layer 106 covers a portion of the second side surface 28 of the low-voltage coil 21A located closer to the fourth end surface 27 than an upper end portion 28A is. The upper end portion 28A forms a corner with the third end surface 26. That is, in the present embodiment, the low-voltage coil 21A protrudes upward from the sixth insulation layer 106. The seventh insulation layer 107 covers the upper end portion 28A of the low-voltage coil 21A.

The element insulation layer 54 includes the seventh insulation layer 107 and the eighth insulation layer 108 as a structure for alleviating the concentration of an electric field on the low-voltage coil 21A at the side of the high-voltage coil 22A. In other words, this structure is for alleviating the concentration of an electric field in the region between the high-voltage coil 22A and the low-voltage coil 21A.

The seventh insulation layer 107 is arranged on the sixth insulation layer 106 so as to contact the third end surface 26 of the low-voltage coil 21A. As described above, in the present embodiment, the low-voltage coil 21A is covered by the sixth insulation layer 106, the seventh insulation layer 107, and the ninth insulation layer 109. Thus, in other words, when the third end surface 26 is in contact with the seventh insulation layer 107, the low-voltage coil 21A is arranged in the sixth insulation layer 106.

The seventh insulation layer 107 has a relative permittivity higher than the relative permittivity of sixth insulation layer 106. The seventh insulation layer 107 is formed from a material including any one of SiN, SiON, and SiC. The seventh insulation layer 107 has a thickness smaller than the thickness of the sixth insulation layer 106. In other words, the seventh insulation layer 107 has a thickness smaller than the thickness of the interlayer insulation film 54B. In the present embodiment, the seventh insulation layer 107 has a thickness greater than the thickness of the etching stopper film 54A.

The seventh insulation layer 107 includes: a fourth high permittivity film 107A in contact with the third end surface 26 of the low-voltage coil 21A; a fifth high permittivity film 107B in contact with the eighth insulation layer 108; and a sixth high permittivity film 107C in contact with the sixth insulation layer 106.

The fourth high permittivity film 107A is provided on the sixth high permittivity film 107C. The fourth high permittivity film 107A is sandwiched between the fifth high permittivity film 107B and the sixth high permittivity film 107C. In the present embodiment, the fourth high permittivity film 107A is in contact with the sixth high permittivity film 107C.

The low-voltage coil 21A extends through the sixth high permittivity film 107C. In the present embodiment, the third end surface 26 of the low-voltage coil 21A is aligned, in the z direction, with a surface of the sixth high permittivity film 107C that is in contact with the fourth high permittivity film 107A. Thus, the sixth high permittivity film 107C is arranged to cover an end portion of the second side surface 28 of the low-voltage coil 21A located close to the third end surface 26. In the present embodiment, the sixth high permittivity film 107C is in contact with the second side surface 28.

The fourth high permittivity film 107A is formed from a material including SiN. Therefore, the fourth high permittivity film 107A has a relative permittivity of approximately 7. The thickness of the fourth high permittivity film 107A is equal to the thickness of the etching stopper film 54A. It is considered that the fourth high permittivity film 107A has a thickness equal to the thickness of the etching stopper film 54A, for example, when the difference between the thickness of the fourth high permittivity film 107A and the thickness of the etching stopper film 54A is within 20% of the thickness of the etching stopper film 54A. The fourth high permittivity film 107A includes the etching stopper film 54A. The fourth high permittivity film 107A is in contact with the third end surface 26 of the low-voltage coil 21A.

The fifth high permittivity film 107B is arranged on the fourth high permittivity film 107A. In the present embodiment, the fifth high permittivity film 107B is in contact with the fourth high permittivity film 107A. That is, the fourth high permittivity film 107A is in contact with both of the fifth high permittivity film 107B and the sixth high permittivity film 107C. The fifth high permittivity film 107B is arranged separately from the low-voltage coil 21A and located closer to the high-voltage coil 22A (refer to FIG. 4) than the low-voltage coil 21A is in the z direction.

The fifth high permittivity film 107B has a relative permittivity lower than the relative permittivity of the fourth high permittivity film 107A. By contrast, the fifth high permittivity film 107B has a relative permittivity higher than the relative permittivity of the sixth insulation layer 106. In one example, the relative permittivity of the fifth high permittivity film 107B is within a range greater than 3.8 and less than 7. In another example, the relative permittivity of the fifth high permittivity film 107B may be within a range greater than 4 and less than 7. The fifth high permittivity film 107B is formed from a material including SiON. Hence, the relative permittivity of the fifth high permittivity film 107B is adjusted within the range described above in accordance with the concentration of nitrogen in SiON.

In one example, the fifth high permittivity film 107B has a thickness equal to the thickness of the fourth high permittivity film 107A. It is considered the fifth high permittivity film 107B has a thickness equal to the thickness of the fourth high permittivity film 107A, for example, when the difference between the thickness of the fifth high permittivity film 107B and the thickness of the fourth high permittivity film 107A is within 20% of the thickness of the fifth high permittivity film 107B.

The sixth high permittivity film 107C is sandwiched between the sixth insulation layer 106 and the fourth high permittivity film 107A. The sixth high permittivity film 107C covers a portion of the second side surface 28 of the low-voltage coil 21A located closer to the third end surface 26 than the upper end portion 28A. In the present embodiment, the sixth high permittivity film 107C is in contact with a portion of the second side surface 28 located closer to the third end surface 26 than the upper end portion 28A.

The sixth high permittivity film 107C has a relative permittivity higher than the relative permittivity of the fifth high permittivity film 107B. The sixth high permittivity film 107C is formed from a material including SiN. Therefore, the sixth high permittivity film 107C has a relative permittivity of approximately 7. Thus, in other words, the sixth high permittivity film 107C includes the etching stopper film 54A.

In one example, the sixth high permittivity film 107C has a thickness equal to the thickness of the fourth high permittivity film 107A. It is considered that the sixth high permittivity film 107C has a thickness equal to the thickness of the fourth high permittivity film 107A, for example, when the difference between the thickness of the sixth high permittivity film 107C and the thickness of the fourth high permittivity film 107A is within 20% of the thickness of the sixth high permittivity film 107C.

The eighth insulation layer 108 is arranged closer to the high-voltage coil 22A than the low-voltage coil 21A is. The eighth insulation layer 108 is arranged separately from the low-voltage coil 21A in the z direction.

The eighth insulation layer 108 has a relative permittivity lower than the relative permittivity of the seventh insulation layer 107. The eighth insulation layer 108 is formed from a material including SiO₂. Therefore, the relative permittivity of the eighth insulation layer 108 is the same as the relative permittivity of the sixth insulation layer 106 and is approximately 3.8. The eighth insulation layer 108 has a thickness greater than the thickness of the seventh insulation layer 107. The eighth insulation layer 108 has a thickness equal to the thickness of the sixth insulation layer 106. It is considered that the eighth insulation layer 108 has a thickness equal to the thickness of the sixth insulation layer 106, for example, when the difference between the thickness of the eighth insulation layer 108 and the thickness of the sixth insulation layer 106 is within 20% of the thickness of the sixth insulation layer 106. In other words, the eighth insulation layer 108 forms the interlayer insulation film 54B.

As described above, in the structure for alleviating the concentration of an electric field on the low-voltage coil 21A at a side of the high-voltage coil 22A, the fourth high permittivity film 107A and the fifth high permittivity film 107B in the seventh insulation layer 107 and the eighth insulation layer 108 are sequentially arranged in a direction from the third end surface 26 of the low-voltage coil 21A toward the high-voltage coil 22A. That is, the relative permittivity is configured to be decreased in the direction from the third end surface 26 of the low-voltage coil 21A toward the high-voltage coil 22A.

The element insulation layer 54 around the low-voltage coil 21A has a structure for alleviating the concentration of an electric field on the low-voltage coil 21A at a side of the substrate 53. In one example, the element insulation layer 54 includes the ninth insulation layer 109 and the tenth insulation layer 110 as the structure for alleviating the concentration of an electric field on the low-voltage coil 21A at a side of the substrate 53.

The ninth insulation layer 109 has a relative permittivity higher than the relative permittivity of the sixth insulation layer 106 (the tenth insulation layer 110). The ninth insulation layer 109 includes: a high permittivity upper film 109A in contact with the fourth end surface 27 of the low-voltage coil 21A; and a high permittivity lower film 109B located at a side of the high permittivity upper film 109A opposite from the low-voltage coil 21A in the z direction.

The high permittivity upper film 109A is in contact with the sixth insulation layer 106 as well as with the fourth end surface 27 of the low-voltage coil 21A. The high permittivity upper film 109A is formed from a material including SiN. Therefore, the high permittivity upper film 109A has a relative permittivity of approximately 7.

The high permittivity upper film 109A has a thickness smaller than the thickness of the tenth insulation layer 110. The high permittivity upper film 109A has a thickness equal to the thickness of the high permittivity lower film 109B. It is considered that the high permittivity upper film 109A has a thickness equal to the thickness of the high permittivity lower film 109B, for example, when the difference between the thickness of the high permittivity upper film 109A and the thickness of the high permittivity lower film 109B is within 20% of the thickness of the high permittivity upper film 109A. The high permittivity upper film 109A has a thickness equal to the thickness of the etching stopper film 54A. It is considered that the high permittivity upper film 109A has a thickness equal to the thickness of the etching stopper film 54A, for example, when the difference between the thickness of the high permittivity upper film 109A and the thickness of the etching stopper film 54A is within 20% of the thickness of the etching stopper film 54A. Thus, that the high permittivity upper film 109A includes the etching stopper film 54A.

The high permittivity lower film 109B is in contact with the high permittivity upper film 109A. The high permittivity lower film 109B is also in contact with the tenth insulation layer 110. Therefore, the high permittivity lower film 109B is sandwiched between the high permittivity upper film 109A and the tenth insulation layer 110. The high permittivity lower film 109B has a relative permittivity lower than the relative permittivity of the high permittivity upper film 109A. In one example, the relative permittivity of the high permittivity lower film 109B is within a range greater than 3.8 and less than 7. In another example, the relative permittivity of the high permittivity lower film 109B may be within a range greater than 4 and less than 7. The high permittivity lower film 109B is formed from a material including SiON. Hence, the relative permittivity of the high permittivity lower film 109B is adjusted within the range described above in accordance with the concentration of nitrogen in SION.

The tenth insulation layer 110 is arranged closer to the substrate 53 than the low-voltage coil 21A is. The tenth insulation layer 110 is arranged separately from the low-voltage coil 21A.

The tenth insulation layer 110 has a relative permittivity lower than the relative permittivity of the ninth insulation layer 109. The tenth insulation layer 110 is formed from a material including SiO₂. Therefore, the relative permittivity of the tenth insulation layer 110 is the same as the relative permittivity of the sixth insulation layer 106 and is approximately 3.8. In the present embodiment, the tenth insulation layer 110 has a thickness smaller than the thickness of the sixth insulation layer 106.

The tenth insulation layer 110 may have a thickness also equal to the thickness of the sixth insulation layer 106. It is considered that the tenth insulation layer 110 has a thickness equal to the thickness of the sixth insulation layer 106, for example, when the difference between the thickness of the tenth insulation layer 110 and the thickness of the sixth insulation layer 106 is within 20% of the thickness of the sixth insulation layer 106. In other words, the tenth insulation layer 110 forms the interlayer insulation film 54B.

As described above, in the structure for alleviating the concentration of an electric field on the low-voltage coil 21A at a side of the substrate 53, the high permittivity upper film 109A and the high permittivity lower film 109B in the ninth insulation layer 109 and the tenth insulation layer 110 are sequentially arranged in a direction extending downward from the fourth end surface 27 of the low-voltage coil 21A. That is, the relative permittivity is configured to be decreased in the direction extending downward from the fourth end surface 27 of the low-voltage coil 21A.

### Method of Manufacturing Transformer Chip

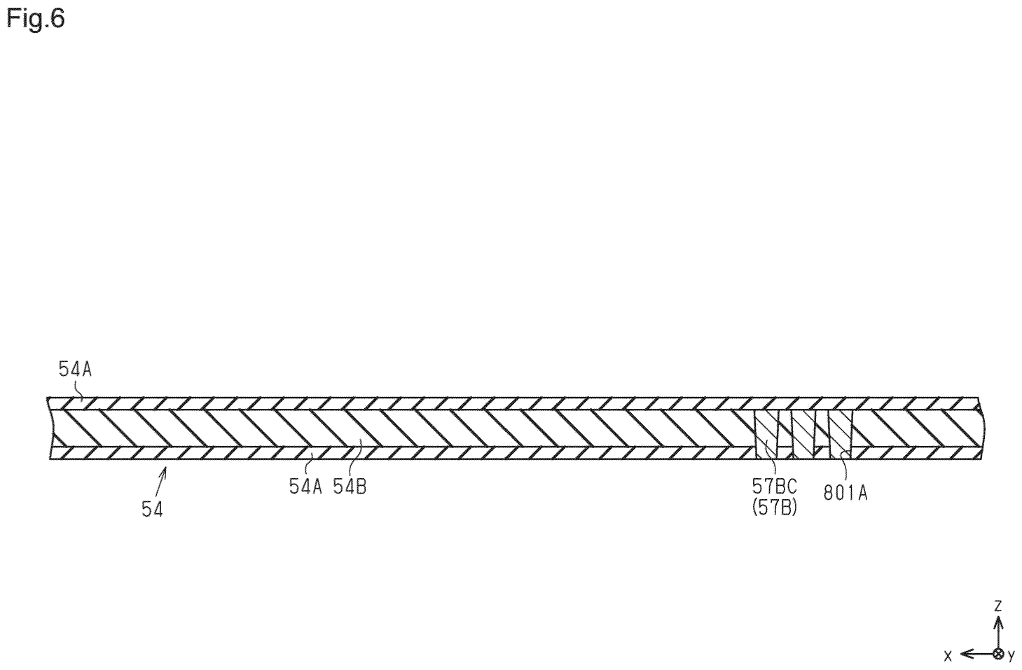

An example of a method of manufacturing the transformer chip 50 will now be described with reference to FIGS. 6 to 16. For the sake of convenience, in the following description of the manufacturing process of the transformer chip 50, the same components as those of the transformer chip 50 will be denoted by the same reference signs. FIGS. 6 to 16 are schematic cross-sectional views of the high-voltage coil 22A and the element insulation layer 54 around the high-voltage coil 22A. The reference signs that are omitted from FIGS. 6 to 16 may be found in FIG. 3.

The method of manufacturing the transformer chip 50 includes steps of: preparing the substrate 53; forming the element insulation layer 54 on the substrate 53; forming the low-voltage coils 21A and 21B and the high-voltage coils 22A and 22B in the element insulation layer 54; forming the low-voltage side connection wirings 57A and 57B and the vias 58A and 58B in the element insulation layer 54; forming the electrode pads 51 and 52 on the element insulation layer 54; and forming the protective film 55 and the passivation film 56 on the element insulation layer 54. A step of forming the element insulation layer 54 and the high-voltage coil 22A, particularly a step of manufacturing a structure for alleviating the concentration of an electric field on the high-voltage coil 22A and the high-voltage coil 22A will be described below in detail.

FIG. 6 illustrates a step of forming a part of the element insulation layer 54 on the substrate 53 and a step of forming a part of the low-voltage side connection wiring 57B on the element insulation layer 54.

The step of forming a part of the element insulation layer 54 is performed. More specifically, in this step, after an interlayer insulation film 54B is formed on the substrate of the substrate 53, etching stopper films 54A and interlayer insulation films 54B are stacked alternately. The etching stopper films 54A and the interlayer insulation films 54B are formed by, for example, chemical vapor deposition (CVD). In the present embodiment, the etching stopper films 54A are SiN films, and the interlayer insulation films 54B are SiO₂ films.

Next, the step of forming a part of the low-voltage side connection wiring 57B is performed. More specifically, in this step, after the etching stopper films 54A and the interlayer insulation films 54B are stacked, a via opening 801A is formed by, for example, etching. The via opening 801A is filled with a metal material by, for example, sputtering. One example of the metal material is Cu. Thus, a part of the second via 57BC of the low-voltage side connection wiring 57B is formed. In FIG. 6, after the second via 57BC is formed, the process returns to the step of forming a part of the element insulation layer 54 again, and an etching stopper film 54A is stacked on the interlayer insulation film 54B.

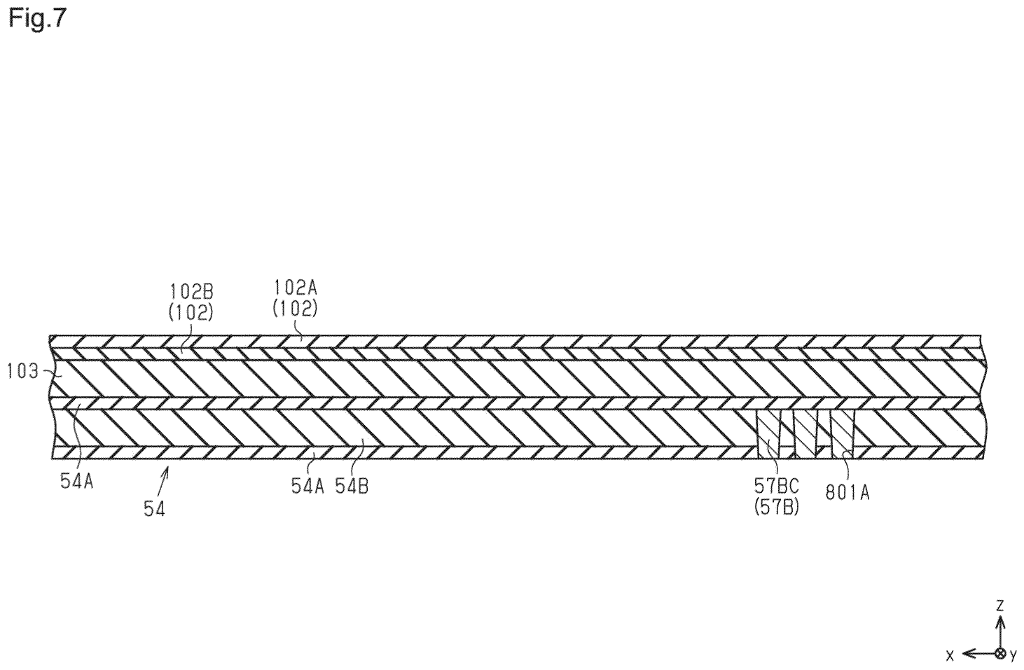

Next, FIG. 7 illustrates a step of forming a part of the element insulation layer 54, following FIG. 6. Specifically, in this step, the third insulation layer 103 is formed on the etching stopper film 54A, and a part of the second insulation layer 102 is formed on the third insulation layer 103.

More specifically, the third insulation layer 103 is formed by being deposited on the etching stopper film 54A using a CVD method. In the present embodiment, the third insulation layer 103 is a SiO₂ film. The second high permittivity film 102B is then formed by being deposited on the third insulation layer 103 using the CVD method. In the present embodiment, the second high permittivity film 102B is a SiON film. The first high permittivity film 102A is then formed by being deposited on the second high permittivity film 102B using the CVD method. In the present embodiment, the first high permittivity film 102A is a SiN film.

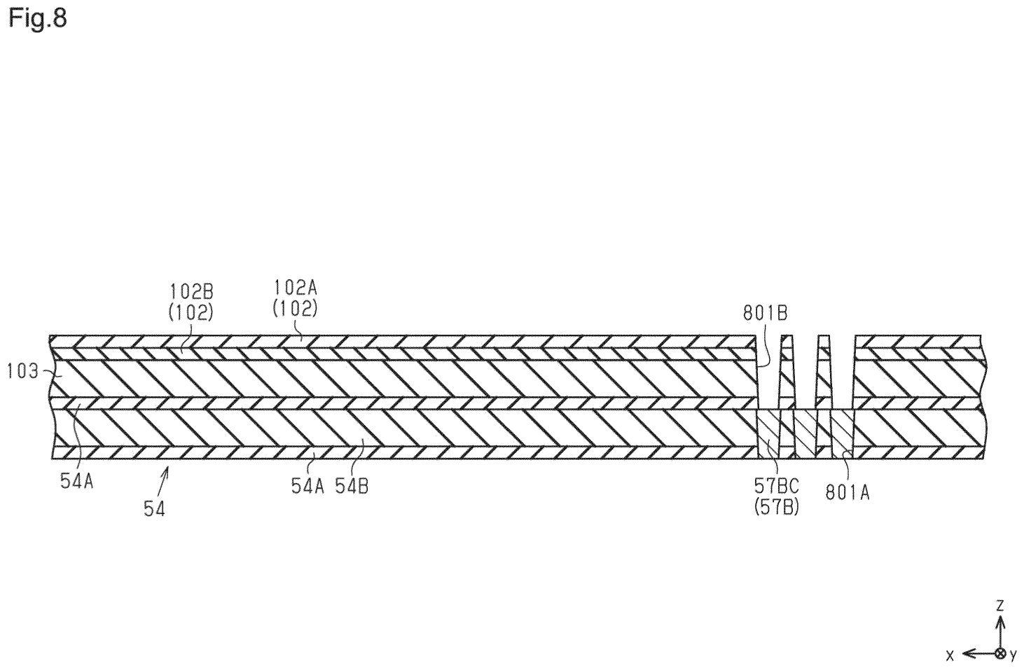

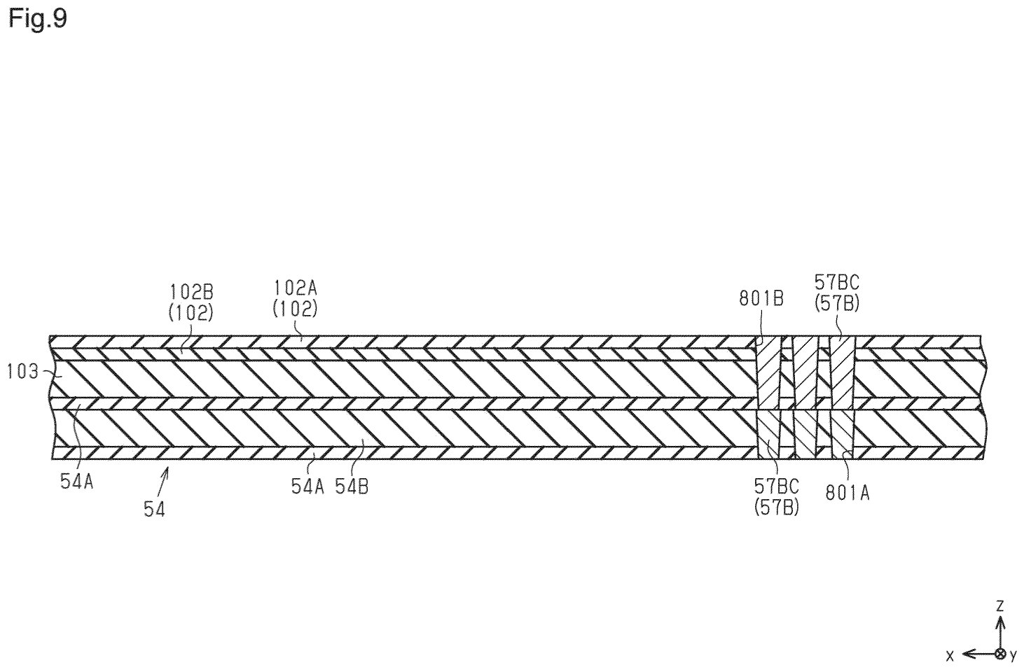

FIGS. 8 and 9 illustrate a step of forming a part of the low-voltage side connection wiring 57B in the element insulation layer 54, following FIG. 7. More specifically, as illustrated in FIG. 8, for example, etching is performed to form a via opening 801B that extends through the first high permittivity film 102A, the second high permittivity film 102B, the third insulation layer 103, and the etching stopper film 54A in the z direction. The second via 57BC in FIG. 7 is exposed through the via opening 801B. The via opening 801B is filled with a metal material by, for example, sputtering, as illustrated in FIG. 9. One example of the metal material is Cu. Thus, the second via 57BC of the low-voltage side connection wiring 57B is formed.

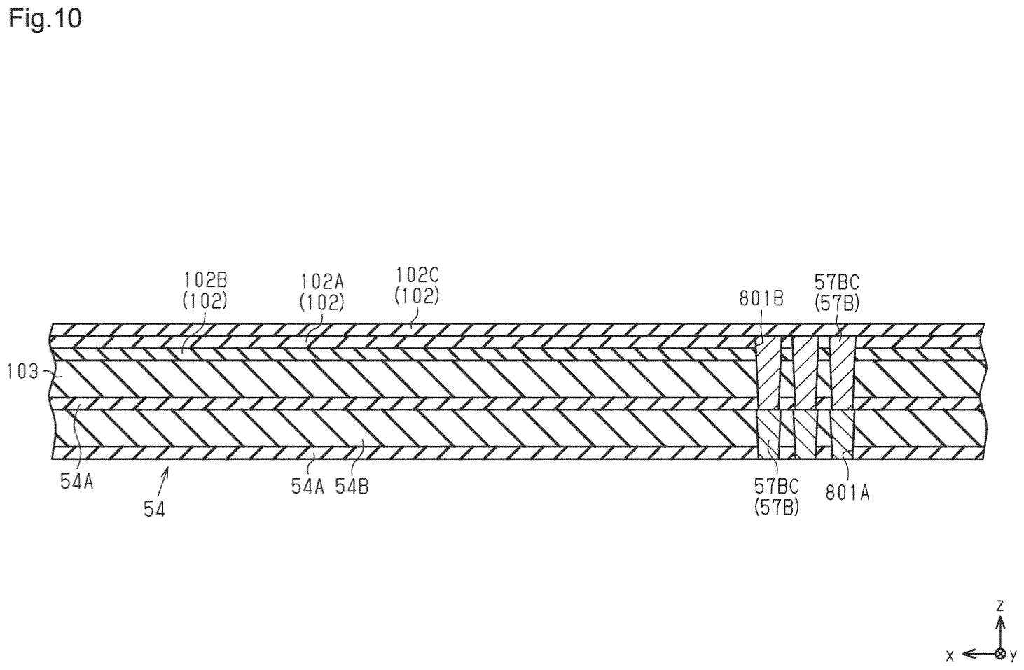

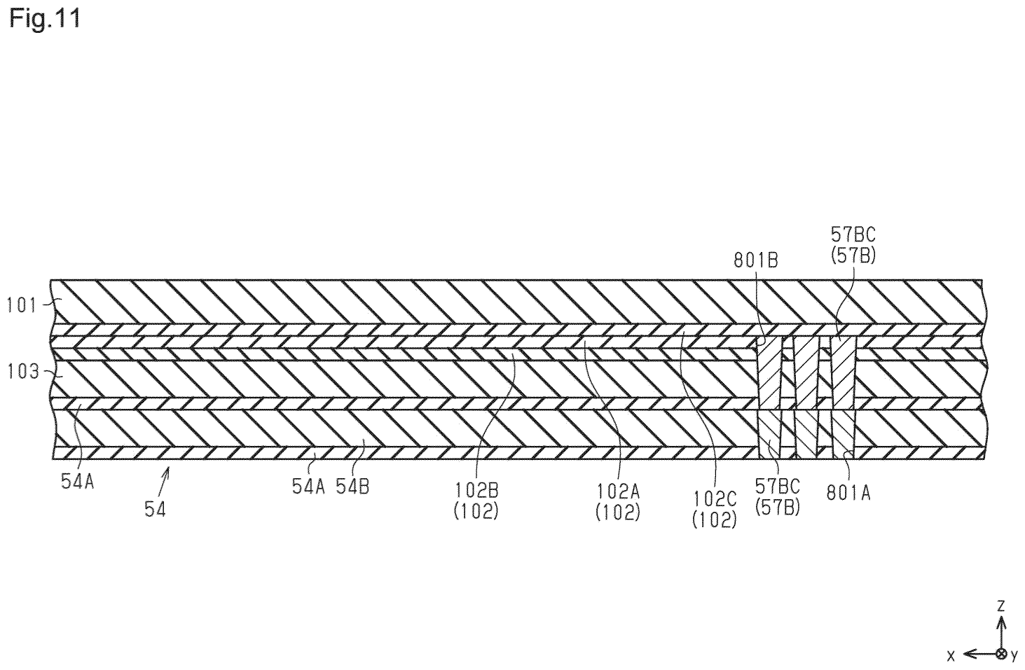

FIGS. 10 and 11 illustrate a step of forming a part of the element insulation layer 54, following FIG. 9. More specifically, as illustrated in FIG. 10, the third high permittivity film 102C is formed by being deposited on the first high permittivity film 102A and the second via 57BC using, for example, the CVD method. In the present embodiment, the third high permittivity film 102C is a SiN film. Thus, in other words, the third high permittivity film 102C is the etching stopper film 54A. The first insulation layer 101 is then formed on the third high permittivity film 102C using, for example, the CVD method as illustrated in FIG. 11. In the present embodiment, the first insulation layer 101 is a SiO₂ film. Thus, in other words, the first insulation layer 101 is the interlayer insulation film 54B.

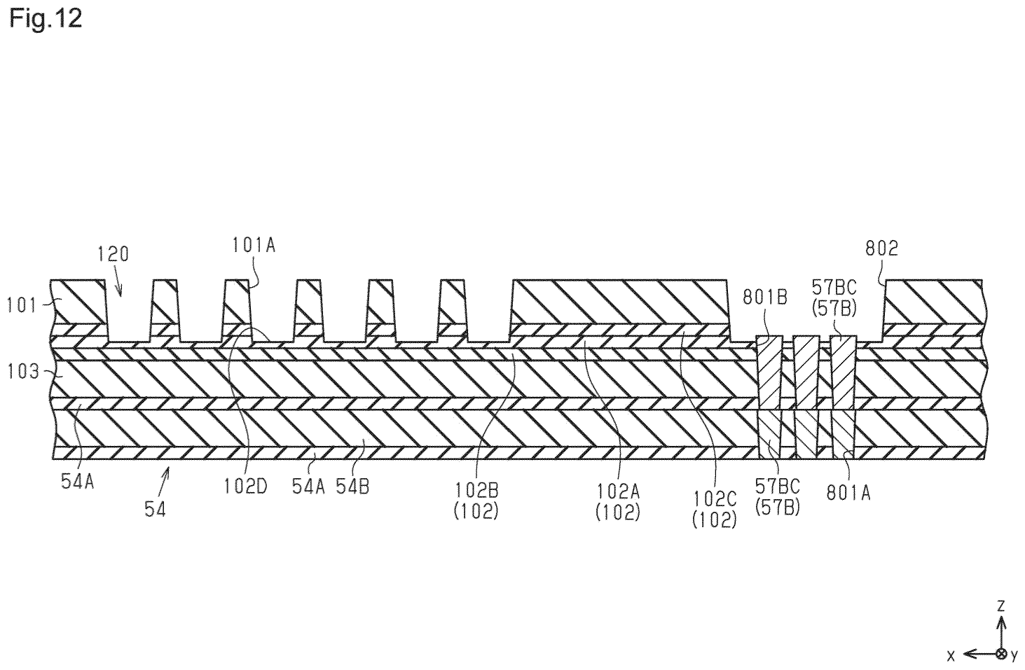

FIG. 12 illustrates a step of forming the high-voltage coil 22A and a step of forming a part of the low-voltage side connection wiring 57B, following FIG. 11. More specifically, the first trench 120 is formed in the first insulation layer 101 and the second insulation layer 102 by, for example, etching. The first trench 120 extends through both of the first insulation layer 101 and the third high permittivity film 102C in the z direction. By contrast, the first trench 120 does not extend through the first high permittivity film 102A in the z direction. Thus, a through hole 101A is formed in the first insulation layer 101, and a groove 102D is formed in the first high permittivity film 102A. The wiring opening 802 is also formed in the first insulation layer 101 and the second insulation layer 102 by, for example, etching. The wiring opening 802 is formed by the same process as the process for the first trench 120. The second via 57BC of the low-voltage side connection wiring 57B is exposed in the wiring opening 802.

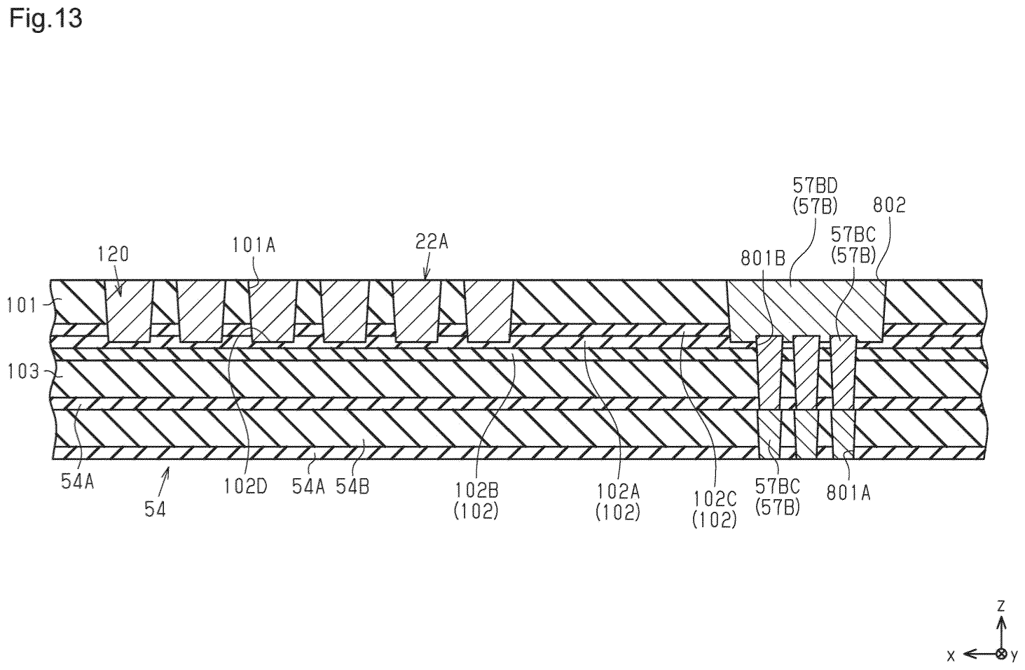

FIG. 13 illustrates a step of forming the high-voltage coil 22A and a step of forming a part of the low-voltage side connection wiring 57B, following FIG. 12. More specifically, in this step, the first trench 120 and the wiring opening 802 are filled with a metal material by, for example, sputtering. One example of the metal material is Cu. Thus, the high-voltage coil 22A and the second wiring 57BD of the low-voltage side connection wiring 57B are formed. That is, the step of forming the high-voltage coil 22A and the step of forming a part of the low-voltage side connection wiring 57B are performed at the same time.

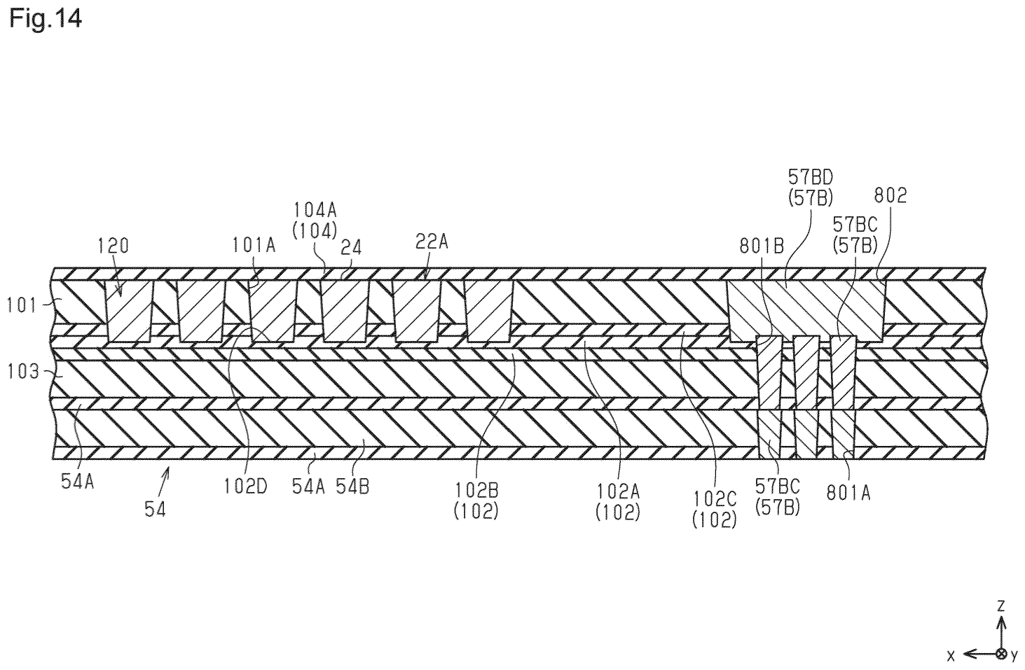

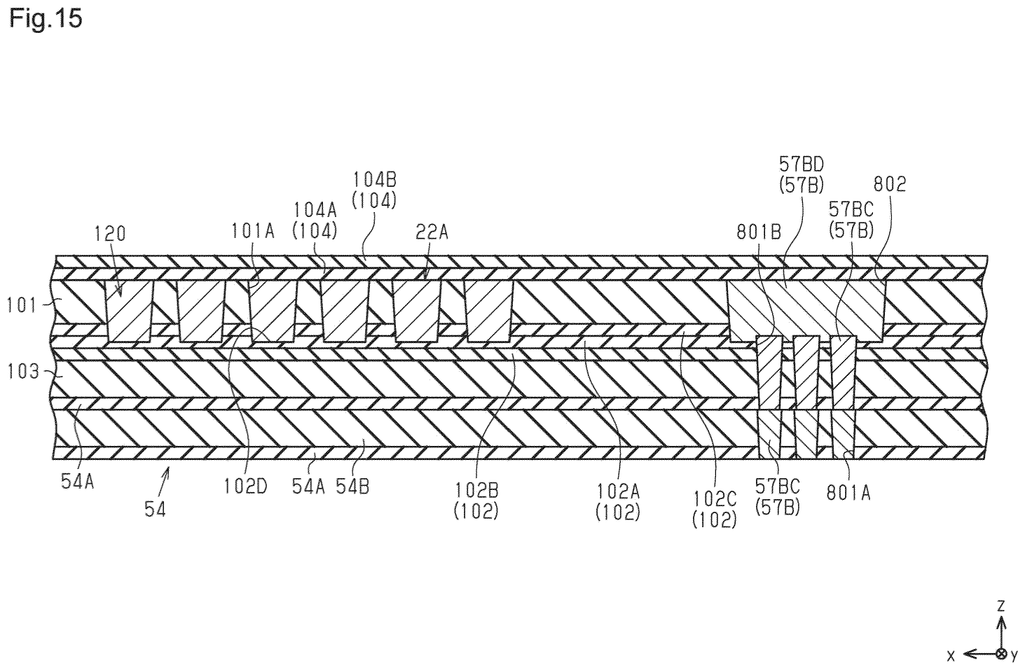

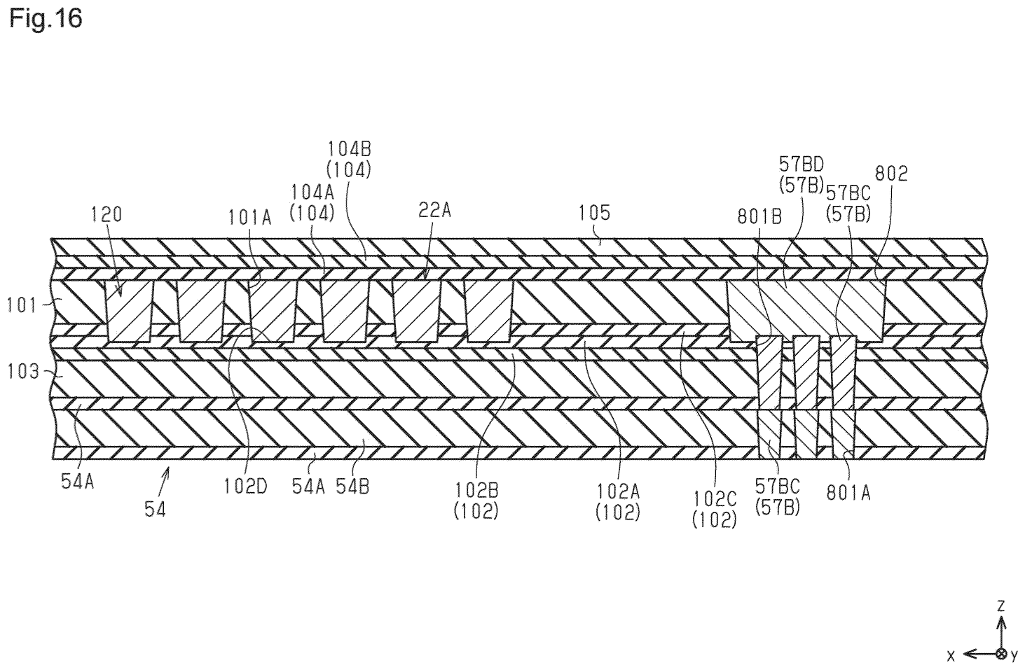

FIGS. 14 to 16 each illustrate a step of forming a part of the element insulation layer 54, following FIG. 13. More specifically, as illustrated in FIG. 14, the high permittivity lower film 104A of the fourth insulation layer 104 is formed by being deposited on the second end surface 24 of the low-voltage coil 21A, the second wiring 57BD of the low-voltage side connection wiring 57B, and the first insulation layer 101 using, for example, the CVD method. The high permittivity lower film 104A is a SiN film. Thus, in other words, the high permittivity lower film 104A is the etching stopper film 54A. The high permittivity upper film 104B is then formed by being deposited on the high permittivity lower film 104A using, for example, the CVD method as illustrated in FIG. 15. The high permittivity upper film 104B is a SiON film. The fifth insulation layer 105 is then formed by being deposited on the high permittivity upper film 104B, using, for example, the CVD method as illustrated in FIG. 16. The fifth insulation layer 105 is a SiO₂ film. Thus, in other words, the fifth insulation layer 105 is the interlayer insulation film 54B.

Although not illustrated, the low-voltage coil 21A and the element insulation layer 54 around the low-voltage coil 21A are also formed in the same manner as the high-voltage coil 22A and the element insulation layer 54 around the high-voltage coil 22A. The low-voltage coil 21A and the element insulation layer 54 around the low-voltage coil 21A are formed in a step prior to the step of forming the high-voltage coil 22A and the element insulation layer 54 around the high-voltage coil 22A.

Subsequently, a step of forming the vias 58A and 58B, a step of forming the electrode pads 51 and 52 on the element insulation layer 54, and a step of forming the protective film 55 and the passivation film 56 on the element insulation layer 54 are sequentially performed.

In the step of forming the vias 58A and 58B, a via opening is formed in the element insulation layer 54, and then the via opening is filled with a metal material in the same manner as the step of forming the low-voltage side connection wirings 57A and 57B. One example of the metal material is Cu.

Each of the electrode pads 51 and 52 is provided on the element head surface 54s of the element insulation layer 54 by, for example, sputtering. Each of the electrode pads 51 and 52 is formed of, for example, Al.

Next, the protective film 55 is formed by being deposited on the element insulation layer 54 and each of the electrode pads 51 and 52 using, for example, the CVD method. The passivation film 56 is then formed by being deposited on the protective film 55 using, for example, the CVD method. Subsequently, for example, etching is performed to form openings that expose the electrode pads 51 and 52 from both the protective film 55 and the passivation film 56. The transformer chip 50 is manufactured through the steps described above.

### Method of Manufacturing Signal Transmitting Device

A method of manufacturing the signal transmitting device 10 will now be described. In the following description, the reference signs related to the signal transmitting device 10 are used with reference to FIG. 2.

The method for manufacturing the signal transmitting device 10 includes: a step of preparing the transformer chip 50, the first chip 30, and the second chip 40; a step of preparing a lead frame; a step of mounting the first chip 30 on the primary-side die pad 60; a step of mounting the transformer chip 50 and the second chip 40 on the secondary-side die pad 70; a step of forming a wire W; a step of forming the encapsulation resin 80; and a step of singulating.

In the step of preparing a lead frame, a lead frame, in which the primary-side die pad 60, a first lead, the secondary-side die pad 70, and a second lead are integrated, is prepared.

In the step of mounting the first chip 30 on the primary-side die pad 60, the first chip 30 is die-bonded to the primary-side die pad 60. In the step of mounting the transformer chip 50 and the second chip 40 on the secondary-side die pad 70, the transformer chip 50 and the second chip 40 are die-bonded to the secondary-side die pad 70.

In the step of forming a wire W, wire bonding device is used to form a wire W connecting the first electrode pad 31 on the first chip 30 to the first lead, a wire W connecting the second electrode pad 32 on the first chip 30 to the first electrode pad 51 on the transformer chip 50, a wire W connecting the second electrode pad 52 on the transformer chip 50 to the first electrode pad 41 on the second chip 40, and a wire W connecting the second electrode pad 42 on the second chip 40 to the second lead.

In the step of forming the encapsulation resin 80, for example, compression molding is performed to form a resin layer that encapsulates the first chip 30, the second chip 40, the transformer chip 50, and the wires W. The resin layer is, for example, a black epoxy resin.

In the singulating step, the lead frame and the resin layer are cut by, for example, dicing. Thus, the first lead, the second lead, and the encapsulation resin 80 are formed. The signal transmitting device 10 is manufactured through the steps described above. Effects

According to the present embodiment, the following effects may be obtained.

(1-1) The transformer chip 50 includes: an element insulation layer 54; high-voltage coils 22A and 22B embedded in the element insulation layer 54; and low-voltage coils 21A and 21B embedded in the element insulation layer 54 and opposed to the respective high-voltage coils 22A and 22B in the z direction. Each of the high-voltage coils 22A and 22B includes a first end surface 23 facing toward corresponding one of the low-voltage coils 21A and 21B in the z direction, a second end surface 24 opposite to the first end surface 23, and a first side surface 25. The element insulation layer 54 includes a third insulation layer 103, a second insulation layer 102 stacked on the third insulation layer 103 and having a relative permittivity higher than the relative permittivity of the third insulation layer 103, and a first insulation layer 101 stacked on the second insulation layer 102 and having a relative permittivity lower than the relative permittivity of the second insulation layer 102. Each of the high-voltage coils 22A and 22B is embedded in the first insulation layer 101 such that the first end surface 23 is in contact with the second insulation layer 102.

With this configuration, the second insulation layer 102 having a relative permittivity higher than the relative permittivity of the first insulation layer 101 covers the first end surface 23 of the high-voltage coils 22A and 22B, thereby reducing the intensity of an electric field on the first end surface 23. This alleviates the concentration of the electric field on the end portion of the high-voltage coils 22A and 22B located at the side of the low-voltage coils 21A and 21B. In other words, the concentration of the electric field in the region between the high-voltage coil 22A (22B) and the low-voltage coil 21A (21B) is alleviated.

(1-2) The second insulation layer 102 covers the lower end portion 25A of the first side surface 25 of the high-voltage coils 22A and 22B, the lower end portion 25A forming a corner with the first end surface 23.

With this configuration, the intensity of the electric field tends to be high on the lower end portion 25A of the high-voltage coils 22A and 22B, and the lower end portion 25A is covered by the second insulation layer 102 having a high relative permittivity. Thus, the concentration of an electric field on the end portion of the high-voltage coils 22A and 22B locate at the side of the low-voltage coils 21A and 21B is effectively alleviated.

(1-3) The second insulation layer 102 includes: a first high permittivity film 102A in contact with the first end surface 23 of the high-voltage coils 22A and 22B; and a second high permittivity film 102B having a relative permittivity lower than the relative permittivity of the first high permittivity film 102A and in contact with the third insulation layer 103.

With this configuration, the first high permittivity film 102A, the second high permittivity film 102B, and the third insulation layer 103 are sequentially disposed with respect to the first end surface 23 of the high-voltage coils 22A and 22B in the second insulation layer 102. The relative permittivity is decreased in the order of the first high permittivity film 102A, the second high permittivity film 102B, and the third insulation layer 103. That is, the relative permittivity of the second insulation layer 102 gradually decreases as the distance from the first end surface 23 increases in a direction from the high-voltage coils 22A and 22B toward the low-voltage coils 21A and 21B. This further reduces the intensity of the electric field on the first end surface 23 of the high-voltage coils 22A and 22B. Therefore, the concentration of the electric field on the end portion of the high-voltage coils 22A and 22B located at the side of the low-voltage coils 21A and 21B is effectively alleviated.

(1-4) The second insulation layer 102 includes a third high permittivity film 102C having a relative permittivity higher than the relative permittivity of the second high permittivity film 102B. The third high permittivity film 102C is arranged on the first high permittivity film 102A.

With this configuration, the third high permittivity film 102C covers a part of the first side surface 25 of the high-voltage coils 22A and 22B in the z direction, thereby reducing the intensity of the electric field on the first side surface 25 of the high-voltage coils 22A and 22B. Thus, the concentration of an electric field on the first side surface 25 of the high-voltage coils 22A and 22B is alleviated.

(1-5) The element insulation layer 54 includes: a fourth insulation layer 104 arranged on the first insulation layer 101 so as to contact the second end surface 24 of the high-voltage coils 22A and 22B, and a fifth insulation layer 105 stacked on the fourth insulation layer 104. The fourth insulation layer 104 has a relative permittivity higher than the relative permittivity of the first insulation layer 101, and the fifth insulation layer 105 has a relative permittivity lower than the relative permittivity of the fourth insulation layer 104.

With this configuration, the fourth insulation layer 104 and the fifth insulation layer 105 are sequentially stacked with respect to the second end surface 24 of the high-voltage coils 22A and 22B. The relative permittivity is decreased in the order of the fourth insulation layer 104 to the fifth insulation layer 105. That is, the relative permittivity of the element insulation layer 54 gradually decreases as the distance from the second end surface 24 increases in a direction from the high-voltage coils 22A and 22B toward the element head surface 54s of the element insulation layer 54. This reduces the intensity of the electric field on the second end surface 24 of the high-voltage coils 22A and 22B. Thus, the concentration of the electric field on the end portion of the high-voltage coils 22A and 22B located at the side opposite to the low-voltage coils 21A and 21B is alleviated.

(1-6) The fourth insulation layer 104 includes: a high permittivity lower film 104A in contact with the second end surface 24 of the high-voltage coils 22A and 22B; and a high permittivity upper film 104B formed on the high permittivity lower film 104A and in contact with the fifth insulation layer 105. The relative permittivity of the high permittivity upper film 104B is lower than the relative permittivity of the high permittivity lower film 104A.

With this configuration, the high permittivity lower film 104A and the high permittivity upper film 104B are sequentially stacked in the fourth insulation layer 104 with respect to the second end surface 24 of the high-voltage coils 22A and 22B. The relative permittivity is decreased in the order of the high permittivity lower film 104A and the high permittivity upper film 104B. That is, the relative permittivity of the fourth insulation layer 104 gradually decreases as the distance from the second end surface 24 increases in a direction from the high-voltage coils 22A and 22B toward the element head surface 54s of the element insulation layer 54. This further reduces the intensity of the electric field on the second end surface 24 of the high-voltage coils 22A and 22B. Thus, the concentration of the electric field on the end portion of the high-voltage coils 22A and 22B located at the side opposite to the low-voltage coils 21A and 21B is alleviated.

(1-7) The low-voltage coils 21A and 21B include: a third end surface 26 facing toward the high-voltage coils 22A and 22B in the z direction, a fourth end surface 27 located opposite to the third end surface 26; and a second side surface 28. The element insulation layer 54 includes: a sixth insulation layer 106; a seventh insulation layer 107 stacked on the sixth insulation layer 106 and having a relative permittivity higher than the relative permittivity of the sixth insulation layer 106; and an eighth insulation layer 108 stacked on the seventh insulation layer 107 and having a relative permittivity lower than the relative permittivity of the seventh insulation layer 107. The low-voltage coils 21A and 21B is embedded in the sixth insulation layer 106 so that the third end surface 26 is in contact with the seventh insulation layer 107.

With this configuration, because the seventh insulation layer 107 having a relative permittivity higher than the relative permittivity of the sixth insulation layer 106 covers the third end surface 26 of the low-voltage coils 21A and 21B, thereby reducing the intensity of the electric field on the third end surface 26. Thus, the concentration of the electric field on the end portion of the low-voltage coils 21A and 21B located at the side of the high-voltage coils 22A and 22B is alleviated. In other words, the concentration of the electric field in the region between the high-voltage coil 22A (22B) and the low-voltage coil 21A (21B) is alleviated.

(1-8) The seventh insulation layer 107 includes: a fourth high permittivity film 107A in contact with the third end surface 26 of the low-voltage coils 21A and 21B; and a fifth high permittivity film 107B in contact with the eighth insulation layer 108. The relative permittivity of the fifth high permittivity film 107B is lower than the relative permittivity of the fourth high permittivity film 107A.

With this configuration, the fourth high permittivity film 107A and the fifth high permittivity film 107B are sequentially stacked in the seventh insulation layer 107 with respect to the third end surface 26 of the low-voltage coils 21A and 21B. The relative permittivity is decreased in the order of the fourth high permittivity film 107A and the fifth high permittivity film 107B. That is, the relative permittivity of the seventh insulation layer 107 gradually decreases as the distance from the third end surface 26 increases in a direction from the low-voltage coils 21A and 21B toward the high-voltage coils 22A and 22B. This reduces the intensity of the electric field on the third end surface 26 of the low-voltage coils 21A and 21B. Thus, the concentration of the electric field on the end portion of the low-voltage coils 21A and 21B located at the side of the high-voltage coils 22A and 22B is effectively alleviated.

(1-9) The seventh insulation layer 107 includes: a sixth high permittivity film 107C having a relative permittivity higher than the relative permittivity of the fifth high permittivity film 107B. The fourth high permittivity film 107A is sandwiched between the fifth high permittivity film 107B and the sixth high permittivity film 107C.

With this configuration, the sixth high permittivity film 107C has a relative permittivity higher than the relative permittivity of the fifth high permittivity film 107B and increases the proportion of the seventh insulation layer 107 occupied by the high permittivity film having a higher relative permittivity than the fifth high permittivity film 107B. Thus, the seventh insulation layer 107 further reduces the intensity of the electric field on the third end surface 26 of the low-voltage coils 21A and 21B. Accordingly, the concentration of the electric field on the end portion of the low-voltage coils 21A and 21B located at the side of the high-voltage coils 22A and 22B is effectively alleviated.

In addition, among the high permittivity films included in the seventh insulation layer 107, the fifth high permittivity film 107B, having a low relative permittivity, is in contact with the eighth insulation layer 108. With this configuration, the relative permittivity of the element insulation layer 54 gradually decreases as the distance from the third end surface 26 increases in a direction from the low-voltage coils 21A and 21B toward the high-voltage coils 22A and 22B through the seventh insulation layer 107. This further reduces the intensity of the electric field on the third end surface 26 of the low-voltage coils 21A and 21B. Thus, the concentration of the electric field on the end portion of the low-voltage coils 21A and 21B located at the side of the high-voltage coils 22A and 22B is alleviated effectively.

(1-10) The element insulation layer 54 includes: a ninth insulation layer 109 in contact with the fourth end surface 27 of the low-voltage coils 21A and 21B; and a tenth insulation layer 110 located opposite to the sixth insulation layer 106 with respect to the ninth insulation layer 109. The ninth insulation layer 109 has a relative permittivity higher than the relative permittivity of the sixth insulation layer 106. The relative permittivity of the tenth insulation layer 110 is lower than the relative permittivity of the ninth insulation layer 109.

With this configuration, the ninth insulation layer 109 and the tenth insulation layer 110 are sequentially disposed with respect to the fourth end surface 27 of the low-voltage coils 21A and 21B. The relative permittivity is decreased in the order of the ninth insulation layer 109 and the tenth insulation layer 110. That is, the relative permittivity of the element insulation layer 54 gradually decreases as the distance from the fourth end surface 27 increases in a direction from the low-voltage coils 21A and 21B toward the element back surface 54r of the element insulation layer 54. This reduces the intensity of the electric field on the fourth end surface 27 of the low-voltage coils 21A and 21B. Thus, the concentration of the electric field on the end portion of the low-voltage coils 21A and 21B located at the side of the substrate 53 is alleviated.

(1-11) The ninth insulation layer 109 includes a high permittivity upper film 109A in contact with the fourth end surface 27 of the low-voltage coils 21A and 21B, and a high permittivity lower film 109B located opposite to the sixth insulation layer 106 with respect to the high permittivity upper film 109A and in contact with the tenth insulation layer 110.

With this configuration, the ninth insulation layer 109 includes the high permittivity upper film 109A and the high permittivity lower film 109B that are sequentially arranged with respect to the fourth end surface 27 of the low-voltage coils 21A and 21B. The relative permittivity is decreased in the order of the high permittivity upper film 109A and the high permittivity lower film 109B. That is, the relative permittivity of the ninth insulation layer 109 gradually decreases as the distance from the fourth end surface 27 increases in a direction from the low-voltage coils 21A and 21B toward the element back surface 54r of the element insulation layer 54. This reduces the intensity of the electric field on the fourth end surface 27 of the low-voltage coils 21A and 21B. Thus, the concentration of the electric field on the end portion of the low-voltage coils 21A and 21B at the side of the substrate 53 is effectively alleviated.

(1-12) The signal transmitting device 10 includes a first chip 30 including a primary-side circuit 13, a transformer chip 50, and a second chip 40 including a secondary-side circuit 14 configured to perform at least one of reception of a signal and transmission of a signal with the primary-side circuit 13 through the transformer chip 50. The transformer chip 50 includes an element insulation layer 54, high-voltage coils 22A and 22B embedded in the element insulation layer 54, and low-voltage coils 21A and 21B embedded in the element insulation layer 54 and opposed to the respective high-voltage coils 22A and 22B in the z direction. Each of the high-voltage coils 22A and 22B includes a first end surface 23 facing toward corresponding one of the low-voltage coils 21A and 21B in the z direction, a second end surface 24 located opposite to the first end surface 23, and a first side surface 25. The element insulation layer 54 includes a third insulation layer 103, a second insulation layer 102 stacked on the third insulation layer 103 and having a relative permittivity higher than the relative permittivity of the third insulation layer 103, and a first insulation layer 101 stacked on the second insulation layer 102 and having a relative permittivity lower than the relative permittivity of the second insulation layer 102. Each of the high-voltage coils 22A and 22B is embedded in the first insulation layer 101 such that the first end surface 23 is in contact with the second insulation layer 102.

With this configuration, the second insulation layer 102, which has a relative permittivity higher than the relative permittivity of the first insulation layer 101, covers the first end surface 23 of the high-voltage coils 22A and 22B, thereby reducing the intensity of the electric field on the first end surfaces 23. This alleviates the concentration of an electric field on the end portion of the high-voltage coils 22A and 22B located at the side of the low-voltage coils 21A and 21B. In other words, the concentration of the electric field in the region between the high-voltage coil 22A (22B) and the low-voltage coil 21A (21B) is alleviated.

### Second Embodiment

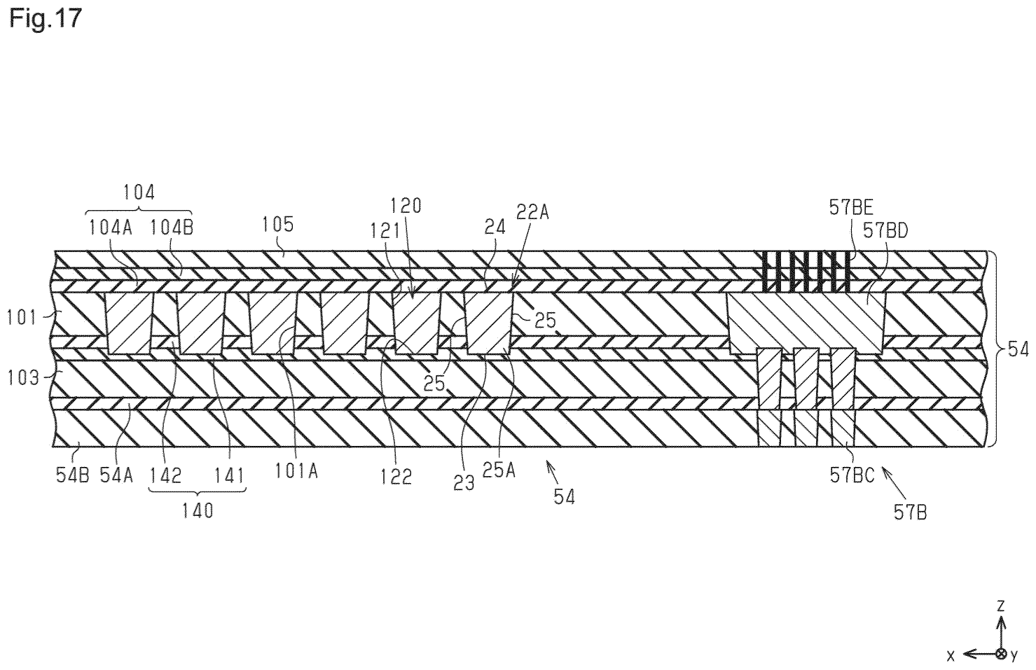

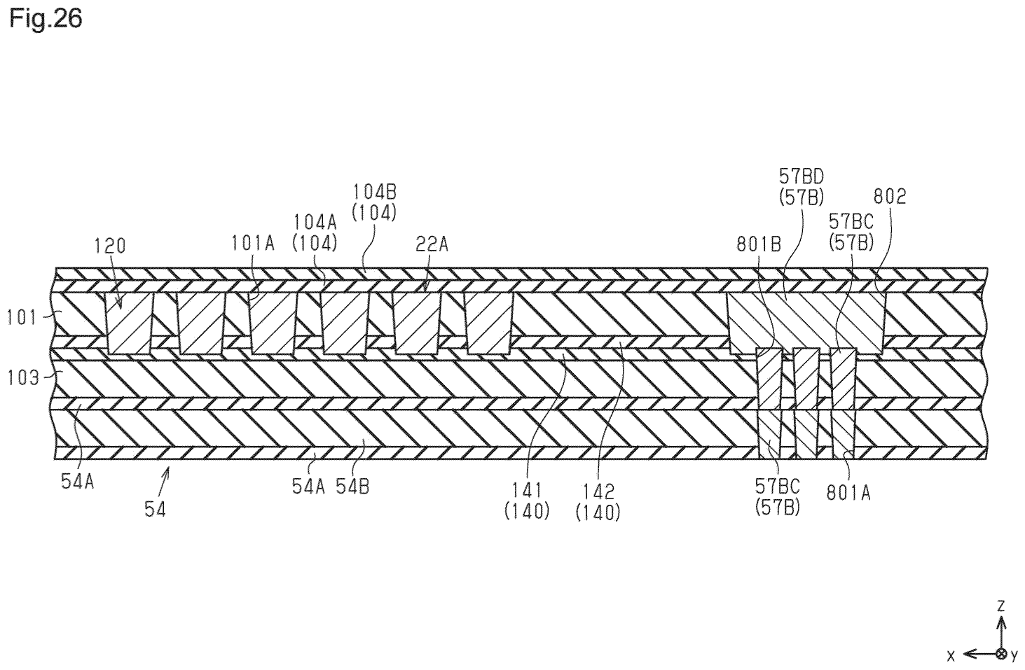

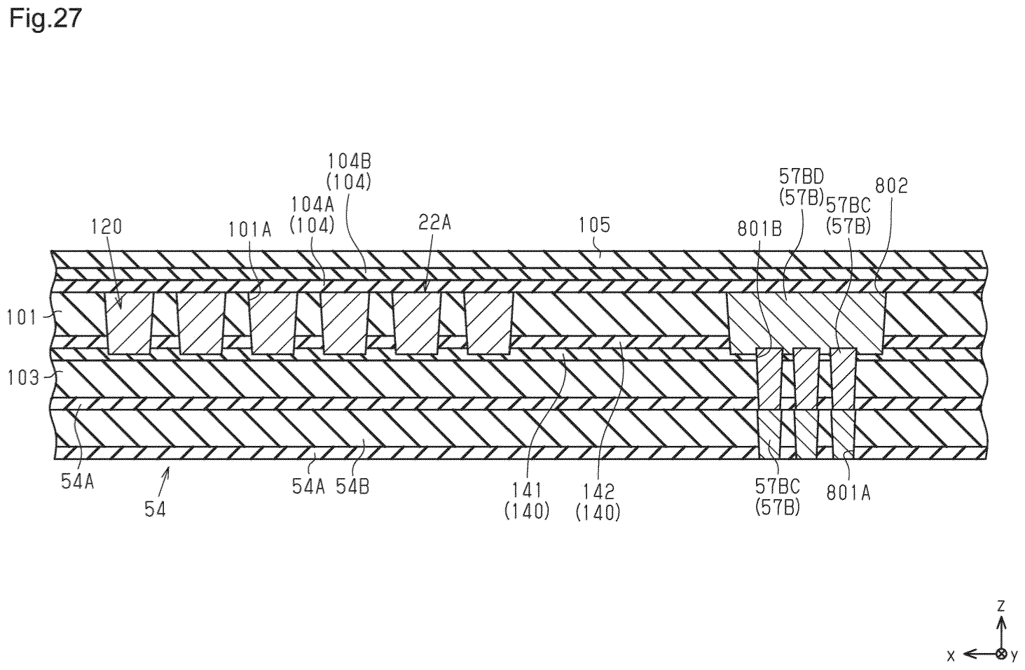

The configuration of a transformer chip 50 according to a second embodiment will now be described with reference to FIGS. 17 to 27. The transformer chip 50 according to the present embodiment differs from the transformer chip 50 according to the first embodiment in the structure for alleviating the concentration of an electric field on the high-voltage coil 22A and the low-voltage coil 21A. In the following description, the same components as those according to the first embodiment are denoted by the same reference signs, and the description thereof will be omitted.

### Configuration of Transformer Chip

As illustrated in FIG. 17, in the present embodiment, the element insulation layer 54 includes a second insulation layer 140 instead of the second insulation layer 102 (refer to FIG. 4). The second insulation layer 140 covers the first end surface 23 and the lower end portion 25A of the first side surface 25 of the high-voltage coil 22A. In the present embodiment, the second insulation layer 140 is in contact with both of the first end surface 23 and the lower end portion 25A of the first side surface 25.

The second insulation layer 140 includes a first high permittivity film 141 and a second high permittivity film 142.

The first high permittivity film 141 covers the first end surface 23 and the lower end portion 25A of the first side surface 25 of the high-voltage coil 22A. In the present embodiment, the first high permittivity film 141 is in contact with both of the first end surface 23 and the lower end portion 25A of the first side surface 25. The first high permittivity film 141 is arranged on the third insulation layer 103. In the present embodiment, the first high permittivity film 141 is in contact with the third insulation layer 103. The first high permittivity film 141 has a thickness equal to the thickness of the second high permittivity film 142. It is considered that the first high permittivity film 141 has a thickness equal to the thickness of the second high permittivity film 142, for example, when the difference between the thickness of the first high permittivity film 141 and the thickness of the second high permittivity film 142 is within 20% of the thickness of the first high permittivity film 141. The first high permittivity film 141 has a relative permittivity higher than the relative permittivity of the third insulation layer 103. In one example, the relative permittivity of the first high permittivity film 141 is within a range greater than 3.8 and less than 7. In another example, the first high permittivity film 141 may have a relative permittivity within a range greater than 4 and less than 7. The first high permittivity film 141 is formed from a material including SiON. Hence, the relative permittivity of the first high permittivity film 141 is adjusted within the range described above in accordance with the concentration of nitrogen in SiON.

The second high permittivity film 142 is arranged on the first high permittivity film 141. In the present embodiment, the second high permittivity film 142 is in contact with the first high permittivity film 141. The second high permittivity film 142 covers a part of the first side surface 25 of the high-voltage coil 22A located above the lower end portion 25A. The first insulation layer 101 is arranged on the second high permittivity film 142. In the present embodiment, the second high permittivity film 142 is in contact with the first insulation layer 101.

The second high permittivity film 142 has a relative permittivity higher than the relative permittivity of the first high permittivity film 141. The second high permittivity film 142 is formed from a material including SiN. Thus, the second high permittivity film 142 has a relative permittivity of approximately 7. In other words, the second high permittivity film 142 is the etching stopper film 54A.

As described above, in the structure for alleviating the concentration of the electric field in the region between the high-voltage coil 22A and the low-voltage coil 21A, the first high permittivity film 141 of the second insulation layer 140 and the third insulation layer 103 sequentially are arranged in a direction from the first end surface 23 of the high-voltage coil 22A toward the low-voltage coil 21A. That is, the relative permittivity is configured to be decreased in the direction from the first end surface 23 of the high-voltage coil 22A toward the low-voltage coil 21A.

Although not illustrated, the structure for alleviating the concentration of an electric field on the high-voltage coil 22A at the side of the low-voltage coil 21A may be changed in the same manner. That is, the configuration of the seventh insulation layer 107 including three layers of high permittivity films (refer to FIG. 5) according to the first embodiment may be changed to a configuration including two layers of the high permittivity films as in the second insulation layer 140.

### Method of Manufacturing Transformer Chip

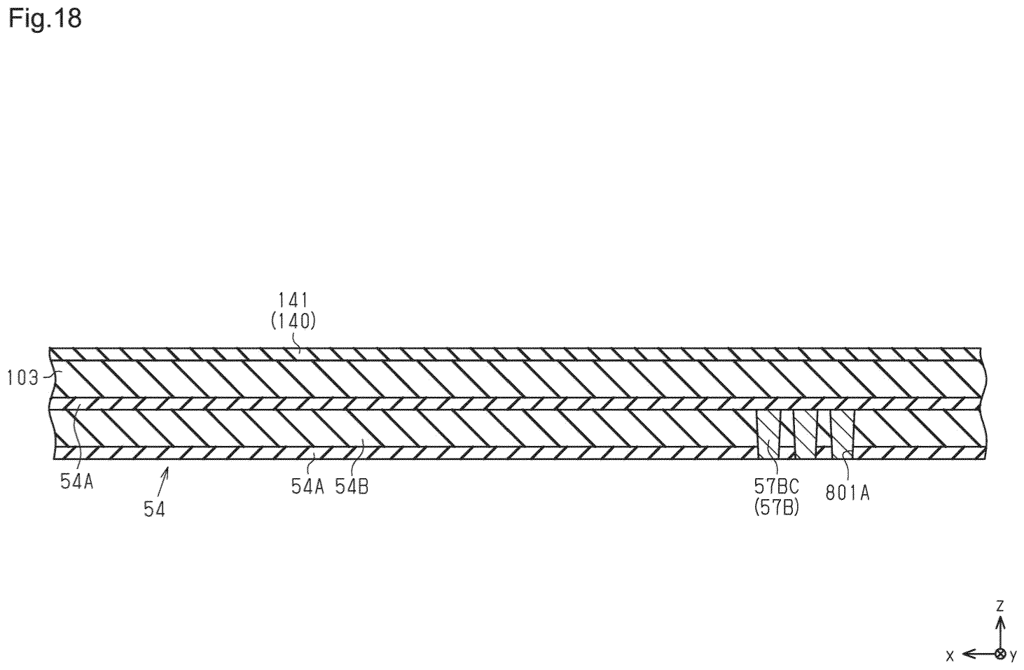

A method of manufacturing the transformer chip 50 according to the present embodiment will now be described with reference to FIGS. 18 to 27. The method of manufacturing the transformer chip 50 according to the present embodiment includes steps that are similar to those in the method of manufacturing the transformer chip 50 according to the first embodiment. In the following description, the method of manufacturing the high-voltage coil 22A and the element insulation layer 54 around the high-voltage coil 22A will be described in detail.

FIG. 18 illustrates a step of forming a part of the element insulation layer 54 on the substrate 53 and a step of forming a part of the low-voltage side connection wiring 57B on the element insulation layer 54. In the step of forming a part of the element insulation layer 54, the etching stopper film 54A and the interlayer insulation film 54B are formed in the same manner as in the first embodiment. In the step of forming a part of the low-voltage side connection wiring 57B, a part of the via opening 801A and a part of the second via 57BC are formed in the same manner as in the first embodiment.

In the step of forming a part of the element insulation layer 54, the third insulation layer 103 is formed in the same manner as in the first embodiment. In the present embodiment, the third insulation layer 103 is a SiO₂ film. Thus, in other words, the third insulation layer 103 includes the interlayer insulation film 54B. The first high permittivity film 141 of the second insulation layer 140 is then formed by being deposited on the third insulation layer 103 using, for example, the CVD method. In the present embodiment, the first high permittivity film 141 is a SiON film.

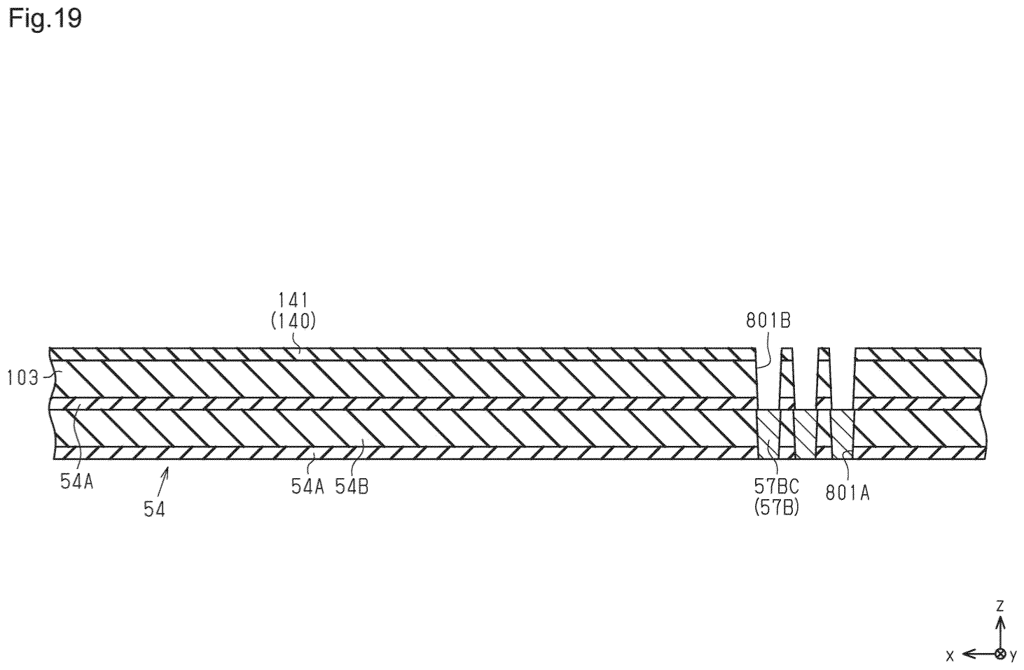

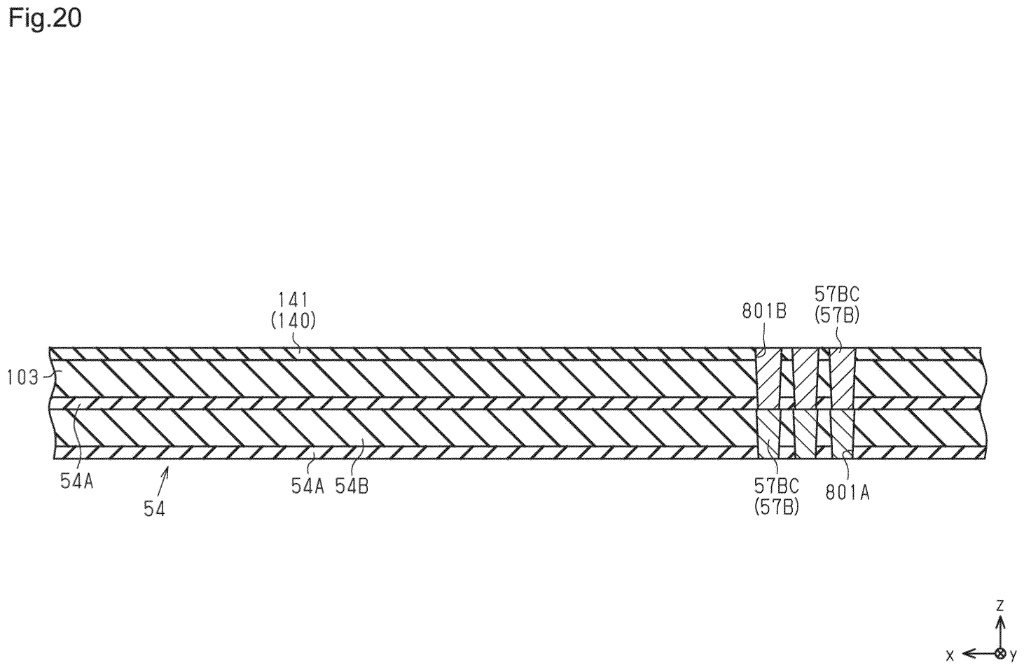

FIGS. 19 and 20 illustrate a step of forming a part of the low-voltage side connection wiring 57B, following FIG. 18. After the via opening 801B is formed in the same manner as in the first embodiment, as illustrated in FIG. 19, the second via 57BC is formed in the same manner as in the first embodiment, as illustrated in FIG. 20.

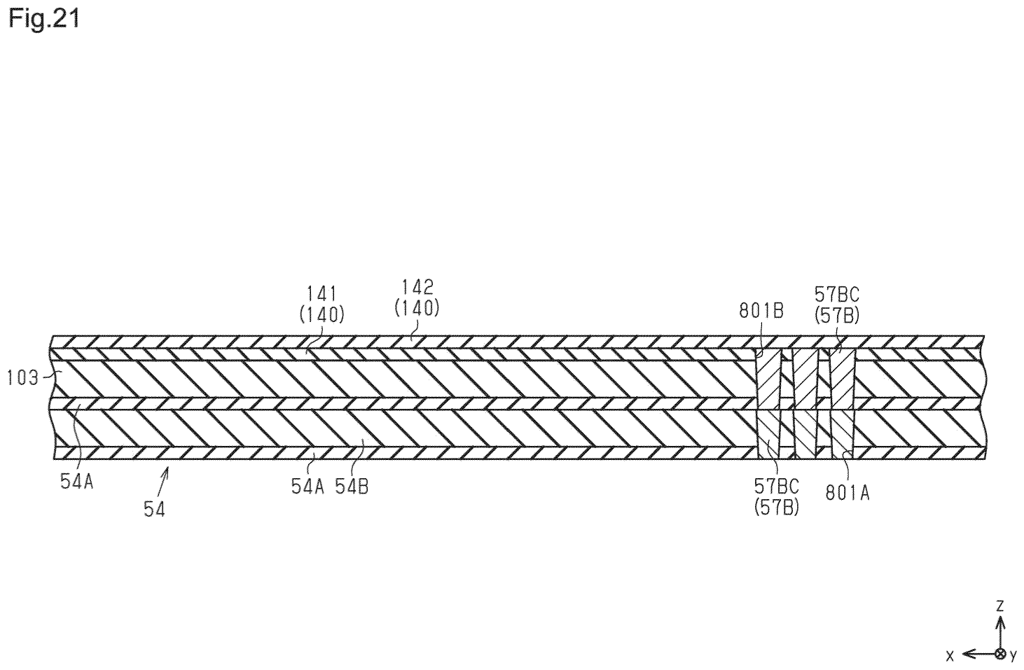

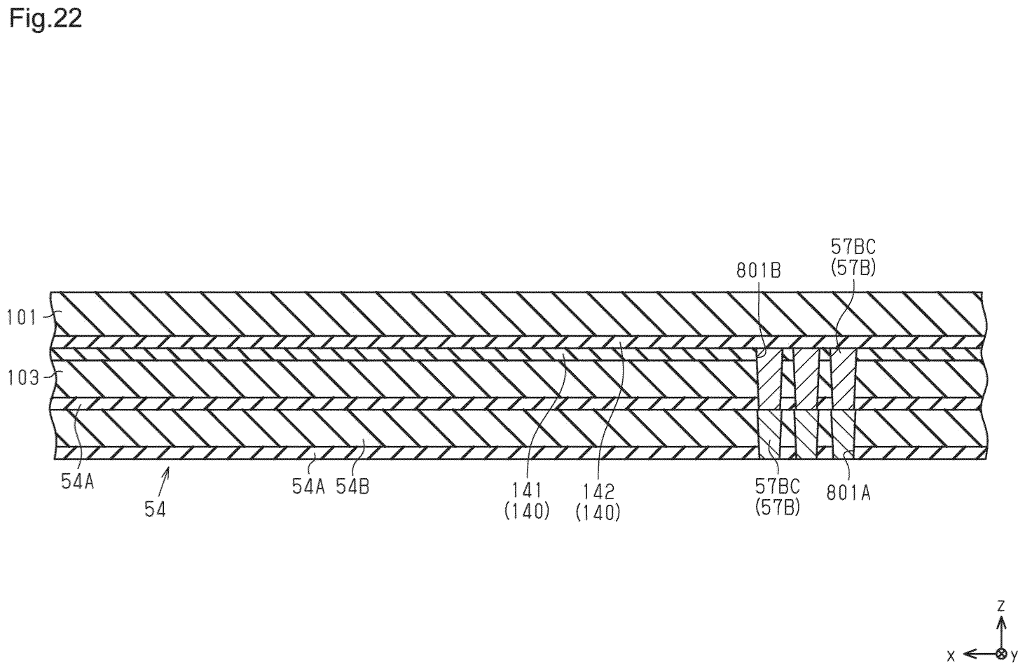

FIGS. 21 and 22 illustrate a step of forming a part of the element insulation layer 54, following FIG. 20. As illustrated in FIG. 21, the second high permittivity film 142 is formed by being deposited on the first high permittivity film 141 using, for example, the CVD method, and the first insulation layer 101 is then formed in the same manner as in the first embodiment, as illustrated in FIG. 22. In the present embodiment, the second high permittivity film 142 is a SiN film, and the first insulation layer 101 is a SiO₂ film.

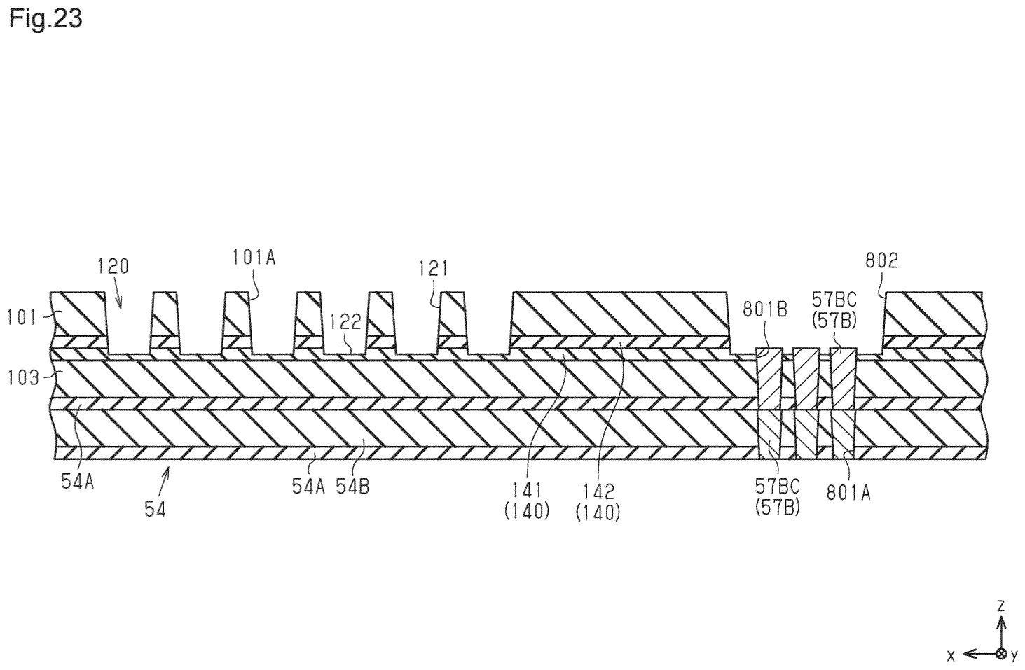

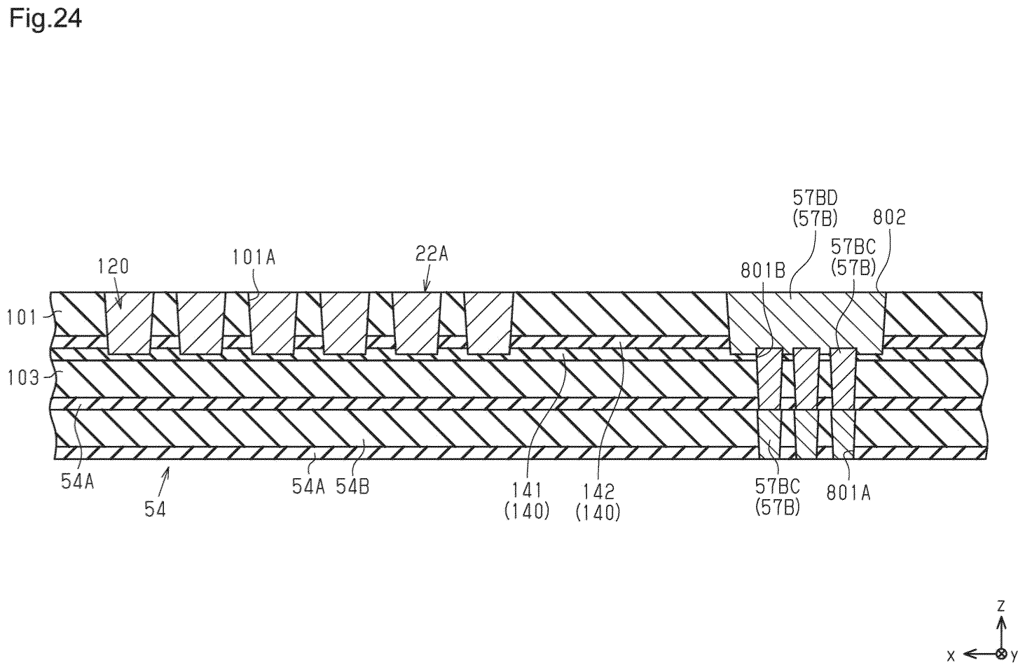

FIGS. 23 and 24 illustrate a step of forming the high-voltage coil 22A and a step of forming a part of the low-voltage side connection wiring 57B, following FIG. 22. As illustrated in FIG. 23, in the same manner as in the first embodiment, the first trench 120 is formed by etching, and the first trench 120 is then filled with a metal material to form the high-voltage coils 22A, for example, as illustrated in FIG. 24. After the wiring opening 802 is formed, in the same manner as in the first embodiment, as illustrated in FIG. 23, the wiring opening 802 is filled with a metal material to form the second wiring 57BD, as illustrated in FIG. 24. At this time, the first trench 120 and the wiring opening 802 extend through both of the first insulation layer 101 and the second high permittivity film 142 in the z direction. By contrast, the first trench 120 and the wiring opening 802 do not extend through the first high permittivity film 141 in the z direction. That is, the first high permittivity film 141 includes the first trench bottom surface 122 of the first trench 120.

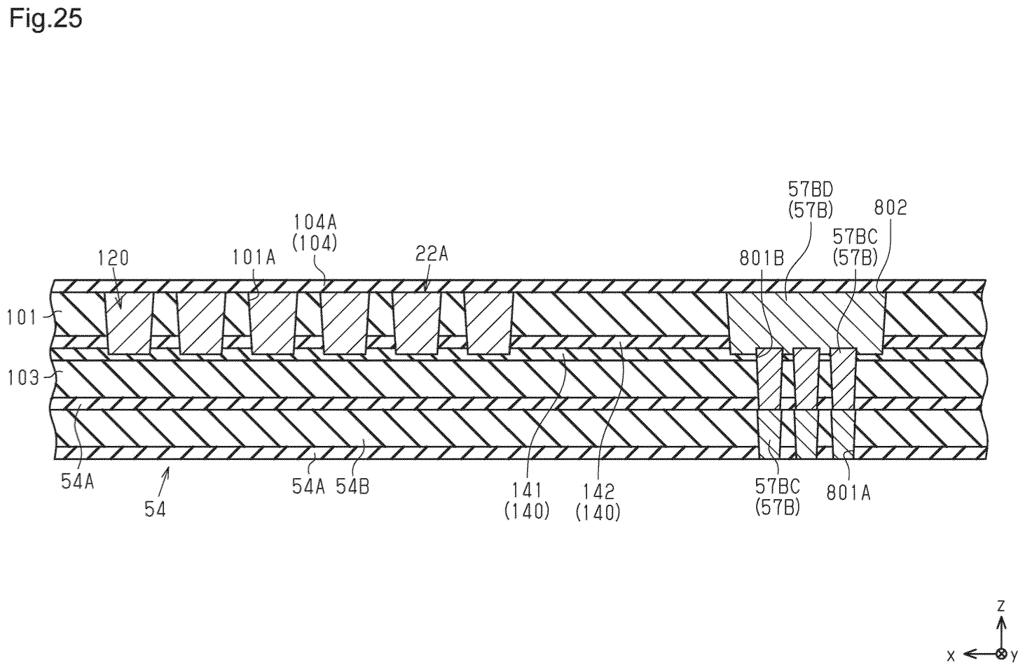

As illustrated in FIGS. 25 to 27, the high permittivity lower film 104A, the high permittivity upper film 104B of the fourth insulation layer 104, and the fifth insulation layer 105 are sequentially formed using, for example, the CVD method, in the same manner as in the first embodiment.

Although not illustrated, the low-voltage coil 21A and the element insulation layer 54 around the low-voltage coil 21A are also formed in the same manner as the high-voltage coil 22A and the element insulation layer 54 around the high-voltage coil 22A. The low-voltage coil 21A and the element insulation layer 54 around the low-voltage coil 21A are formed in a step prior to the step of forming the high-voltage coil 22A and the element insulation layer 54 around the high-voltage coil 22A.

Subsequently, a step of forming the electrode pads 51 and 52 on the element insulation layer 54 and a step of forming the protective film 55 and the passivation film 56 on the element insulation layer 54 are sequentially performed in the same manner as in the first embodiment. The transformer chip 50 is manufactured through the steps described above.

### Effects

According to the present embodiment, the following effects may be obtained.

(2-1) The second insulation layer 140 covers the first end surface 23 of the high-voltage coils 22A and 22B and the lower end portion 25A of the first side surface 25. The lower end portion 25A forms a corner with the first end surface 23.

With this configuration, the intensity of the electric field tends to be high on the lower end portion 25A of the high-voltage coils 22A and 22B, and the lower end portion 25A is covered by the second insulation layer 140, This effectively alleviates the concentration of an electric field on the end portion of the high-voltage coils 22A and 22B located at the side of the low-voltage coils 21A and 21B.

(2-2) The second insulation layer 140 includes a first high permittivity film 141 in contact with the first end surface 23 of the high-voltage coils 22A and 22B and a second high permittivity film 142 stacked on the first high permittivity film 141 and in contact with the first insulation layer 101.

With this configuration, the second high permittivity film 142 covers a part of the first side surface 25 of the high-voltage coils 22A and 22B in the z direction, thereby reducing the intensity of the electric field on the first side surface 25 of the high-voltage coils 22A and 22B. This alleviates the concentration of an electric field on the end portion of the high-voltage coils 22A and 22B located at the side of the low-voltage coils 21A and 21B.

### Third Embodiment

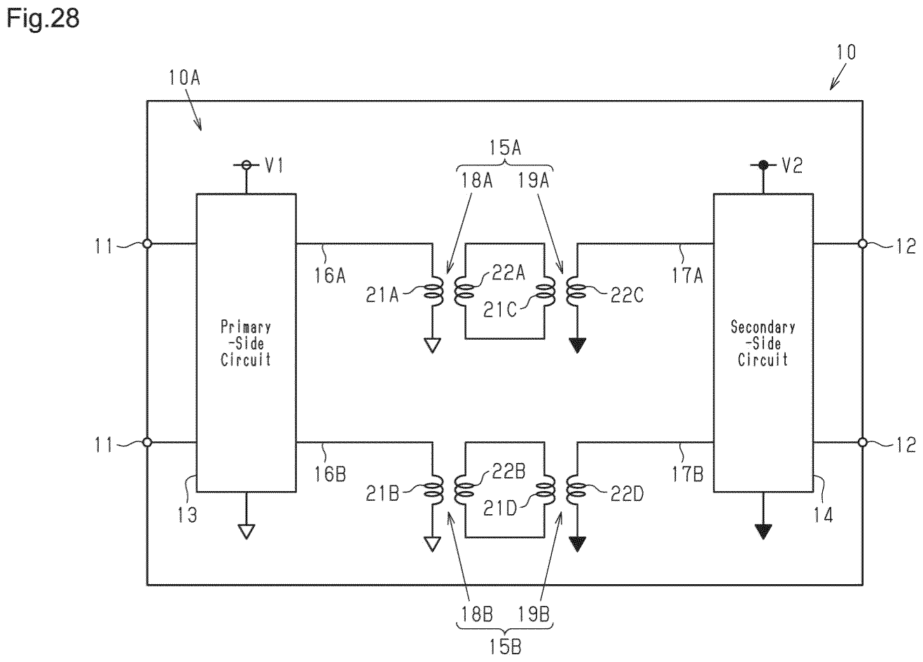

A signal transmitting device 10 according to a third embodiment will now be described with reference to FIGS. 28 to 30. The signal transmitting device 10 according to the present embodiment differs from the signal transmitting device 10 according to the first embodiment in the configuration of the transformer chip 50. In the following description, the same components as those according to the first embodiment are denoted by the same reference signs, and the description thereof will be omitted.

As illustrated in FIG. 28, the transformer 15A includes transformers 18A and 19A that are connected with each other in series. The transformer 18A is electrically connected to the primary-side circuit 13. The transformer 18A includes a low-voltage coil 21A and a high-voltage coil 22A. The transformer 19A is electrically connected to the secondary-side circuit 14. The transformer 19A includes a first high-voltage coil 21C and a second high-voltage coil 22C that is insulated from the first high-voltage coil 21C and capable of being magnetically coupled to the first high-voltage coil 21C.

The low-voltage coil 21A is electrically connected by a primary-side signal line 16A and is connected to the ground of the primary-side circuit 13. That is, a first end portion of the low-voltage coil 21A is electrically connected to the primary-side circuit 13, and a second end portion of the low-voltage coil 21A is electrically connected to the ground of the primary-side circuit 13.

The high-voltage coil 22A is connected to the first high-voltage coil 21C of the transformer 19A. In one example, the high-voltage coil 22A and the first high-voltage coil 21C are connected so as to achieve an electrically floating state. That is, the first end portion of the high-voltage coil 22A is connected to the first end portion of the first high-voltage coil 21C, and the second end portion of the high-voltage coil 22A is connected to the second end portion of the first high-voltage coil 21C. In this manner, the high-voltage coil 22A and the first high-voltage coil 21C serve as relay coils that relay the transmission of signals from the low-voltage coil 21A to the second high-voltage coil 22C.

The second high-voltage coil 22C is electrically connected by a secondary-side signal line 17A, and is connected to the ground of the secondary-side circuit 14. That is, a first end portion of the second high-voltage coil 22C is electrically connected to the secondary-side circuit 14, and a second end portion of the second high-voltage coil 22C is electrically connected to the ground of the secondary-side circuit 14.

The transformer 15B includes transformers 18B and 19B connected with each other in series. The transformer 18B includes a low-voltage coil 21B and a high-voltage coil 22B. The transformer 19B includes a first high-voltage coil 21D and a second high-voltage coil 22D. Because the transformers 18B and 19B are the same as the transformers 18A and 19A, detailed description thereof will be omitted.

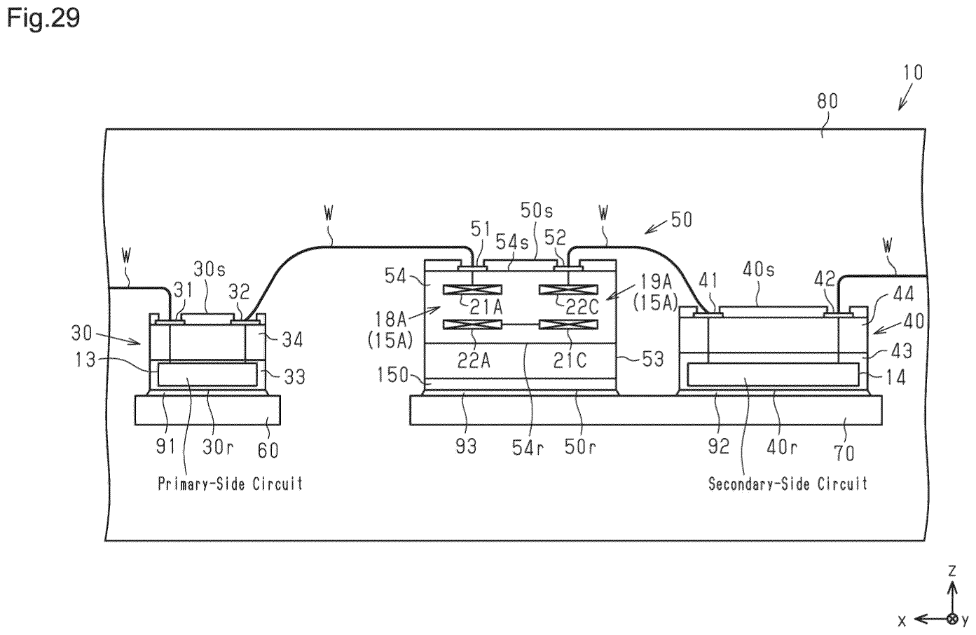

As illustrated in FIG. 29, the transformer chip 50 is mounted on the secondary-side die pad 70 with an insulation member 150 sandwiched between the transformer chip and the secondary-side die pad 70. The insulation member 150 is provided on the substrate 53. In one example, the insulation member 150 is bonded by an insulative bonding material. That is, the insulation member 150 is sandwiched between the third bonding material 93 and the substrate 53. The insulation member 150 is bonded to the secondary-side die pad 70 with the third bonding material 93.

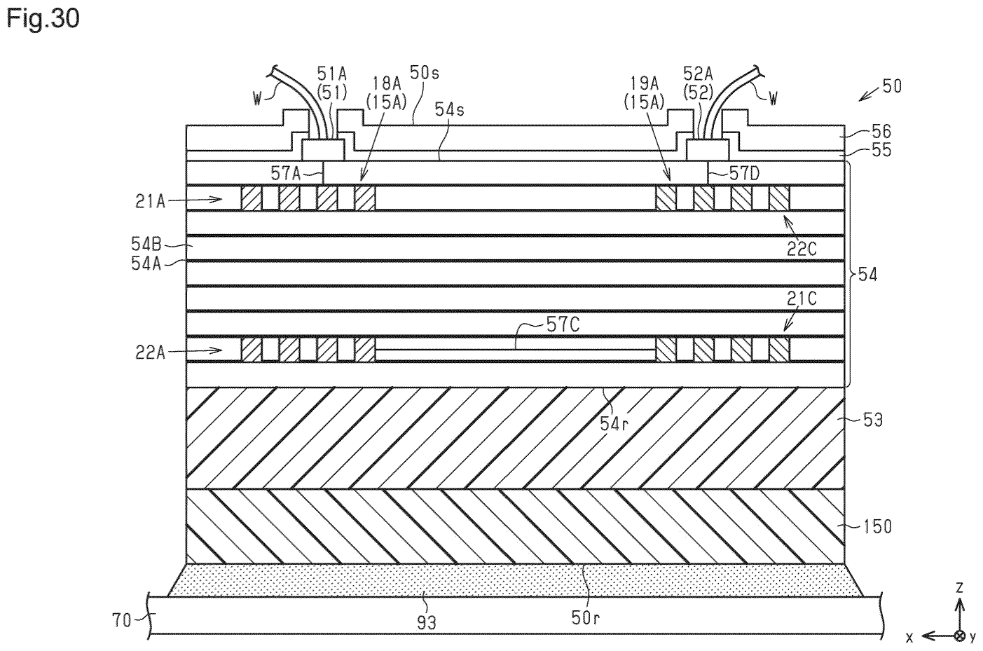

FIG. 30 is a cross-sectional structure illustrating the low-voltage coil 21A, the high-voltage coil 22A, the first high-voltage coil 21C, and the second high-voltage coil 22C included in the transformer chip 50. The configurations and arrangements of the low-voltage coil 21B, the high-voltage coil 22B, the first high-voltage coil 21D, and the second high-voltage coil 22D are the same as those of the low-voltage coil 21A, the high-voltage coil 22A, the first high-voltage coil 21C, and the second high-voltage coil 22C. Thus, configurations and arrangements of the low-voltage coil 21A, the high-voltage coil 22A, the first high-voltage coil 21C, and the second high-voltage coil 22C will be described in detail, and a detailed description of configurations and arrangements of the low-voltage coil 21B, the high-voltage coil 22B, the first high-voltage coil 21D, and the second high-voltage coil 22D will be omitted.

As illustrated in FIG. 30, the low-voltage coil 21A and the high-voltage coil 22A are opposed to each other in the z direction. A part of the element insulation layer 54 is sandwiched between the low-voltage coil 21A and the high-voltage coil 22A in the z direction. In the present embodiment, the low-voltage coil 21A is disposed closer to the element head surface 54s than the high-voltage coil 22A is. In other words, the high-voltage coil 22A is disposed closer to the element back surface 54r than the low-voltage coil 21A is. Thus, in the present embodiment, the low-voltage coil 21A corresponds to the “first coil”, and the high-voltage coil 22A corresponds to the “second coil”.

The low-voltage coil 21A is electrically connected to the first electrode pad 51A via the low-voltage side connection wiring 57A. In the present embodiment, a via extending through one element insulation layer 54 in the z direction forms the low-voltage side connection wiring 57A. Although not illustrated, the low-voltage coil 21A is electrically connected to the first electrode pad 51B (refer to FIG. 3) via the low-voltage side connection wiring 57B.

The high-voltage coil 22A is electrically connected to the first high-voltage coil 21C in the element insulation layer 54. More specifically, a high-voltage side connection wiring 57C is provided in element insulation layer 54. The high-voltage side connection wiring 57C electrically connects the high-voltage coil 22A and the first high-voltage coil 21C to each other.

The first high-voltage coil 21C and the second high-voltage coil 22C are opposed to each other in the z direction. A part of the element insulation layer 54 is sandwiched between the first high-voltage coil 21C and the second high-voltage coil 22C in the z direction. The first high-voltage coil 21C is disposed closer to the element back surface 54r than the second high-voltage coil 22C is. In other words, the second high-voltage coil 22C is disposed closer to the element head surface 54s than the first high-voltage coil 21C is. In the present embodiment, the first high-voltage coil 21C is aligned with the high-voltage coil 22A in the z direction. The second high-voltage coil 22C is aligned with the low-voltage coil 21A in the z direction. In the present embodiment, the second high-voltage coil 22C corresponds to the “third coil”, and the first high-voltage coil 21C corresponds to the “fourth coil”.

As a material forming the first high-voltage coil 21C and the second high-voltage coil 22C, one or more elements are appropriately selected from Ti, TiN, Ta, TaN, Au, Ag, Cu, Al, and W. The material forming the first high-voltage coil 21C and the second high-voltage coil 22C may be the same as the material forming the low-voltage coil 21A and the high-voltage coil 22A. In the present embodiment, both of the first high-voltage coil 21C and the second high-voltage coil 22C are formed from a material including Cu.

The second high-voltage coil 22C is electrically connected to the second electrode pad 52A via the high-voltage side connection wiring 57D. In the present embodiment, a via extending through one element insulation layer 54 in the z direction forms the high-voltage side connection wiring 57D. Although not illustrated, the second high-voltage coil 22C is electrically connected to the second electrode pad 52B (refer to FIG. 3) by a high-voltage side connection wiring that differs from the high-voltage side connection wiring 57D.

Although not illustrated, the structure for alleviating the concentration of the electric field on the low-voltage coil 21A at the side of the high-voltage coil 22A is the same as that according to the first embodiment. The structure for alleviating the concentration of the electric field on the low-voltage coil 21A at the side of the high-voltage coil 22A is the same as that according to the first embodiment. That is, the structure for alleviating the concentration of the electric field in the region between the high-voltage coil 22A and the low-voltage coil 21A is the same as that according to the first embodiment. In addition, the structure for alleviating the concentration of the electric field on the low-voltage coil 21A at the side opposite to the high-voltage coil 22A is the same as that according to the first embodiment. Furthermore, the structure for alleviating the concentration of an electric field on the high-voltage coil 22A at the side of the substrate 53 is the same as that according to the first embodiment.

Furthermore, the structure for alleviating the concentration of the electric field on the first high-voltage coil 21C at the side of the second high-voltage coil 22C is the same as the structure for alleviating the concentration of the electric field on the high-voltage coil 22A at the side of the low-voltage coil 21A. The structure for alleviating the concentration of the electric field on the first high-voltage coil 21C at the side of the substrate 53 is the same as the structure for alleviating the concentration of the electric field on the high-voltage coil 22A at the side of the substrate 53. Furthermore, the structure for alleviating the concentration of the electric field on the second high-voltage coil 22C at the side of the first high-voltage coil 21C is the same as the structure for alleviating the concentration of the electric field on the low-voltage coil 21A at the side of the high-voltage coil 22A. The structure for alleviating the concentration of the electric field on the second high-voltage coil 22C at the side opposite to the first high-voltage coil 21C is the same as the structure for alleviating the concentration of the electric field on the low-voltage coil 21A at the side opposite to the high-voltage coil 22A.

### Effects

According to the present embodiment, the following effects may be obtained.

(3-1) The transformer chip 50 includes transformers 18A (18B) and 19A (19B) connected in series. The transformers 18A (18B) and 19A (19B) are arranged in the x direction orthogonal to the thickness-wise direction of the element insulation layer 54.

With this configuration, the transformers 18A (18B) and 19A (19B) connected in series are arranged in the x direction. This improves the withstand voltage of the transformer chip 50 while limiting an increase in the distance between the element head surface 54s and the element back surface 54r of the element insulation layer 54 in the z direction.

(3-2) The insulation member 150 is sandwiched between the secondary-side die pad 70 and the transformer chip 50.

With this configuration, the distance from the low-voltage coil 21A (21B) and the second high-voltage coil 22C (22D) to the secondary-side die pad 70 in the z direction is increased as compared with a configuration in which the insulation member 150 is not sandwiched between the secondary-side die pad 70 and the transformer chip 50. This improves the withstand voltage between the transformer chip 50 and the secondary-side die pad 70.

(3-3) The insulation member 150 and the secondary-side die pad 70 are bonded by the third bonding material 93. The third bonding material 93 is an insulative bonding material.

With this configuration, the insulation distance from the low-voltage coil 21A (21B) and the second high-voltage coil 22C (22D) to the secondary-side die pad 70 in the z direction is increased as compared with a configuration in which the third bonding material 93 is a conductive bonding material. This improves the withstand voltage between the transformer chip 50 and the secondary-side die pad 70.

(3-4) The high-voltage coil 22A is aligned with the first high-voltage coil 21C in the z direction.

With this configuration, the ninth insulation layer 109 and the tenth insulation layer 110 alleviate the concentration of the electric field on the first high-voltage coil 21C at the side opposite to the second high-voltage coil 22C. The seventh insulation layer 107 and the eighth insulation layer 108 alleviate the concentration of the electric field on the first high-voltage coil 21C at the side of the second high-voltage coil 22C. As described above, the same structure is used to alleviate the concentration of the electric field on high-voltage coil 22A and alleviate the concentration of the electric field on first high-voltage coil 21C. Thus, the process of manufacturing the transformer chip 50 is simplified as compared with a configuration having separate structures for alleviating the concentration of the electric field on the high-voltage coil 22A and for alleviating the concentration of the electric field on the first high-voltage coil 21C.

(3-5) The low-voltage coil 21A is aligned with the second high-voltage coil 22C in the z direction.

With this configuration, the fourth insulation layer 104 and the fifth insulation layer 105 alleviate the concentration of the electric field on the second high-voltage coil 22C at the side opposite to the first high-voltage coil 21C. The third insulation layer 103 and the second insulation layer 102 alleviate the concentration of the electric field on the second high-voltage coil 22C at the side of the first high-voltage coil 21C. As described above, the same structures may be used to alleviate the concentration of the electric field on the low-voltage coil 21A and to alleviate the concentration of the electric field on the second high-voltage coil 22C. Thus, the process of manufacturing the transformer chip 50 is simplified as compared with a configuration having separate structures for alleviating the concentration of the electric field on the low-voltage coil 21A and for alleviating the concentration of the electric field on the second high-voltage coil 22C.

### MODIFIED EXAMPLES

Each of the embodiments described above may be modified in the manner described below. Furthermore, each of the embodiments described above and the modified examples described below may be implemented in any combination within a scope in which such a combination is not technically inconsistent. For example, the transformer chip 50 including the transformers 18A (18B) and 19A (19B) according to the third embodiment may be applied to the second embodiment.

### Modified Example of Transformer Chip

In the first and third embodiments, the structure for alleviating the concentration of an electric field on the low-voltage coil 21A at the side of the high-voltage coil 22A may be changed to that according to the second embodiment.

In the second embodiment, the structure for alleviating the concentration of an electric field on the low-voltage coil 21A at the side of the high-voltage coil 22A may be changed to that according to the first embodiment.

In the first and third embodiments, the structure for alleviating the concentration of an electric field on the low-voltage coil 21A at the side of the high-voltage coil 22A may be omitted. In one example, the etching stopper film 54A may be used instead of the seventh insulation layer 107. Hence, the third end surface 26 of the low-voltage coil 21A is in contact with the etching stopper film 54A. Furthermore, in one example, the second trench 130 forming the low-voltage coil 21A in the element insulation layer 54 may be provided in a manner extending through both of one interlayer insulation film 54B and one etching stopper film 54A. The interlayer insulation film 54B immediately below the etching stopper film 54A includes the second trench bottom surface 132 of the second trench 130. Hence, the fourth end surface 27 of the low-voltage coil 21A is in contact with the interlayer insulation film 54B immediately below the etching stopper film 54A. In the second embodiment, the structure for alleviating the concentration of an electric field on the low-voltage coil 21A at the side of the high-voltage coil 22A may be omitted in the same manner.

In the first and third embodiments, the structure for alleviating the concentration of an electric field on the low-voltage coil 21A at the side of the substrate 53 may be omitted. In one example, the etching stopper film 54A may be used instead of the ninth insulation layer 109. In such a case, the fourth end surface 27 of the low-voltage coil 21A is in contact with the etching stopper film 54A. In the second embodiment, the structure for alleviating the concentration of an electric field on the low-voltage coil 21A at the side of the substrate 53 may be omitted.

In the first and third embodiments, the relative permittivity of each of the first high permittivity film 102A, the second high permittivity film 102B, and the third high permittivity film 102C in the second insulation layer 102 may be changed to any value within a range greater than the relative permittivity of the first insulation layer 101 (third insulation layer 103). In one example, the third high permittivity film 102C may have a relative permittivity lower than the relative permittivity of the first high permittivity film 102A. In one example, the third high permittivity film 102C has a relative permittivity within a range greater than 3.8 and less than 7. In one example, the third high permittivity film 102C may have a relative permittivity within a range greater than 4 and less than 7. The third high permittivity film 102C is formed from a material including SiON. Hence, the relative permittivity of the third high permittivity film 102C is adjusted within the range described above in accordance with the concentration of nitrogen in SiON. The second high permittivity film 102B may have a relative permittivity equal to the relative permittivity of the first high permittivity film 102A. In such a case, each of the first high permittivity film 102A and the second high permittivity film 102B may be formed from a material including, for example, SiN. In such a case, each of the first high permittivity film 102A and the second high permittivity film 102B has a relative permittivity of approximately 7. In addition, each of the high permittivity films 102A, 102B, and 102C may be formed from a material including SiON.

In the second embodiment, the relative permittivity of each of the first high permittivity film 141 and the second high permittivity film 142 in the second insulation layer 140 may be changed to any value within a range greater than the relative permittivity of the first insulation layer 101 (third insulation layer 103). In one example, the first high permittivity film 141 may have a relative permittivity greater than or equal to the relative permittivity of the second high permittivity film 142. In such a case, each of the first high permittivity film 141 and the second high permittivity film 142 may be formed from a material including, for example, SiN. In such a case, each of the first high permittivity film 141 and the second high permittivity film 142 has a relative permittivity of approximately 7. Furthermore, each of the first high permittivity film 141 and the second high permittivity film 142 may be formed from a material including, for example, SiON. In such a case, each of the first high permittivity film 141 and the second high permittivity film 142 have the relative permittivity within a range greater than 3.8 and less than 7. In one example, each of the first high permittivity film 141 and the second high permittivity film 142 may have a relative permittivity within a range greater than 4 and less than 7. The relative permittivity of each of the first high permittivity film 141 and the second high permittivity film 142 is adjusted within the range described above in accordance with the concentration of nitrogen in SiON. Furthermore, the first high permittivity film 141 may be formed from a material including, for example, SiN, and the second high permittivity film 142 may be formed from a material including, for example, SiON. In such a case, the first high permittivity film 141 has a relative permittivity of approximately 7, and the second high permittivity film 142 has a relative permittivity within a range greater than 3.8 and less than 7. In one example, the second high permittivity film 142 may have a relative permittivity within a range greater than 4 and less than 7. The relative permittivity of the second high permittivity film 142 is adjusted within the range described above in accordance with the concentration of nitrogen in SiON.

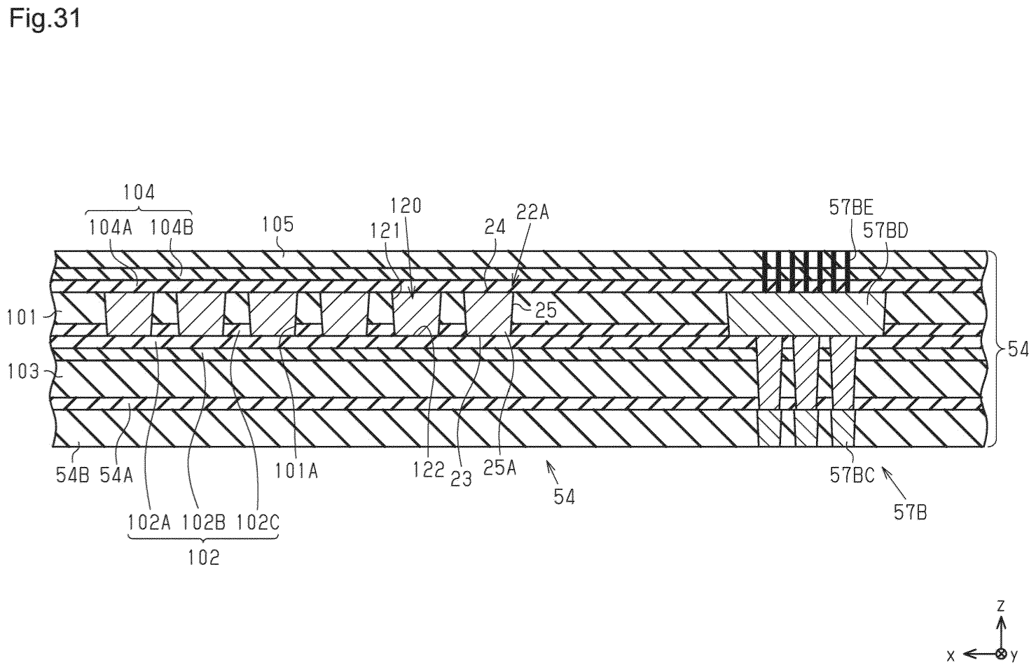

In the first embodiment, the positional relationship between the second insulation layer 102 and the high-voltage coil 22A in the z direction may be changed in any manner. In one example, as illustrated in FIG. 31, the first trench 120 for forming the high-voltage coil 22A does not need to have a groove 102D (refer to FIG. 4) in the second insulation layer 102. That is, the portion of the second insulation layer 102 including the first trench bottom surface 122 of the first trench 120 may have the same thickness as the remaining portion of the second insulation layer 102. The second insulation layer 140 according to the second embodiment and the second insulation layer 102 according to the third embodiment may also be changed in the same manner.

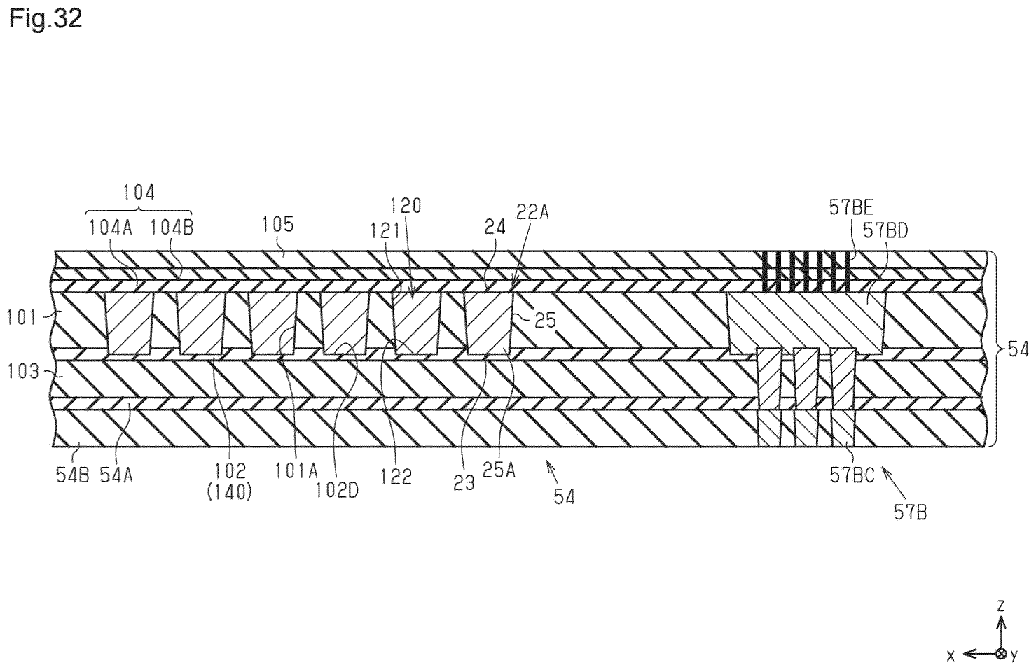

In the first to third embodiments, the number of high permittivity films included in the second insulation layers 102 and 140 may be changed in any manner. In one example, as illustrated in FIG. 32, the second insulation layer 102 (140) may be a single film (high permittivity film). In such a case, the second insulation layer 102 (140) is formed from a material including any one of SiN, SiON, and SiC. That is, the second insulation layer 102 (140) has a relative permittivity higher than the relative permittivity of the third insulation layer 103. In one example, the second insulation layer 102 (140) may have a stacked structure that includes four or more high permittivity films.

In the first and third embodiments, the thickness of each of the first high permittivity film 102A, the second high permittivity film 102B, and the third high permittivity film 102C in the second insulation layer 102 may be changed in any manner. In one example, each of the first high permittivity film 102A, the second high permittivity film 102B, and the third high permittivity film 102C may have a different thickness. In one example, the first high permittivity film 102A may have a thickness greater than the thickness of the second high permittivity film 102B. The first high permittivity film 102A may have a thickness greater than the thickness of the third high permittivity film 102C. In one example, the second high permittivity film 102B may have a thickness greater than the thickness of the first high permittivity film 102A. In one example, the third high permittivity film 102C may have a thickness greater than the thickness of the first high permittivity film 102A. In one example, the third high permittivity film 102C may have a thickness greater or smaller than the thickness of the second high permittivity film 102B.

In the second embodiment, the thickness of each of the first high permittivity film 141 and the second high permittivity film 142 in the second insulation layer 140 may be changed in any manner. The first high permittivity film 141 may have a thickness greater than the thickness of the second high permittivity film 142.

In the first to third embodiments, the relative permittivity of each of the high permittivity lower film 104A and the high permittivity upper film 104B included in the fourth insulation layer 104 may be changed within any range greater than the relative permittivity of the fifth insulation layer 105. In one example, the relative permittivity of the high permittivity lower film 104A and the relative permittivity of the high permittivity upper film 104B may be equal to each other. In such a case, each of the high permittivity lower film 104A and the high permittivity upper film 104B may be formed from a material including any one of SIN, SiON, and SiC.

In the first to third embodiments, the number of high permittivity films included in the fourth insulation layer 104 may be changed in any manner. In one example, the fourth insulation layer 104 may be a single film (high permittivity film). In such a case, the fourth insulation layer 104 is formed from a material including any one of SiN, SiON, and SiC. That is, the fourth insulation layer 104 has a relative permittivity higher than first insulation layer 101. In another example, the fourth insulation layer 104 may have a stacked structure including three or more high permittivity films. Furthermore, an etching stopper film 54A may be arranged instead of the fourth insulation layer 104.

In the first to third embodiments, the thickness of each of the high permittivity lower film 104A and the high permittivity upper film 104B included in the fourth insulation layer 104 may be changed in any manner. In one example, the high permittivity lower film 104A and the high permittivity upper film 104B may differ in thicknesses from each other. For example, the high permittivity lower film 104A may have a thickness greater than the thickness of the high permittivity upper film 104B. For example, the high permittivity lower film 104A may have a thickness smaller than the thickness of the high permittivity upper film 104B.

In the first embodiment, the relative permittivity of each of the fourth high permittivity film 107A, the fifth high permittivity film 107B, and the sixth high permittivity film 107C included in the seventh insulation layer 107 may be changed within any range higher than the relative permittivity of the eighth insulation layer 108 (sixth insulation layer 106). In one example, the sixth high permittivity film 107C may have a relative permittivity lower than the relative permittivity of the fourth high permittivity film 107A. In one example, the sixth high permittivity film 107C has a relative permittivity within a range greater than 3.8 and less than 7. In one example, the sixth high permittivity film 107C may have a relative permittivity within a range greater than 4 and less than 7. The sixth high permittivity film 107C is formed from a material including SiON. Hence, the relative permittivity of the sixth high permittivity film 107C is adjusted within the range described above in accordance with the concentration of nitrogen in SiON. The fifth high permittivity film 107B may have a relative permittivity equal to the relative permittivity of the fourth high permittivity film 107A. In such a case, each of the fourth high permittivity film 107A and the fifth high permittivity film 107B may be formed from a material including, for example, SiN. In such a case, each of the fourth high permittivity film 107A and the fifth high permittivity film 107B has a relative permittivity of approximately 7. In addition, each of the high permittivity films 107A, 107B, and 107C may be formed from a material including SiON. The high permittivity films included in the seventh insulation layer 107 according to the second and third embodiments may also be changed in the same manner.

In the first embodiment, the number of high permittivity films included in the seventh insulation layer 107 may be changed in any manner. In one example, the seventh insulation layer 107 may be a single film (high permittivity film). In such a case, the seventh insulation layer 107 is formed from a material including any one of SiN, SiON, and SiC. In other words, the seventh insulation layer 107 has a relative permittivity higher than the relative permittivity of the eighth insulation layer 108 (sixth insulation layer 106). In another example, the seventh insulation layer 107 may have a stacked structure including four or more high permittivity films. The seventh insulation layer 107 according to the second and third embodiments may also be changed in the same manner.

In the first and third embodiments, the thickness of each of the fourth high permittivity film 107A, the fifth high permittivity film 107B, and the sixth high permittivity film 107C included in the seventh insulation layer 107 may be changed in any manner. In one example, each of the fourth high permittivity film 107A, the fifth high permittivity film 107B, and the sixth high permittivity film 107C may have a different thickness. In one example, the fourth high permittivity film 107A may have a thickness greater than the thickness of the fifth high permittivity film 107B. The fourth high permittivity film 107A may have a thickness greater than the thickness of the sixth high permittivity film 107C. In another example, the fifth high permittivity film 107B may have a thickness greater than the thickness of the fourth high permittivity film 107A. In another example, the sixth high permittivity film 107C may have a thickness greater than the thickness of the fourth high permittivity film 107A. In another example, the sixth high permittivity film 107C may have a thickness greater or smaller than the thickness of the fifth high permittivity film 107B.

In the first and third embodiments, the positional relationship between the low-voltage coil 21A and the seventh insulation layer 107 may be changed in any manner. In one example, the low-voltage coil 21A may be configured to protrude upward from the sixth high permittivity film 107C of the seventh insulation layer 107. For example, the low-voltage coil 21A and the seventh insulation layer 107 may be formed so that the third end surface 26 of the low-voltage coil 21A is flush with a surface of the fourth high permittivity film 107A that is in contact with the fifth high permittivity film 107B.

In the first to third embodiments, the relative permittivity of each of the high permittivity upper film 109A and the high permittivity lower film 109B included in the ninth insulation layer 109 may be changed within any range higher than the relative permittivity of the tenth insulation layer 110 (sixth insulation layer 106). In one example, the relative permittivity of the high permittivity upper film 109A and the relative permittivity of the high permittivity lower film 109B may be equal to each other. In such a case, each of the high permittivity upper film 109A and the high permittivity lower film 109B may be formed from a material including any one of SiN, SiON, and SiC. In one example, the high permittivity upper film 109A may have a relative permittivity lower than the relative permittivity of the high permittivity lower film 109B. In such a case, the high permittivity upper film 109A is formed from a material including SiON, and the high permittivity lower film 109B is formed from a material including SiN.

In the first to third embodiments, the number of high permittivity films included in the ninth insulation layer 109 may be changed in any manner. In one example, the ninth insulation layer 109 may be a single film (high permittivity film). In such a case, the ninth insulation layer 109 is formed from a material including any one of SIN, SiON, and SiC. In other words, the ninth insulation layer 109 has a relative permittivity higher than the relative permittivity of the tenth insulation layer 110 (sixth insulation layer 106). In another example, the ninth insulation layer 109 may have a stacked structure including three or more high permittivity films.

In the first to third embodiments, the thickness of each of the high permittivity upper film 109A and the high permittivity lower film 109B in the ninth insulation layer 109 may be changed in any manner. In one example, the high permittivity lower film 109B may have a thickness greater than the thickness of the high permittivity upper film 109A. In another example, the high permittivity lower film 109B may have a thickness smaller than the thickness of the high permittivity upper film 109A.

In the first to third embodiments, the low-voltage coil 21A does not necessarily have to protrude from the sixth insulation layer 106 toward the high-voltage coil 22A. In such a case, the sixth insulation layer 106 includes the second trench side surface 131 of the second trench 130. Thus, the second side surface 28 of the low-voltage coil 21A is in contact with only the sixth insulation layer 106. The second high-voltage coil 22C according to the third embodiment may also be changed in the same manner.

In the first to third embodiments, the low-voltage coil 21A may protrude from the sixth insulation layer 106 to the ninth insulation layer 109. In such a case, the fourth end surface 27 of the low-voltage coil 21A is covered by the ninth insulation layer 109. In such a case, the ninth insulation layer 109 may have a high permittivity film formed at a side of the high permittivity lower film 109B located opposite to the high permittivity upper film 109A. Such a high permittivity film may have a relative permittivity lower than the relative permittivity of the high permittivity upper film 109A. In such a case, for example, both of the high permittivity upper film 109A and the high permittivity lower film 109B are formed from a material including SiN, and the high permittivity film described above may be formed from a material including SiON.

In the third embodiment, the configuration in which the low-voltage coil 21A, the high-voltage coil 22A, the first high-voltage coil 21C, and the second high-voltage coil 22C are arranged may be changed in any manner. In one example, the high-voltage coil 22A may be disposed closer to the element head surface 54s of the element insulation layer 54 than the low-voltage coil 21A is. In the same manner, the first high-voltage coil 21C may be disposed closer to the element head surface 54s of the element insulation layer 54 than the second high-voltage coil 22C is.

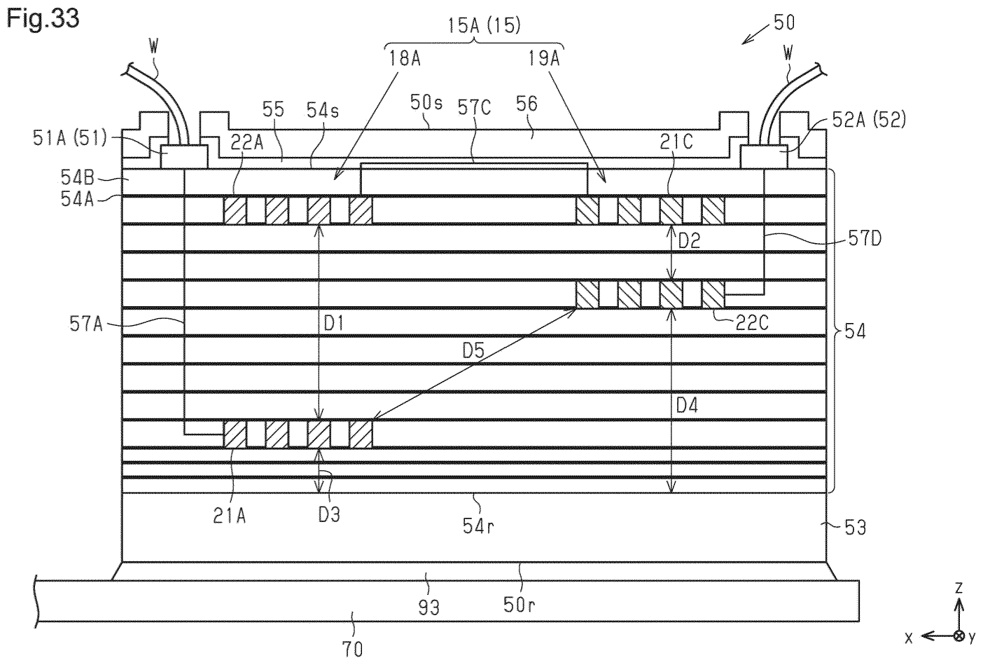

In the third embodiment, the insulation member 150 sandwiched between the transformer chip 50 and the secondary-side die pad 70 may be omitted. As illustrated in FIG. 33, one example of an internal configuration of a transformer chip 50 mounted on the secondary-side die pad 70 will now be described. The transformer chip 50 differs from that according to the third embodiment in a configuration in which the low-voltage coil 21A, the high-voltage coil 22A, the first high-voltage coil 21C, and the second high-voltage coil 22C are arranged.

More specifically, the low-voltage coil 21A is disposed closer to the element back surface 54r of the element insulation layer 54 than the high-voltage coil 22A is. In other words, the high-voltage coil 22A is disposed closer to the element head surface 54s of the element insulation layer 54 than the low-voltage coil 21A is. The first high-voltage coil 21C is disposed closer to the element head surface 54s than the second high-voltage coil 22C is. In other words, the second high-voltage coil 22C is disposed closer to the element back surface 54r than the first high-voltage coil 21C is. In addition, the second high-voltage coil 22C is disposed at a position further away from the element back surface 54r than the low-voltage coil 21A is. In other words, a distance D2 between the first high-voltage coil 21C and the second high-voltage coil 22C in the z direction is smaller than a distance D1 between the low-voltage coil 21A and the high-voltage coil 22A in the z direction. In other words, the second high-voltage coil 22C is disposed between the low-voltage coil 21A and the high-voltage coil 22A as viewed from the y direction. A distance D4 between the second high-voltage coil 22C and the substrate 53 in the z direction is greater than a distance D3 between the low-voltage coil 21A and the substrate 53 in the z direction. In other words, the second high-voltage coil 22C is disposed at a position further away from the secondary-side die pad 70 in the z direction than the low-voltage coil 21A is. A distance D5 between the low-voltage coil 21A and the second high-voltage coil 22C is greater than or equal to the distance D1. The distance D5 may be greater than or equal to the distance D4. Although not illustrated, the low-voltage coil 21B, the high-voltage coil 22B, the first high-voltage coil 21D, and the second high-voltage coil 22D are arranged in the same configuration.

With this configuration, the distance between the secondary-side die pad 70 and the second high-voltage coil 22C (22D), to which a relatively high voltage is applied when the signal transmitting device 10 is driven, is greater than the distance between the secondary-side die pad 70 and the low-voltage coil 21A (21B), to which a relatively low voltage is applied. This improves the withstand voltage of the transformer chip 50.

In addition, the distance between the low-voltage coil 21A (21B) and the second high-voltage coil 22C (22D) to which relatively high voltage is applied when the signal transmitting device 10 is driven is increased. This improves the withstand voltage of the transformer chip 50.

### Modified Example of Signal Transmitting Device

In the third embodiment, the transformer chip 50 may be divided into two transformer chips, namely, a first transformer chip and a second transformer chip. The first transformer chip is a package including the transformers 18A and 18B, and the second transformer chip is a package including the transformers 19A and 19B. The first transformer chip is mounted on the primary-side die pad 60, and the second transformer chip is mounted on the secondary-side die pad 70. The first transformer chip and the second transformer chip are disposed between the first chip 30 and the second chip 40 in the x direction. The first transformer chip is connected to the first chip 30 via a wire W, and the second transformer chip is connected to the second chip 40 via a wire W. The first transformer chip and the second transformer chip are connected via a wire W. Thus, the low-voltage coil 21A (21B) is electrically connected to the primary-side circuit 13; the second high-voltage coil 22C (22D) is electrically connected to the secondary-side circuit 14; and the high-voltage coil 22A (22B) and the first high-voltage coil 21C (21D) are electrically connected to each other.

In the first to third embodiments, the arrangement configuration of the transformer chip 50 may be changed in any manner. In one example, the transformer chip 50 may be mounted on the primary-side die pad 60. In such a case, both of the first chip 30 and the transformer chip 50 are mounted on the primary-side die pad 60.

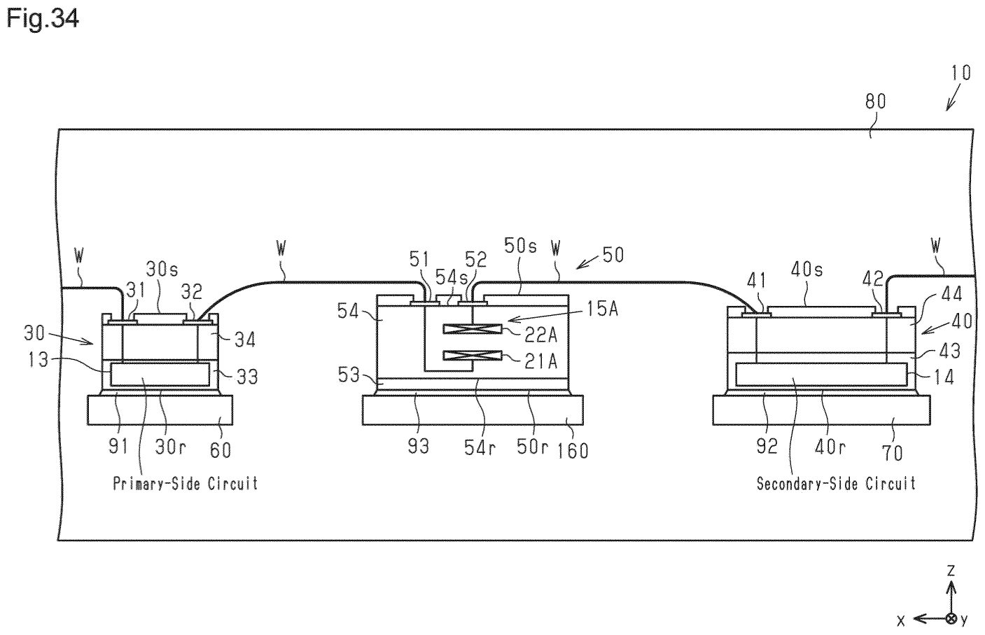

As illustrated in FIG. 34, the transformer chip 50 may be mounted on an intermediate die pad 160. The intermediate die pad 160 is disposed between the primary-side die pad 60 and the secondary-side die pad 70 in the x direction. The intermediate die pad 160 is electrically connected neither to the primary-side die pad 60 nor to the secondary-side die pad 70. In other words, the intermediate die pad 160 is in an electrically floating state with respect to the primary-side die pad 60 and the secondary-side die pad 70. The intermediate die pad 160 is formed of, for example, the same material as those of the primary-side die pad 60 and the secondary-side die pad 70. The intermediate die pad 160 herein corresponds to a “third die pad”.

The transformer chip 50 is applicable to devices other than the signal transmitting devices 10 in the first to third embodiments.

In a first example, the transformer chip 50 may be applied to, for example, a primary-side circuit module. That is, the primary-side circuit module includes the first chip 30, the transformer chip 50, and the encapsulation resin encapsulating the chips 30 and 50. The primary-side circuit module includes the primary-side die pad 60 on which the first chip 30 and the transformer chip 50 are mounted. The first chip 30 is bonded to the primary-side die pad 60 by the primary bonding material 91, and the transformer chip 50 is bonded to the primary-side die pad 60 by the third bonding material 93. In such a case, the primary-side circuit 13 (refer to FIG. 1) included in the first chip 30 corresponds to the “signal transmitting circuit”, and the first chip 30 corresponds to the “circuit chip”. The primary-side circuit module corresponds to the “insulation module”.

In a second example, the transformer chip 50 may be applied to, for example, a secondary-side circuit module. That is, the secondary-side circuit module includes the second chip 40, the transformer chip 50, and the encapsulation resin encapsulating the chips 40, 50. The secondary-side circuit module includes the secondary-side die pad 70 on which both of the second chip 40 and the transformer chip 50 are mounted. The second chip 40 is bonded to the secondary-side die pad 70 by the secondary bonding material 92, and the transformer chip 50 is bonded to the secondary-side die pad 70 by the third bonding material 93. In such a case, the secondary-side circuit 14 (refer to FIG. 1) included in the second chip 40 corresponds to the “signal transmitting circuit”, and the second chip 40 corresponds to the “circuit chip”. The secondary-side circuit module corresponds to the “insulation module”.

In a third example, only the transformer chip 50 may be put into a module. More specifically, the insulation module includes the transformer chip 50 and the encapsulation resin encapsulating the transformer chip 50. The insulation module also includes a die pad on which the transformer chip 50 is mounted. The transformer chip 50 is bonded to the die pad by the third bonding material 93.

In the first to third embodiments, the configuration of the signal transmitting device 10 may be changed in any manner.

In one example, the signal transmitting device 10 may include the primary-side circuit module described above and the second chip 40. In such a case, the second chip 40 may be mounted on the secondary-side die pad 70, and both of the secondary-side die pad 70 and the second chip 40 may be provided as a module encapsulated by an encapsulation resin. The signal transmitting device 10 includes the primary-side circuit module and the module described above.

In another example, the signal transmitting device 10 may include the secondary-side circuit module described above and the first chip 30. In such a case, the first chip 30 may be mounted on the primary-side die pad 60, and both of the primary-side die pad 60 and the first chip 30 may be provided as a module encapsulated by a encapsulation resin. The signal transmitting device 10 includes the secondary-side circuit module and the module described above.

In the first to third embodiments, the direction in which the signal transmitting device 10 transmits a signal may be changed in any manner. In one example, the signal transmitting device 10 may be configured in such a manner that a signal is transmitted from the secondary-side circuit 14 to the primary-side circuit 13 through the transformer 15. More specifically, when a signal (e.g., a feedback signal) from a driving circuit electrically connected to the secondary-side circuit 14 via the secondary-side terminal 12 is input to the secondary-side terminal 12, the signal is transmitted from the secondary-side circuit 14 to the primary-side circuit 13 through the transformer 15. The signal at the primary-side circuit 13 is then output to a control device electrically connected to the primary-side circuit 13 via the primary-side terminal 11. The signal transmitting device 10 may be configured in such a manner that signals are transmitted bidirectionally between the primary-side circuit 13 and the secondary-side circuit 14. That is, the signal transmitting device 10 may include a primary-side circuit 13 and a secondary-side circuit 14 configured to perform at least one of signal transmission and reception with respect to the primary-side circuit 13 through the transformer 15.

### Fourth Embodiment

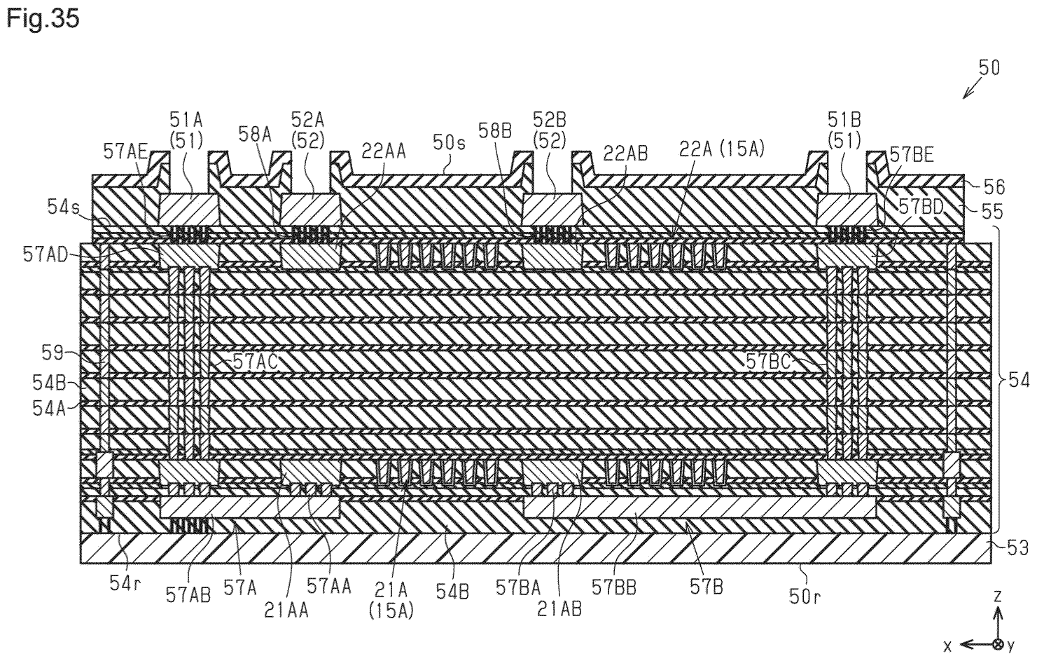

A configuration of a transformer chip 50 according to a fourth embodiment will now be described with reference to FIGS. 35 to 52. The transformer chip 50 according to the present embodiment differs from that in the transformer chip 50 according to the first embodiment in a structure for alleviating the concentration of an electric field on the high-voltage coil 22A and the low-voltage coil 21A. In the following description, the same components as those according to the first embodiment are denoted by the same reference signs, and the description thereof will be omitted.

### Schematic Configuration of Transformer Chip

An example of an internal configuration of the transformer chip 50 according to the fourth embodiment is as illustrated in FIG. 35. Details of the internal configuration are the same as those according to the first embodiment except for the structure for alleviating the concentration of an electric field on the high-voltage coil 22A and the low-voltage coil 21A; therefore, a description of the same details will be omitted.

### Detailed Configuration of Each Coil and Components Around Coil

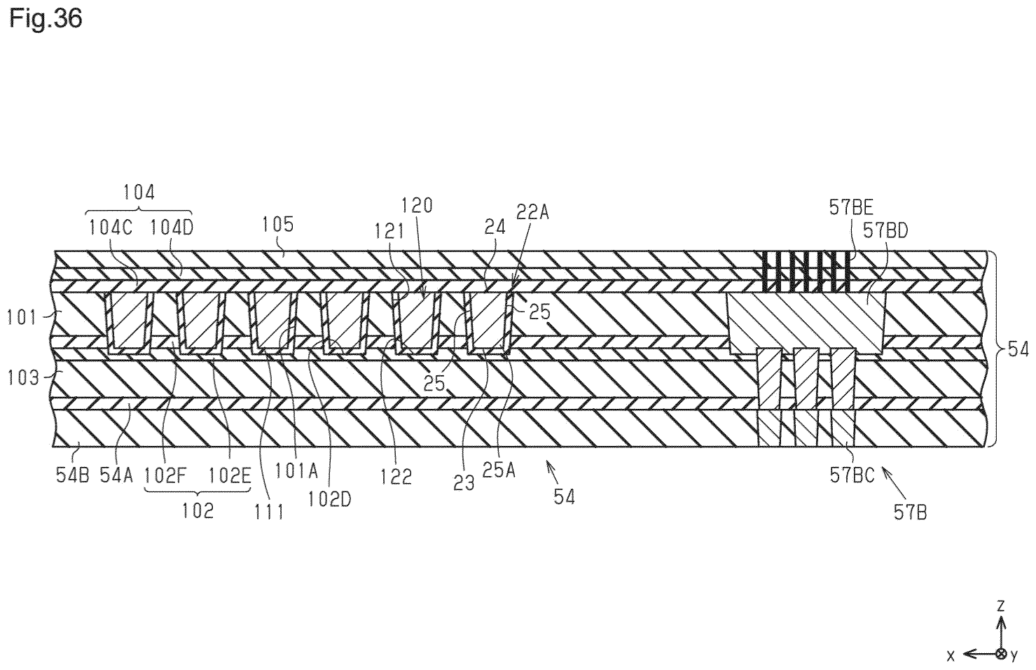

As illustrated in FIGS. 36 to 38, the configuration of the element insulation layer 54 around each of the coils 21A and 22A is different from the configuration of the element insulation layer 54 between the low-voltage coil 21A and the high-voltage coil 22A in the z direction. Specifically, the element insulation layer 54 includes, in addition to the etching stopper films 54A and the interlayer insulation films 54B, a structure that alleviates the concentration of an electric field on the coils 21A and 22A. A detailed configuration of each of the coils 21A and 22A and a detailed configuration of each of the coils 21A and 22A and the element insulation layer 54 around the coils 21A and 22A will now be described.

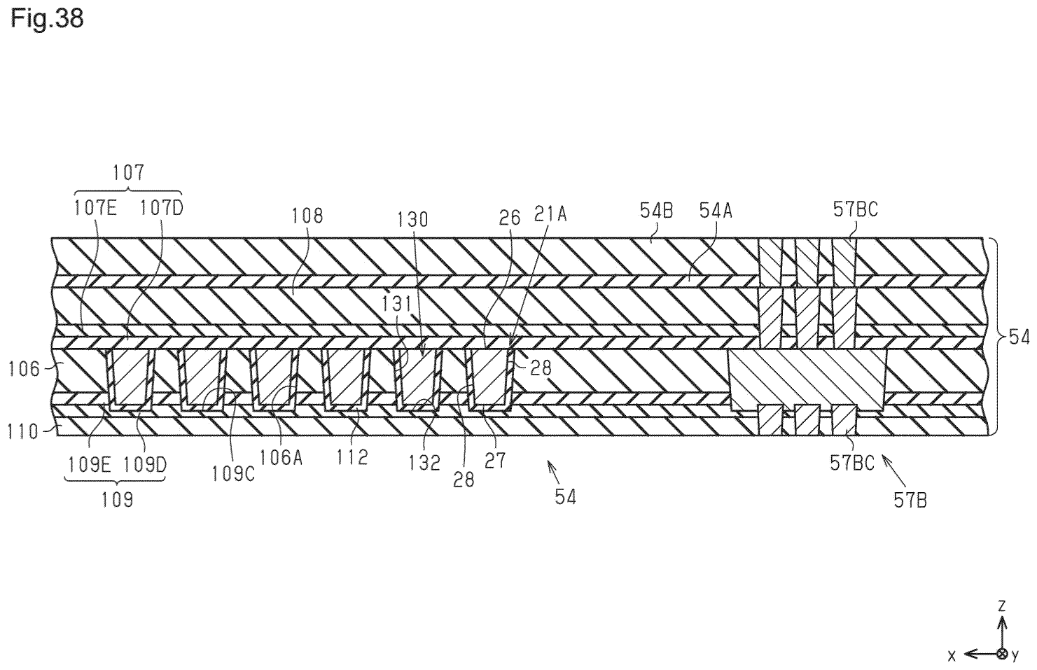

As illustrated in FIG. 36, the high-voltage coil 22A includes a first end surface 23 facing toward the low-voltage coil 21A (refer to FIG. 38) in the z direction, a second end surface 24 facing the side opposite to the first end surface 23 in the z direction, and a first side surface 25. The first side surface 25 extends between the first end surface 23 and the second end surface 24 in the z direction. In the present embodiment, in the cross-sectional view shown in FIG. 36, the first side surface 25 is tapered from the second end surface 24 toward the first end surface 23. In the cross-sectional view in FIG. 36, each of the first end surface 23 and the second end surface 24 has a flat surface that is orthogonal to the z direction. The high-voltage coil 22A is spiral as viewed from the z direction.

The number of turns in the high-voltage coil 22A may be changed in any manner. In addition, the cross-sectional structure including the first end surface 23, the second end surface 24, and the two first side surfaces 25 of the high-voltage coil 22A may be changed in any manner. In one example, the two first side surfaces 25 may extend along the z direction. In other words, the high-voltage coil 22A including the first end surface 23, the second end surface 24, and the two first side surfaces 25 may have any rectangular cross-sectional structure.

The element insulation layer 54 around the high-voltage coil 22A includes a first insulation layer 101, a second insulation layer 102, a third insulation layer 103, a fourth insulation layer 104, a fifth insulation layer 105, and a first coating layer 111. The second insulation layer 102 is arranged on the third insulation layer 103; the first insulation layer 101 is arranged on the second insulation layer 102; the fourth insulation layer 104 is arranged on first insulation layer 101; and the fifth insulation layer 105 is arranged on the fourth insulation layer 104. The high-voltage coil 22A is arranged in the first insulation layer 101. In the present embodiment, the high-voltage coil 22A extends in the first insulation layer 101 and the second insulation layer 102. The first coating layer 111 extends in the first insulation layer 101 and the second insulation layer 102.

The first insulation layer 101 and the second insulation layer 102 include a first trench 120 corresponding to the high-voltage coil 22A. The first trench 120 includes a first trench side surface 121 and a first trench bottom surface 122. The first trench side surface 121 is tapered toward the first trench bottom surface 122. In other words, the first trench 120 includes a through hole 101A extending through the first insulation layer 101 in the z direction and a groove 102D formed in the second insulation layer 102 and communicating with the through hole 101A. The first trench side surface 121 includes a side surface defining the through hole 101A and a side surface of the groove 102D. The first trench bottom surface 122 includes a bottom surface of the groove 102D. As described above, the first insulation layer 101 and the second insulation layer 102 include the first trench side surface 121, and the second insulation layer 102 includes the first trench bottom surface 122.

The first coating layer 111 is formed in the first trench 120. The first coating layer 111 extends along the first trench bottom surface 122 and the first trench side surface 121. Therefore, the first coating layer 111 is in contact with the second insulation layer 102 on the first trench bottom surface 122 and in contact with the first insulation layer 101 on the first trench side surface 121.

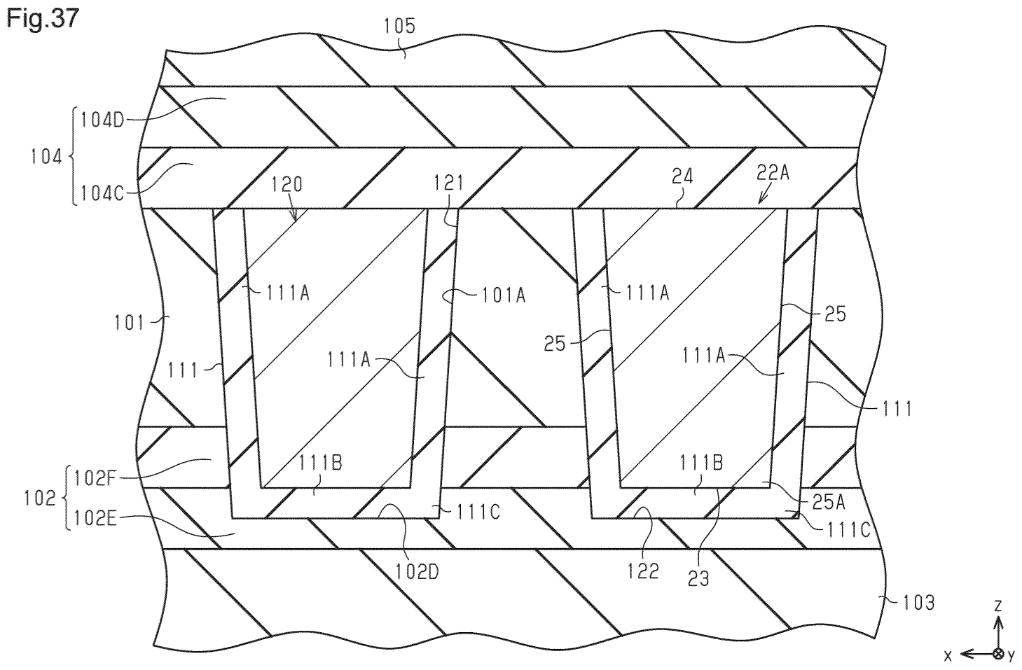

As illustrated in FIG. 37, the first coating layer 111 includes a side surface portion 111A and a bottom surface portion 111B. The side surface portion 111A and the bottom surface portion 111B are integrally formed. The side surface portion 111A is arranged on the first trench side surface 121. The bottom surface portion 111B is arranged on the first trench bottom surface 122. That is, the side surface portion 111A is in contact with the first insulation layer 101, and the bottom surface portion 111B is in contact with the second insulation layer 102. In the present embodiment, the side surface portion 111A extends on the entire first trench side surface 121. The bottom surface portion 111B extends on the entire first trench bottom surface 122.

The side surface portion 111A includes a lower end portion 111C located adjacent to the bottom surface portion 111B. The lower end portion 111C is in contact with the second insulation layer 102. In other words, the bottom surface portion 111B and the lower end portion 111C are covered by the second insulation layer 102.

The first coating layer 111 has a thickness smaller than the thickness of the first insulation layer 101. That is, the first coating layer 111 has a thickness smaller than the thickness of the interlayer insulation film 54B. The first coating layer 111 has a thickness smaller than the thickness of the second insulation layer 102. In the present embodiment, the first coating layer 111 has a thickness smaller than the thickness of the etching stopper film 54A (refer to FIG. 36).

The high-voltage coil 22A is formed in the first trench 120. Specifically, the high-voltage coil 22A is arranged in the first trench 120 such that the first end surface 23 and the first side surface 25 are in contact with the first coating layer 111. Specifically, the first end surface 23 is in contact with the bottom surface portion 111B of the first coating layer 111, and the first side surface 25 is in contact with the side surface portion 111A of the first coating layer 111. The first coating layer 111 covers a lower end portion 25A of the first side surface 25 of the high-voltage coil 22A. The lower end portion 25A forms a corner with the first end surface 23.

The bottom surface portion 111B of the first coating layer 111 has a thickness smaller than the depth of the groove 102D of the second insulation layer 102. Therefore, the first end surface 23 of the high-voltage coil 22A is located below a surface of the second insulation layer 102 located at the side of the first insulation layer 101 (at the side of the third insulation layer 103).

The element insulation layer 54 around the high-voltage coil 22A has a structure for alleviating the concentration of an electric field generated in a region between the high-voltage coil 22A and the low-voltage coil 21A. In one example, the element insulation layer 54 includes the first coating layer 111, the second insulation layer 102, and the third insulation layer 103 as the structure for alleviating the concentration of an electric field in the region between the high-voltage coil 22A and the low-voltage coil 21A.

The third insulation layer 103 is arranged below the high-voltage coil 22A. In other words, the third insulation layer 103 is arranged closer to the low-voltage coil 21A (refer to FIG. 35) than the high-voltage coil 22A is. The third insulation layer 103 is arranged separately from the high-voltage coil 22A in the z direction. The third insulation layer 103 has a relative permittivity lower than the relative permittivity of the second insulation layer 102. The third insulation layer 103 is formed from a material including SiO₂. Therefore, the third insulation layer 103 has a relative permittivity of approximately 3.8. The third insulation layer 103 has a thickness greater than the thickness of the second insulation layer 102. In the present embodiment, the third insulation layer 103 forms the interlayer insulation film 54B.

The first coating layer 111 has a relative permittivity higher than the relative permittivity of the third insulation layer 103. The first coating layer 111 is formed from a material including SiN. Therefore, the first coating layer 111 has a relative permittivity of approximately 7.

The second insulation layer 102 has a relative permittivity higher than the relative permittivity of the third insulation layer 103. The second insulation layer 102 is formed from a material including any one of SiN, SiON, and SiC. The second insulation layer 102 has a thickness smaller than the thickness of the third insulation layer 103. In other words, the second insulation layer 102 has a thickness smaller than the thickness of the interlayer insulation film 54B. In the present embodiment, the second insulation layer 102 has a thickness greater than the thickness of the etching stopper film 54A.

The second insulation layer 102 includes a first high permittivity film 102E in contact with the bottom surface portion 111B of the first coating layer 111 and a second high permittivity film 102F in contact with the first insulation layer 101. The groove 102D defining the first trench 120 extends through the second high permittivity film 102F and forms a recess in the first high permittivity film 102E. In other words, the groove 102D has a depth greater than the thickness of the second high permittivity film 102F.

The first high permittivity film 102E is in contact with the bottom surface portion 111B of the first coating layer 111 and the lower end portion 111C of the side surface portion 111A. More specifically, the first high permittivity film 102E includes the groove 102D. The lower end portion 111C of the side surface portion 111A is in contact with the groove 102D. Thus, the second insulation layer 102 is arranged in a manner covering the lower end portion 111C of the first coating layer 111. The first high permittivity film 102E is arranged on the third insulation layer 103. In the present embodiment, the first high permittivity film 102E is in contact with the third insulation layer 103. The first high permittivity film 102E has a thickness equal to the thickness of the second high permittivity film 102F. It is considered that the first high permittivity film 102E has a thickness equal to the thickness of the second high permittivity film 102F, for example, when the difference between the thickness of the first high permittivity film 102E and the thickness of the second high permittivity film 102F is within 20% of the thickness of the first high permittivity film 102E.

The first high permittivity film 102E has a relative permittivity lower than the relative permittivity of the first coating layer 111. The relative permittivity of the first high permittivity film 102E is within a range greater than 3.8 and less than 7. In one example, the relative permittivity of the first high permittivity film 102E may be within a range greater than 4 and less than 7. The first high permittivity film 102E is formed from a material including SiON. Hence, the relative permittivity of the first high permittivity film 102E is adjusted within the range described above in accordance with the concentration of N (nitrogen) in SiON.

The second high permittivity film 102F is arranged on the first high permittivity film 102E. In the present embodiment, the second high permittivity film 102F is in contact with the first high permittivity film 102E. The second high permittivity film 102F is sandwiched between the first high permittivity film 102E and the first insulation layer 101. The second high permittivity film 102F is formed at a position matching the first end surface 23 of the high-voltage coil 22A, as viewed from a direction orthogonal to the z direction. The second high permittivity film 102F covers a portion of the first side surface 25 of the high-voltage coil 22A located closer to the first end surface 23.

The second high permittivity film 102F has a relative permittivity higher than the relative permittivity of the first high permittivity film 102E. The second high permittivity film 102F is formed from a material including SiN. The second high permittivity film 102F has a relative permittivity of approximately 7. Hence, in other words, the second high permittivity film 102F includes the etching stopper film 54A.

As described above, in the structure for alleviating the concentration of an electric field on the high-voltage coil 22A with respect to the low-voltage coil 21A, the first coating layer 111, the first high permittivity film 102E of the second insulation layer 102, and the third insulation layer 103 are sequentially arranged in a direction from the first end surface 23 of the high-voltage coil 22A toward the low-voltage coil 21A. That is, the relative permittivity is configured to be decreased in the direction from the first end surface 23 of the high-voltage coil 22A toward the low-voltage coil 21A.

The element insulation layer 54 also has a structure for alleviating the concentration of an electric field on the first side surface 25 of the high-voltage coil 22A. In one example, the element insulation layer 54 includes the first coating layer 111 and the first insulation layer 101.

The first insulation layer 101 has a relative permittivity lower than the relative permittivity of the first coating layer 111. The relative permittivity of the first insulation layer 101 is lower than the relative permittivity of the first high permittivity film 102E. The first insulation layer 101 is formed from a material including SiO₂. The first insulation layer 101 has a relative permittivity of approximately 3.8. In the present embodiment, the first insulation layer 101 includes an interlayer insulation film 54B (refer to FIG. 36).

The first insulation layer 101 has a thickness greater than the thickness of the first coating layer 111. The first insulation layer 101 has a thickness greater than the thickness of the second insulation layer 102. In the present embodiment, the first insulation layer 101 has a thickness equal to the thickness of the third insulation layer 103. It is considered that the first insulation layer 101 has a thickness equal to the thickness of the third insulation layer 103, for example, when the difference between the thickness of the first insulation layer 101 and the thickness of the third insulation layer 103 is within 20% of the thickness of the first insulation layer 101.

As described above, in the structure for alleviating the concentration of an electric field on the first side surface 25 of the high-voltage coil 22A, the first coating layer 111 and the first insulation layer 101 are sequentially arranged in a direction extending orthogonal to the z direction away from the first side surface 25 of the high-voltage coil 22A. That is, the relative permittivity is configured to be decreased in the direction extending away from the first side surface 25 of the high-voltage coil 22A.

As illustrated in FIG. 36, the element insulation layer 54 around the high-voltage coil 22A has a structure for alleviating the concentration of an electric field on the high-voltage coil 22A at the side opposite to the low-voltage coil 21A. In one example, the element insulation layer 54 includes a fourth insulation layer 104 and a fifth insulation layer 105 as the structure for alleviating the concentration of an electric field on the high-voltage coil 22A at the side opposite to the low-voltage coil 21A.

The fourth insulation layer 104 is arranged on the first insulation layer 101 so as to contact the second end surface 24 of the high-voltage coil 22A. As described above, in the present embodiment, the high-voltage coil 22A is covered by the first insulation layer 101, the second insulation layer 102, and the fourth insulation layer 104. The fourth insulation layer 104 has a relative permittivity higher than the relative permittivity of the first insulation layer 101. The fourth insulation layer 104 is formed from a material including any one of SiN, SiON, and SiC.

The fourth insulation layer 104 includes a high permittivity lower film 104C in contact with the second end surface 24 of the high-voltage coil 22A and a high permittivity upper film 104D that is stacked on the high permittivity lower film 104C.

The high permittivity lower film 104C is in contact with the first insulation layer 101 as well as with the second end surface 24. The high permittivity lower film 104C is in contact with the first coating layer 111. The high permittivity lower film 104C has a relative permittivity higher than the relative permittivity of the first insulation layer 101. The high permittivity lower film 104C is formed from a material including SiN. Therefore, the high permittivity lower film 104C has a relative permittivity of approximately 7.

The thickness of the high permittivity lower film 104C is equal to the thickness of the etching stopper film 54A. It is considered that the thickness of the high permittivity lower film 104C is equal to the thickness of the etching stopper film 54A, for example, when the difference between the thickness of the high permittivity lower film 104C and the thickness of the etching stopper film 54A is within 20% of the thickness of the etching stopper film 54A. Hence, in other words, the high permittivity lower film 104C includes the etching stopper film 54A.

The high permittivity upper film 104D is in contact with the high permittivity lower film 104C. The high permittivity upper film 104D is arranged separately from the high-voltage coil 22A. The high permittivity upper film 104D has a relative permittivity lower than the relative permittivity of the high permittivity lower film 104C. By contrast, the high permittivity upper film 104D has a relative permittivity higher than the relative permittivity of the fifth insulation layer 105. In one example, the relative permittivity of the high permittivity upper film 104D is within a range greater than 3.8 and less than 7. In another example, the relative permittivity of the high permittivity upper film 104D is within a range greater than 4 and less than 7. The high permittivity upper film 104D is formed from a material including SiON. Hence, the relative permittivity of the high permittivity upper film 104D is adjusted within the range described above in accordance with the concentration of nitrogen in SiON.

The high permittivity upper film 104D has a thickness equal to the thickness of the high permittivity lower film 104C. It is considered that the high permittivity upper film 104D has a thickness equal to the thickness of the high permittivity lower film 104C, for example, when the difference between the thickness of the high permittivity upper film 104D and the thickness of the high permittivity lower film 104C is within 20% of the thickness of the high permittivity upper film 104D.

The fifth insulation layer 105 is stacked on the fourth insulation layer 104. Specifically, the fifth insulation layer 105 is formed on the high permittivity upper film 104D. The fifth insulation layer 105 is in contact with the high permittivity upper film 104D. The fifth insulation layer 105 is arranged separately from the high-voltage coil 22A in the z direction.

The fifth insulation layer 105 has a relative permittivity lower than the relative permittivity of the fourth insulation layer 104. The fifth insulation layer 105 is formed from a material including SiO₂. Therefore, the relative permittivity of the fifth insulation layer 105 is the same as the relative permittivity of the first insulation layer 101 and is approximately 3.8. In the present embodiment, the fifth insulation layer 105 has a thickness smaller than the thickness of the first insulation layer 101. The fifth insulation layer 105 has a thickness greater than the thickness of each of the high permittivity lower film 104C and the thickness of the high permittivity upper film 104D.

The fifth insulation layer 105 may have a thickness greater than or equal to the thickness of the fourth insulation layer 104. The fifth insulation layer 105 may have a thickness equal to the thickness of the first insulation layer 101. It is considered that the fifth insulation layer 105 has a thickness equal to the thickness of the first insulation layer 101, for example, when the difference between the thickness of the fifth insulation layer 105 and the thickness of the first insulation layer 101 is within 20% of the thickness of the first insulation layer 101. In other words, the fifth insulation layer 105 includes the interlayer insulation film 54B.

As described above, in the structure for alleviating the concentration of an electric field on the high-voltage coil 22A at the side opposite to the low-voltage coil 21A, the high permittivity lower film 104C and the high permittivity upper film 104D in the fourth insulation layer 104 and the fifth insulation layer 105 are sequentially stacked in a direction upward from the second end surface 24 of the high-voltage coil 22A. That is, the relative permittivity is configured to be decreased in the direction extending upward from the third end surface 26 of the high-voltage coil 22A.

As illustrated in FIG. 38, the low-voltage coil 21A has a configuration similar to that of the high-voltage coil 22A. The low-voltage coil 21A includes a third end surface 26 facing toward the high-voltage coil 22A (refer to FIG. 37) in the z direction, a fourth end surface 27 facing the opposite side of the third end surface 26 in the z direction, and a second side surface 28. The third end surface 26 faces in the same direction as the second end surface 24 (refer to FIG. 37) of the high-voltage coil 22A, and the fourth end surface 27 faces in the same direction as the first end surface 23 (refer to FIG. 37) of the high-voltage coil 22A. The second side surface 28 extends between the third end surface 26 and the fourth end surface 27 in the z direction. The second side surface 28 is tapered from the third end surface 26 toward the fourth end surface 27 in the cross-sectional view in FIG. 38. In the cross-sectional view shown in FIG. 38, the third end surface 26 and the fourth end surface 27 both have a flat surface. The low-voltage coil 21A has a spiral shape as viewed from the z direction. The number of turns in the low-voltage coil 21A is the same as the number of turns in the high-voltage coil 22A.

The number of turns in the low-voltage coil 21A may be changed in any manner. The cross-sectional structure including the third end surface 26, the fourth end surface 27, and the two second side surfaces 28 of the low-voltage coil 21A may be changed in any manner. In one example, the two second side surfaces 28 may extend along the z direction. That is, the low-voltage coil 21A including the third end surface 26, the fourth end surface 27, and the two second side surfaces 28 may have any rectangular cross-sectional structure.

The element insulation layer 54 around the low-voltage coil 21A includes a sixth insulation layer 106, a seventh insulation layer 107, an eighth insulation layer 108, a ninth insulation layer 109, a tenth insulation layer 110, and a second coating layer 112. The ninth insulation layer 109 is arranged on the tenth insulation layer 110, the sixth insulation layer 106 is arranged on the ninth insulation layer 109, the seventh insulation layer 107 is arranged on the sixth insulation layer 106, and the eighth insulation layer 108 is arranged on the seventh insulation layer 107. The low-voltage coil 21A and the second coating layer 112 are provided in the sixth insulation layer 106.

The sixth insulation layer 106 and the ninth insulation layer 109 include a second trench 130 corresponding to the low-voltage coil 21A. The second trench 130 includes a second trench side surface 131 and a second trench bottom surface 132. The second trench side surface 131 is a tapered toward the second trench bottom surface 132. In other words, the second trench 130 includes a through hole 106A extending through the sixth insulation layer 106 in the z direction and a groove 109C formed in the ninth insulation layer 109 and communicating with the through hole 106A. The second trench side surface 131 includes a side surface defining the through hole 106A and a side surface of the groove 109C. The second trench bottom surface 132 includes a bottom surface of the groove 109C. The sixth insulation layer 106 and the ninth insulation layer 109 include the entire second trench side surface 131. The ninth insulation layer 109 includes the entire second trench bottom surface 132.

The second coating layer 112 is formed in the second trench 130. The second coating layer 112 is formed on the second trench bottom surface 132 and the second trench side surface 131. Thus, the second coating layer 112 is in contact with the ninth insulation layer 109 on the second trench bottom surface 132 and is in contact with the sixth insulation layer 106 on the second trench side surface 131. The second coating layer 112 has a configuration similar to that of the first coating layer 111.

The second coating layer 112 has a relative permittivity higher than the relative permittivity of the sixth insulation layer 106. The second coating layer 112 is formed from a material including SiN. The second coating layer 112 has a thickness smaller than the thickness of the sixth insulation layer 106. That is, the second coating layer 112 has a thickness smaller than the thickness of the interlayer insulation film 54B. The second coating layer 112 has a thickness smaller than the thickness of the seventh insulation layer 107. In the present embodiment, the second coating layer 112 has a thickness smaller than the thickness of the etching stopper film 54A.

The low-voltage coil 21A is formed in the second trench 130. Specifically, the low-voltage coil 21A is arranged in the second trench 130 such that the fourth end surface 27 and the second side surface 28 are in contact with the second coating layer 112. Hence, in the present embodiment, the ninth insulation layer 109 is not in contact with the low-voltage coil 21A.

The sixth insulation layer 106 is formed from a material including SiO₂.

Therefore, the sixth insulation layer 106 has a relative permittivity of approximately 3.8. The sixth insulation layer 106 has a thickness greater than the thickness of the seventh insulation layer 107 (ninth insulation layer 109). The sixth insulation layer 106 has a thickness equal to the thickness of the third insulation layer 103. It is considered that the sixth insulation layer 106 has a thickness equal to the thickness of the third insulation layer 103, for example, when the difference between the thickness of the sixth insulation layer 106 and the thickness of the third insulation layer 103 is within 20% of the thickness of the third insulation layer 103. In the present embodiment, the sixth insulation layer 106 includes the interlayer insulation film 54B in the same manner as the third insulation layer 103.

The element insulation layer 54 includes the seventh insulation layer 107, the eighth insulation layer 108, and the second coating layer 112 as the structure for alleviating the concentration of an electric field on the low-voltage coil 21A at the side of the high-voltage coil 22A. In other words, this structure is for alleviating the concentration of an electric field on the region between the high-voltage coil 22A and the low-voltage coil 21A.

The seventh insulation layer 107 is stacked on the sixth insulation layer 106 so as to contact the third end surface 26 of the low-voltage coil 21A. The seventh insulation layer 107 is also in contact with the second coating layer 112. In the present embodiment, the seventh insulation layer 107 covers the third end surface 26. As described above, in the present embodiment, the low-voltage coil 21A is covered by the sixth insulation layer 106, the seventh insulation layer 107, and the ninth insulation layer 109. In other words, the low-voltage coil 21A is arranged in the sixth insulation layer 106 such that the third end surface 26 is in contact with the seventh insulation layer 107. In other words, the low-voltage coil 21A is covered by the second coating layer 112 and the seventh insulation layer 107.

The seventh insulation layer 107 has a relative permittivity higher than the relative permittivity of sixth insulation layer 106. The seventh insulation layer 107 is formed from a material including any one of SiN, SiON, and SiC. The seventh insulation layer 107 has a thickness smaller than the thickness of the sixth insulation layer 106. In other words, the seventh insulation layer 107 has a thickness smaller than the thickness of the interlayer insulation film 54B. In the present embodiment, the seventh insulation layer 107 has a thickness greater than the thickness of the etching stopper film 54A.

The seventh insulation layer 107 includes the third high permittivity film 107D in contact with the third end surface 26 of the low-voltage coil 21A and the fourth high permittivity film 107E in contact with the eighth insulation layer 108.

The third high permittivity film 107D is provided on the sixth insulation layer 106. The third high permittivity film 107D is sandwiched between the fourth high permittivity film 107E and the sixth insulation layer 106. In the present embodiment, the third high permittivity film 107D is in contact with the sixth insulation layer 106 and the second coating layer 112.

The third high permittivity film 107D is formed from a material including SiN. Therefore, the third high permittivity film 107D has a relative permittivity of approximately 7. The third high permittivity film 107D has a thickness greater than the thickness of the second coating layer 112. The third high permittivity film 107D has a thickness equal to the thickness of the etching stopper film 54A. It is considered that the third high permittivity film 107D has a thickness equal to the thickness of the etching stopper film 54A, for example, when the difference between the thickness of the third high permittivity film 107D and the thickness of the etching stopper film 54A is within 20% of the thickness of the etching stopper film 54A. In other words, the third high permittivity film 107D includes the etching stopper film 54A.

The fourth high permittivity film 107E is provided on the third high permittivity film 107D. In the present embodiment, the fourth high permittivity film 107E is in contact with the third high permittivity film 107D. The fourth high permittivity film 107E is sandwiched between the third high permittivity film 107D and the eighth insulation layer 108. The fourth high permittivity film 107E is arranged separately from the low-voltage coil 21A and located closer to the side of the high-voltage coil 22A (refer to FIG. 36) in the z direction than the low-voltage coil 21A is.

The fourth high permittivity film 107E has a relative permittivity lower than the relative permittivity of the third high permittivity film 107D. By contrast, the fourth high permittivity film 107E has a relative permittivity higher than the relative permittivity of the sixth insulation layer 106. In one example, the fourth high permittivity film 107E has a relative permittivity within a range greater than 3.8 and less than 7. In another example, the fourth high permittivity film 107E may have a relative permittivity within a range greater than 4 and less than 7. The fourth high permittivity film 107E is formed from a material including SiON. Hence, the relative permittivity of the fourth high permittivity film 107E is adjusted within the range described above in accordance with the concentration of nitrogen in SiON.

In one example, the fourth high permittivity film 107E has a thickness greater than the thickness of the second coating layer 112. The fourth high permittivity film 107E has a thickness equal to the thickness of the third high permittivity film 107D. It is considered that the fourth high permittivity film 107E has a thickness equal to the thickness of the third high permittivity film 107D, for example, when the difference between the thickness of the fourth high permittivity film 107E and the thickness of the third high permittivity film 107D is within 20% of the thickness of the fourth high permittivity film 107E.

The eighth insulation layer 108 is located closer to the high-voltage coil 22A than the low-voltage coil 21A is. The eighth insulation layer 108 is arranged separately from the low-voltage coil 21A in the z direction.

The eighth insulation layer 108 has a relative permittivity lower than the relative permittivity of the seventh insulation layer 107. The eighth insulation layer 108 is formed from a material including SiO₂. Therefore, the relative permittivity of the eighth insulation layer 108 is the same as the relative permittivity of the sixth insulation layer 106 and is approximately 3.8. The eighth insulation layer 108 has a thickness greater than the thickness of the seventh insulation layer 107. The eighth insulation layer 108 has a thickness equal to the thickness of the sixth insulation layer 106. It is considered that the eighth insulation layer 108 has a thickness equal to the thickness of the sixth insulation layer 106, for example, when the difference between the thickness of the eighth insulation layer 108 and the thickness of the sixth insulation layer 106 is within 20% of the thickness of the sixth insulation layer 106. In other words, the eighth insulation layer 108 includes the interlayer insulation film 54B.

As described above, in the structure for alleviating the concentration of an electric field on the low-voltage coil 21A at the side of the high-voltage coil 22A, the third high permittivity film 107D and the fourth high permittivity film 107E of the seventh insulation layer 107 and the eighth insulation layer 108 are sequentially stacked in a direction from the third end surface 26 of the low-voltage coil 21A toward the high-voltage coil 22A. That is, the relative permittivity is configured to be decreased in the direction from the third end surface 26 of the low-voltage coil 21A toward the high-voltage coil 22A.

The element insulation layer 54 around the low-voltage coil 21A has a structure for alleviating the concentration of an electric field on the low-voltage coil 21A at the side of the substrate 53. In one example, the element insulation layer 54 includes the ninth insulation layer 109 and the tenth insulation layer 110 as the structure for alleviating the concentration of an electric field on the low-voltage coil 21A at the side of the substrate 53.

The second coating layer 112 is in contact with the groove 109C of the ninth insulation layer 109. The groove 109C has a depth greater than the thickness of the second coating layer 112. Therefore, the fourth end surface 27 of the low-voltage coil 21A is located below a surface of the ninth insulation layer 109 that is in contact with the sixth insulation layer 106. Thus, the ninth insulation layer 109 covers a lower end portion including the fourth end surface 27 of the low-voltage coil 21A.

The ninth insulation layer 109 has a relative permittivity higher than the relative permittivity of the sixth insulation layer 106 (the tenth insulation layer 110). By contrast, the relative permittivity of the ninth insulation layer 109 is lower than the relative permittivity of the second coating layer 112. The ninth insulation layer 109 includes a high permittivity lower film 109D in contact with the second coating layer 112 and a high permittivity upper film 109E that is arranged on the high permittivity lower film 109D.

The high permittivity lower film 109D is in contact with the tenth insulation layer 110 in addition to with the second coating layer 112. In one example, the high permittivity lower film 109D has a relative permittivity within a range greater than 3.8 and less than 7. In another example, the high permittivity lower film 109D may have a relative permittivity within a range greater than 4 and less than 7. The high permittivity lower film 109D is formed from a material including SiON. Hence, the relative permittivity of the high permittivity lower film 109D is adjusted within the range described above in accordance with the concentration of nitrogen in SiON.

The high permittivity lower film 109D has a thickness equal to the thickness of the high permittivity upper film 109E. It is considered that the high permittivity lower film 109D has a thickness equal to the thickness of the high permittivity upper film 109E, for example, when the difference between the thickness of the high permittivity lower film 109D and the thickness of the high permittivity upper film 109E is within 20% of the thickness of the high permittivity lower film 109D. The thickness of the high permittivity lower film 109D is also equal to the thickness of the etching stopper film 54A. It is considered that the high permittivity lower film 109D has a thickness equal to the thickness of the etching stopper film 54A, for example, when the difference between the thickness of the high permittivity lower film 109D and the thickness of the etching stopper film 54A is within 20% of the thickness of the etching stopper film 54A.

The high permittivity upper film 109E is in contact with the high permittivity lower film 109D. The high permittivity upper film 109E is also in contact with the sixth insulation layer 106. Therefore, the high permittivity upper film 109E is sandwiched between the high permittivity lower film 109D and the sixth insulation layer 106. The high permittivity upper film 109E has a relative permittivity higher than the relative permittivity of the high permittivity lower film 109D. The high permittivity upper film 109E is formed from a material including SiN. Therefore, the high permittivity upper film 109E has a relative permittivity of approximately 7. In other words, the high permittivity upper film 109E includes the etching stopper film 54A.

The tenth insulation layer 110 is arranged closer to the substrate 53 than the low-voltage coil 21A is. The tenth insulation layer 110 is arranged separately from the low-voltage coil 21A.

The tenth insulation layer 110 has a relative permittivity lower than the relative permittivity of the ninth insulation layer 109. The tenth insulation layer 110 is formed from a material including SiO₂. Therefore, the relative permittivity of the tenth insulation layer 110 is the same as the relative permittivity of the sixth insulation layer 106 and is approximately 3.8. In the present embodiment, the tenth insulation layer 110 has a thickness smaller than the thickness of the ninth insulation layer 109. In the present embodiment, the tenth insulation layer 110 has a thickness smaller than the thickness of the sixth insulation layer 106. The tenth insulation layer 110 has a thickness greater than the thickness of the high permittivity lower film 109D and the thickness of the high permittivity upper film 109E.

The tenth insulation layer 110 may have a thickness greater than or equal to the thickness of the ninth insulation layer 109. The tenth insulation layer 110 may have a thickness equal to the thickness of the sixth insulation layer 106. It is considered that the tenth insulation layer 110 has a thickness equal to the thickness of the sixth insulation layer 106, for example, when the difference between the thickness of the tenth insulation layer 110 and the thickness of the sixth insulation layer 106 is within 20% of the thickness of the sixth insulation layer 106. In other words, the tenth insulation layer 110 includes the interlayer insulation film 54B.

As described above, in the structure for alleviating the concentration of an electric field on the low-voltage coil 21A at the side of the substrate 53, the second coating layer 112, the high permittivity lower film 109D in the ninth insulation layer 109, and the tenth insulation layer 110 are sequentially arranged in a direction extending downward from the fourth end surface 27 of the low-voltage coil 21A. That is, the relative permittivity is configured to be decreased in a direction extending downward from the fourth end surface 27 of the low-voltage coil 21A.

### Method of Manufacturing Transformer Chip

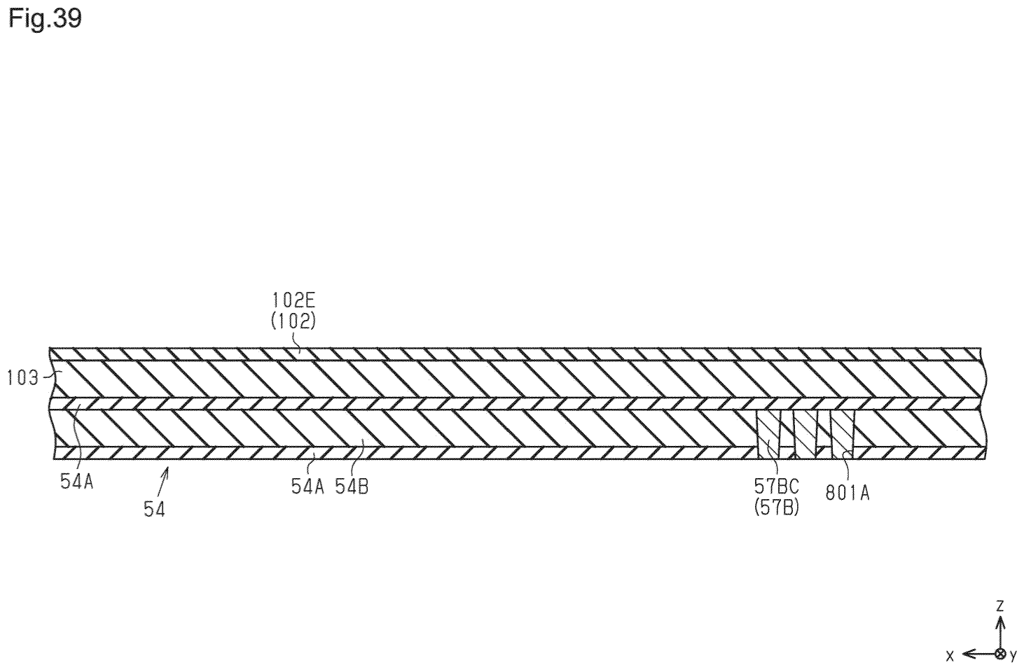

An example of a method of manufacturing the transformer chip 50 will now be described with reference to FIGS. 39 to 52. For the sake of convenience, in the following description of the manufacturing process of the transformer chip 50, the same components as those of the transformer chip 50 will be denoted by the same reference signs. FIGS. 39 to 52 are schematic cross-sectional views of the high-voltage coil 22A and the element insulation layer 54 around the high-voltage coil 22A. The reference signs that are omitted from FIGS. 39 to 52 may be found in FIG. 35.

The method of manufacturing the transformer chip 50 includes steps of: preparing the substrate 53; forming the element insulation layer 54 on the substrate 53; forming the low-voltage coils 21A and 21B and the high-voltage coils 22A and 22B in the element insulation layer 54; forming the low-voltage side connection wirings 57A and 57B and the vias 58A and 58B in the element insulation layer 54; forming the electrode pads 51 and 52 on the element insulation layer 54; and forming the protective film 55 and the passivation film 56 on the element insulation layer 54. A step of forming the element insulation layer 54 and the high-voltage coil 22A, particularly, a step of manufacturing a structure for alleviating the concentration of an electric field on the high-voltage coil 22A and the high-voltage coil 22A will be described below in detail.

FIG. 39 illustrates a step of forming a part of the element insulation layer 54 on the substrate 53 and a step of forming a part of the low-voltage side connection wiring 57B on the element insulation layer 54. In the step of forming a part of the element insulation layer 54, after the interlayer insulation film 54B is formed on the substrate of the substrate 53, the etching stopper films 54A and the interlayer insulation films 54B are stacked alternately. The etching stopper films 54A and the interlayer insulation films 54B are formed by, for example, chemical vapor deposition (CVD). In the present embodiment, the etching stopper films 54A are SiN films, and the interlayer insulation films 54B are SiO₂ films.

Next, the step of forming a part of the low-voltage side connection wiring 57B is performed. More specifically, in this step, after the etching stopper films 54A and the interlayer insulation films 54B are stacked, a via opening 801A is formed by, for example, etching. The via opening 801A is filled with a metal material by, for example, sputtering. One example of the metal material is Cu. Thus, a part of the second via 57BC of the low-voltage side connection wiring 57B is formed. In FIG. 39, after the second via 57BC is formed, the process returns to the step of forming a part of the element insulation layer 54 again, and the etching stopper film 54A is stacked on the interlayer insulation film 54B.

Next, after the third insulation layer 103 is formed on the etching stopper film 54A, a part of the second insulation layer 102 is formed on the third insulation layer 103.

More specifically, the step of forming a part of the element insulation layer 54 is performed. In other words, the third insulation layer 103 is formed by being deposited on the etching stopper film 54A, using a CVD method. In the present embodiment, the third insulation layer 103 is a SiO₂ film. The first high permittivity film 102E is then formed by being deposited on the third insulation layer 103, using the CVD method. In the present embodiment, the first high permittivity film 102E is a SiON film.

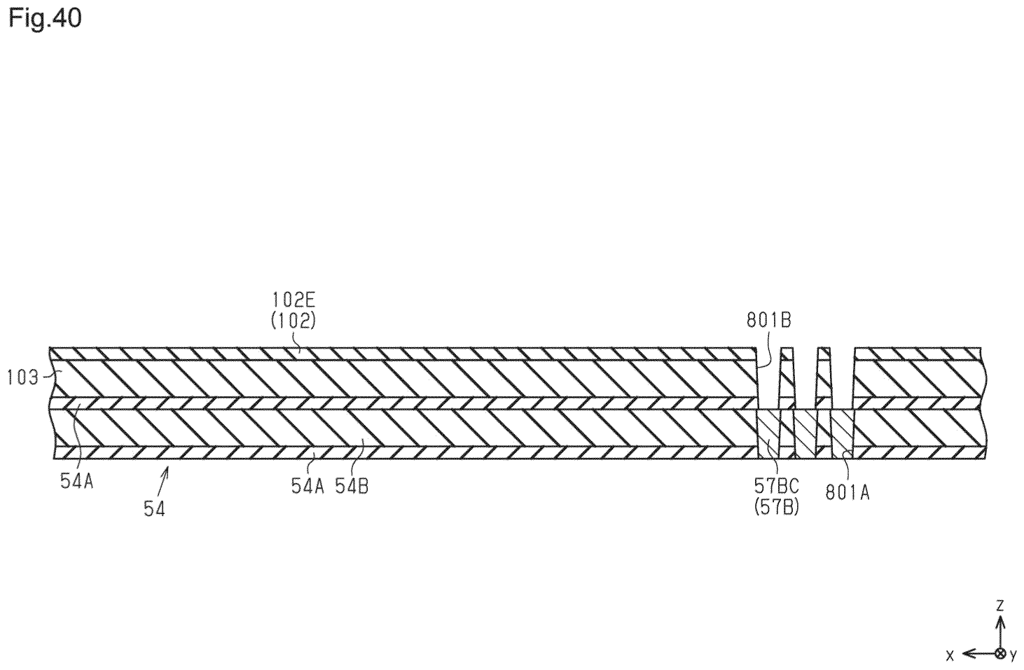

FIG. 40 illustrates a step of forming a part of the low-voltage side connection wiring 57B in the element insulation layer 54, following FIG. 39. More specifically, in this step, for example, etching is performed to form a via opening 801B that exposes the first high permittivity film 102E, the third insulation layer 103, and the etching stopper film 54A in the z direction. The second via 57BC in FIG. 39 is exposed through the via opening 801B.

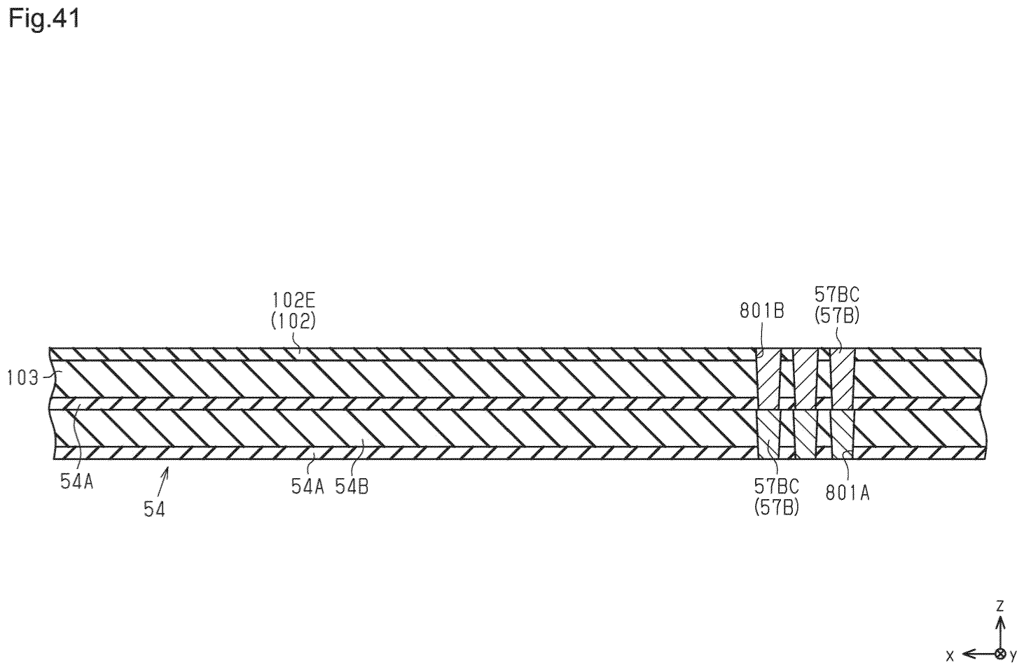

FIG. 41 illustrates a step of forming a part of the low-voltage side connection wiring 57B in the element insulation layer 54, following FIG. 40. More specifically, in this step, the via opening 801B is filled with a metal material by, for example, sputtering. One example of the metal material is Cu. Thus, the second via 57BC of the low-voltage side connection wiring 57B is formed.

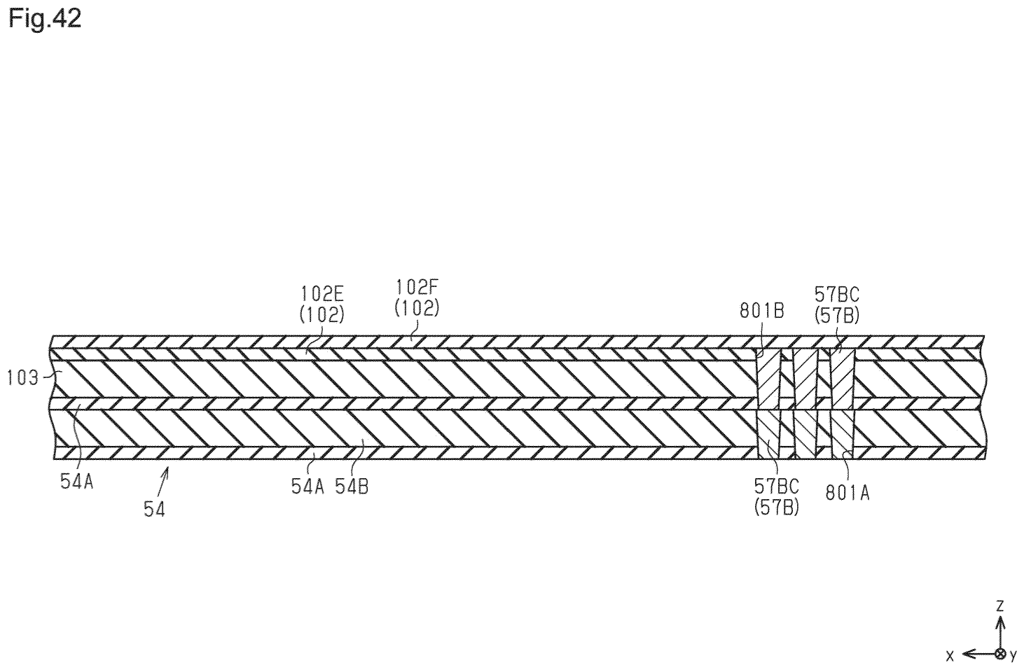

Next, FIG. 42 illustrates a step of forming a part of the element insulation layer 54, following FIG. 41. More specifically, in this step, the second high permittivity film 102F is formed by being deposited on the first high permittivity film 102E and the second via 57BC using, for example, a CVD method. In the present embodiment, the second high permittivity film 102F is a SiN film. Thus, in other words, the second high permittivity film 102F is the etching stopper film 54A.

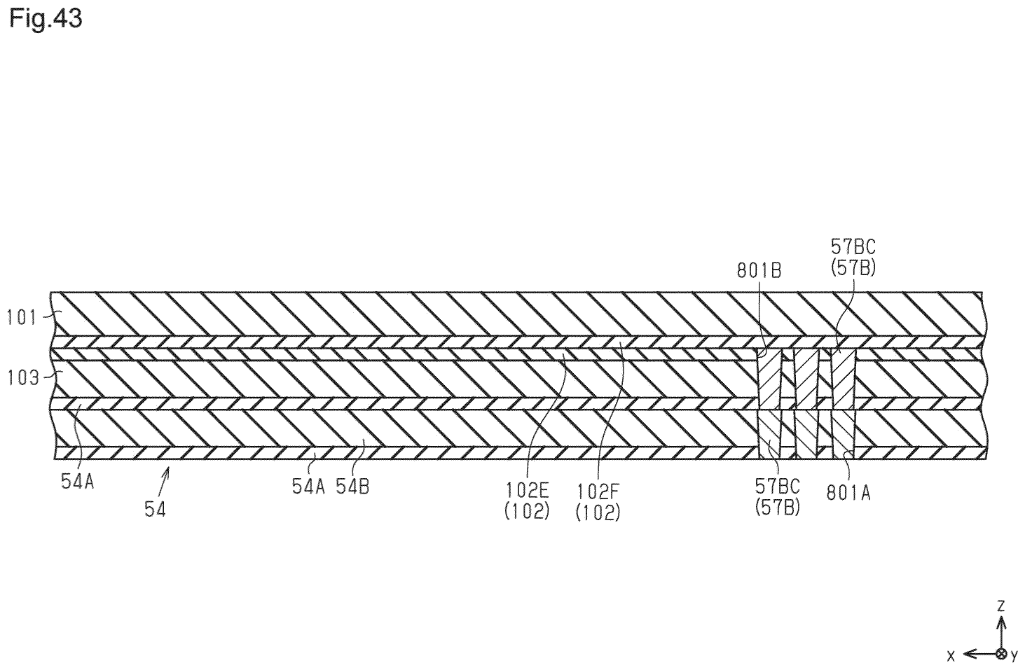

Next, FIG. 43 illustrates a step of forming a part of the element insulation layer 54, following FIG. 42. More specifically, in this step, the first insulation layer 101 is formed on the second high permittivity film 102F using, for example, the CVD method. In the present embodiment, the first insulation layer 101 is a SiO₂ film. Thus, in other words, the first insulation layer 101 includes the interlayer insulation film 54B.

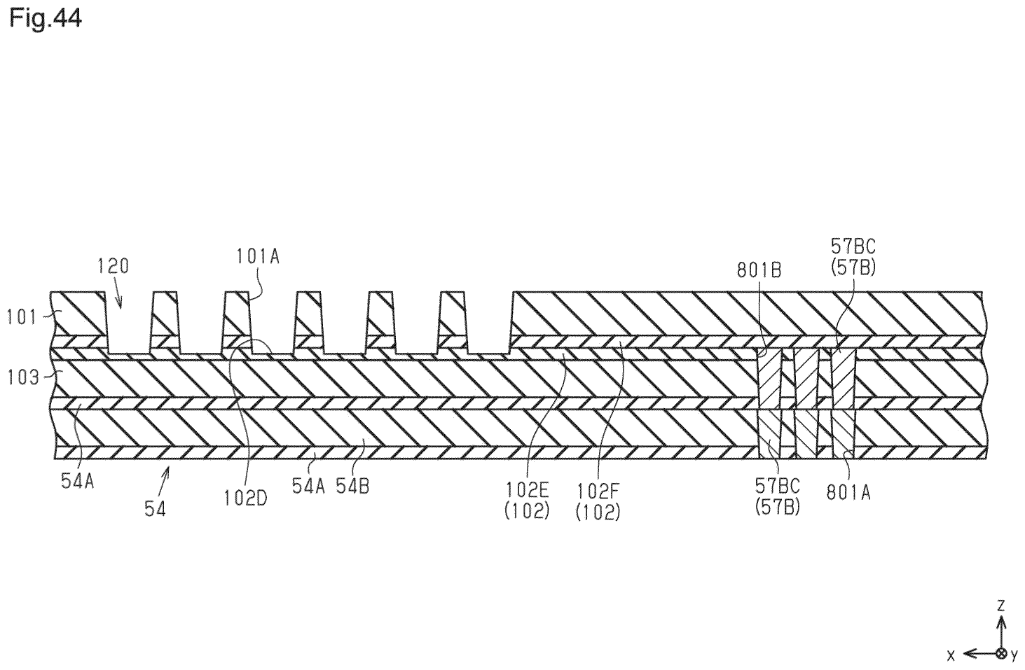

Next, FIG. 44 illustrates a process of forming the high-voltage coil 22A, following FIG. 43. More specifically, the first trench 120 is formed in the first insulation layer 101 and the second insulation layer 102 by, for example, etching. The first trench 120 extends through both of the first insulation layer 101 and the second high permittivity film 102F in the z direction. By contrast, the first trench 120 does not extend through the first high permittivity film 102E in the z direction. Thus, a through hole 101A is formed in the first insulation layer 101, and a groove 102D is formed in the first high permittivity film 102E.

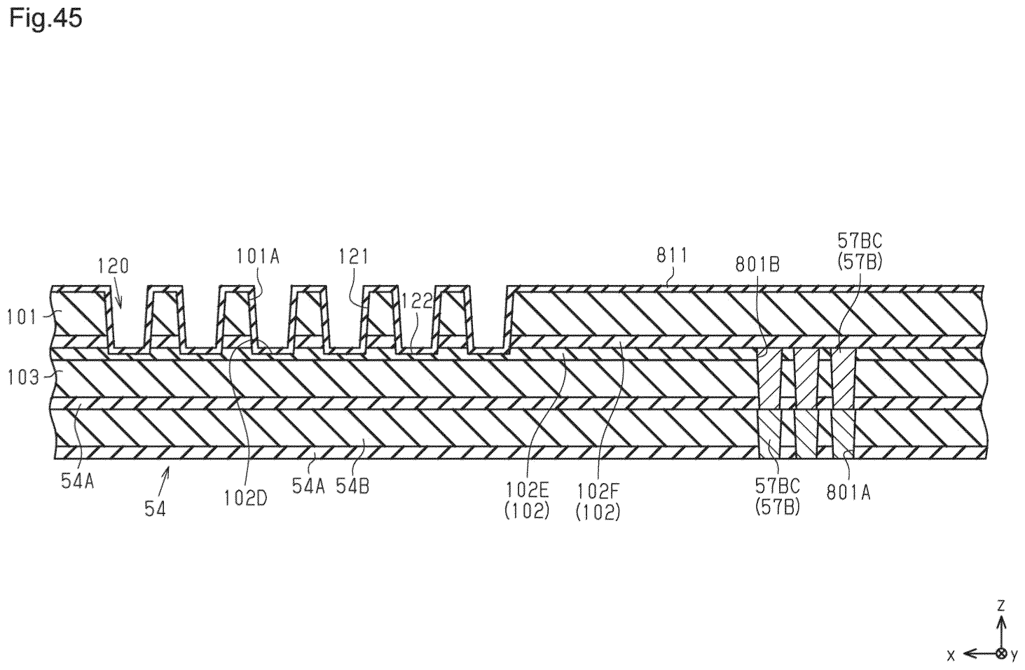

Next, FIG. 45 illustrates a step of forming a part of the element insulation layer 54, following FIG. 44. More specifically, in this step, a first coating layer 811 is formed on the first trench side surface 121 and the first trench bottom surface 122 of the first trench 120, and on the first insulation layer 101 using, for example, the CVD method. The first coating layer 811 is configured to be the first coating layer 111. The first coating layer 811 is a SiN film.

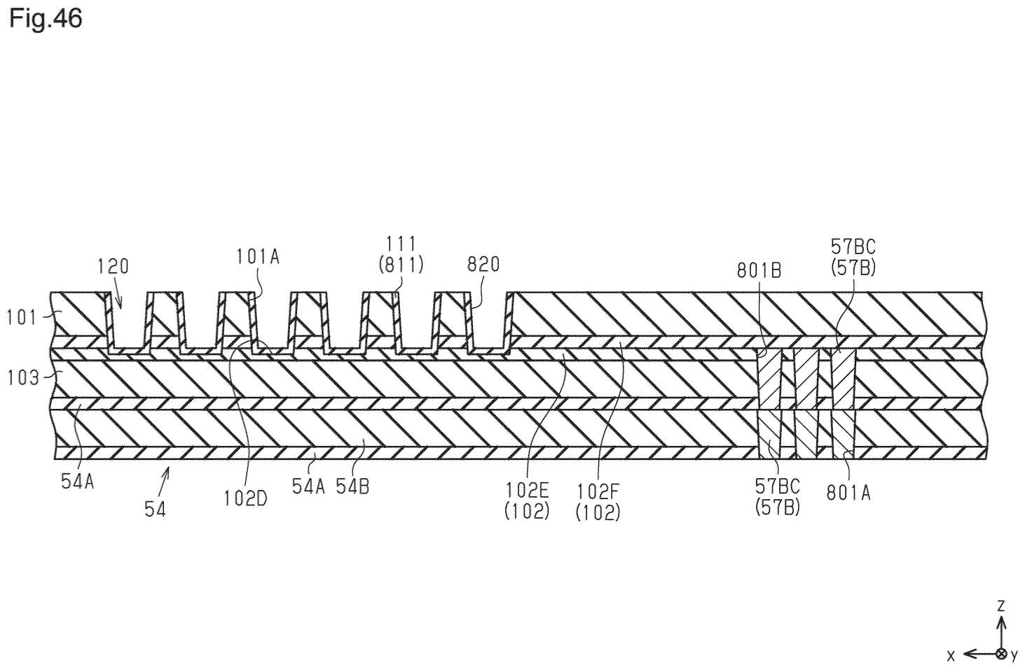

Next, FIG. 46 illustrates a step of forming a part of the element insulation layer 54, following FIG. 45. More specifically, in this step, a portion of the first coating layer 811 located above the first insulation layer 101 is removed by, for example, etching. This forms the first coating layer 111.

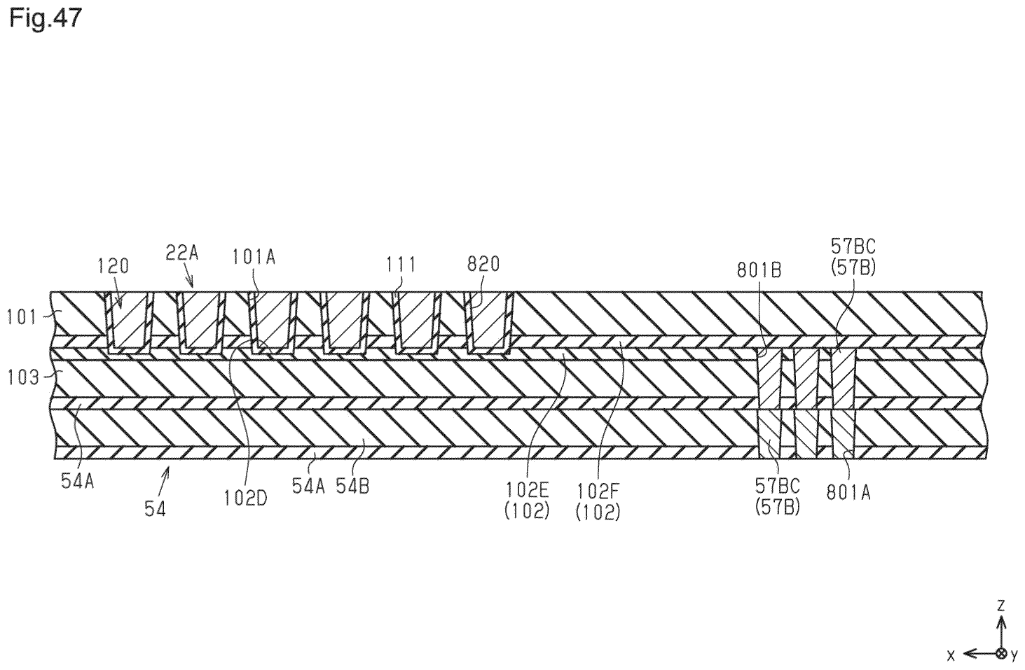

Next, FIG. 47 illustrates a process of forming the high-voltage coil 22A, following FIG. 46. More specifically, in this step, a recess 820 that is formed by the first coating layer 111 is filled with a metal material by, for example, sputtering. One example of the metal material is Cu. This forms the high-voltage coil 22A.

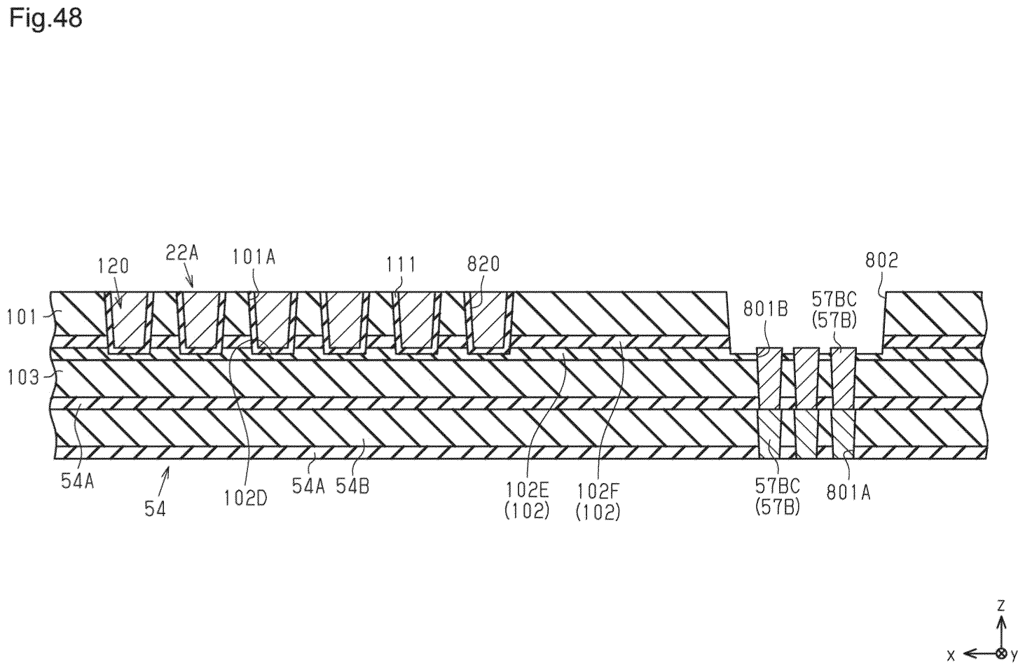

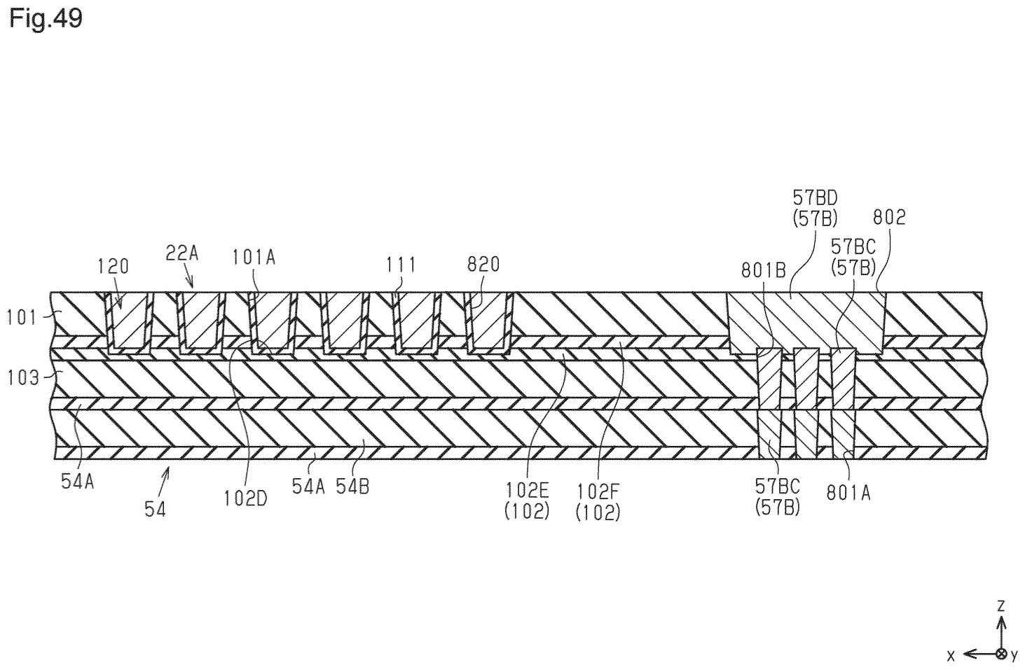

Next, FIGS. 48 and 49 illustrate a step of forming a part of the low-voltage side connection wiring 57B, following FIG. 47. More specifically, in this step, as illustrated in FIG. 48, the wiring opening 802 is formed in the first insulation layer 101 and the second insulation layer 102 by, for example, etching. The second via 57BC is thus exposed in the wiring opening 802.

The wiring opening 802 is filled with a metal material by, for example, sputtering as illustrated in FIG. 49. One example of the metal material is Cu. This forms the second wiring 57BD of the low-voltage side connection wiring 57B.

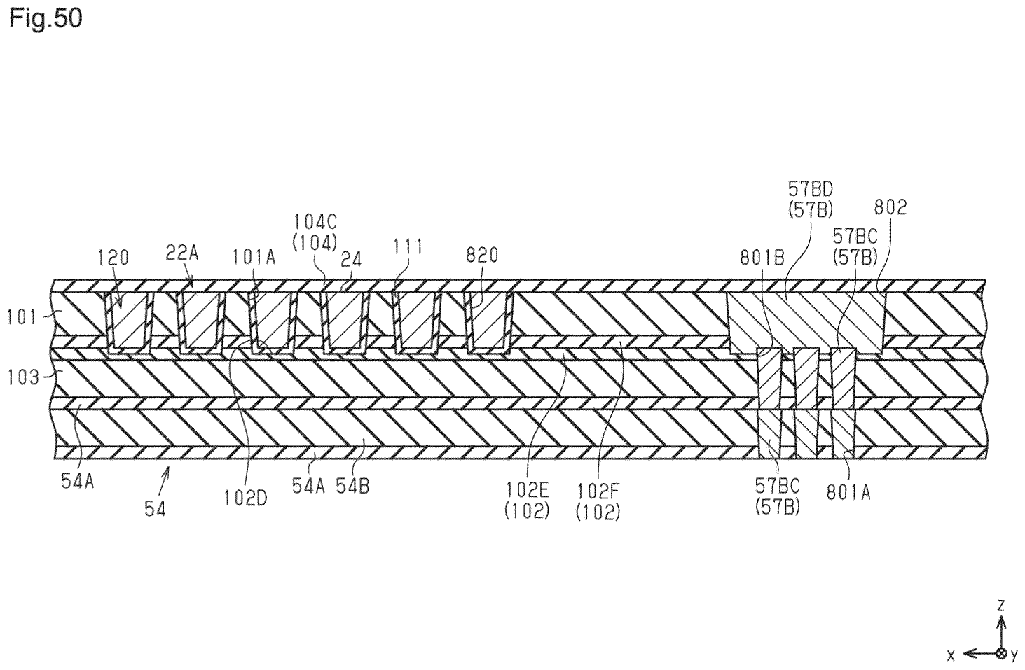

Next, FIGS. 50 to 52 illustrate a step of forming a part of the element insulation layer 54, following FIG. 49. More specifically, in this step, as illustrated in FIG. 50, the high permittivity lower film 104C of the fourth insulation layer 104 is formed by being deposited on the second end surface 24 of the low-voltage coil 21A, the second wiring 57BD of the low-voltage side connection wiring 57B, and the first insulation layer 101 using, for example, the CVD method. The high permittivity lower film 104C is a SiN film. Thus, in other words, the high permittivity lower film 104C is the etching stopper film 54A.

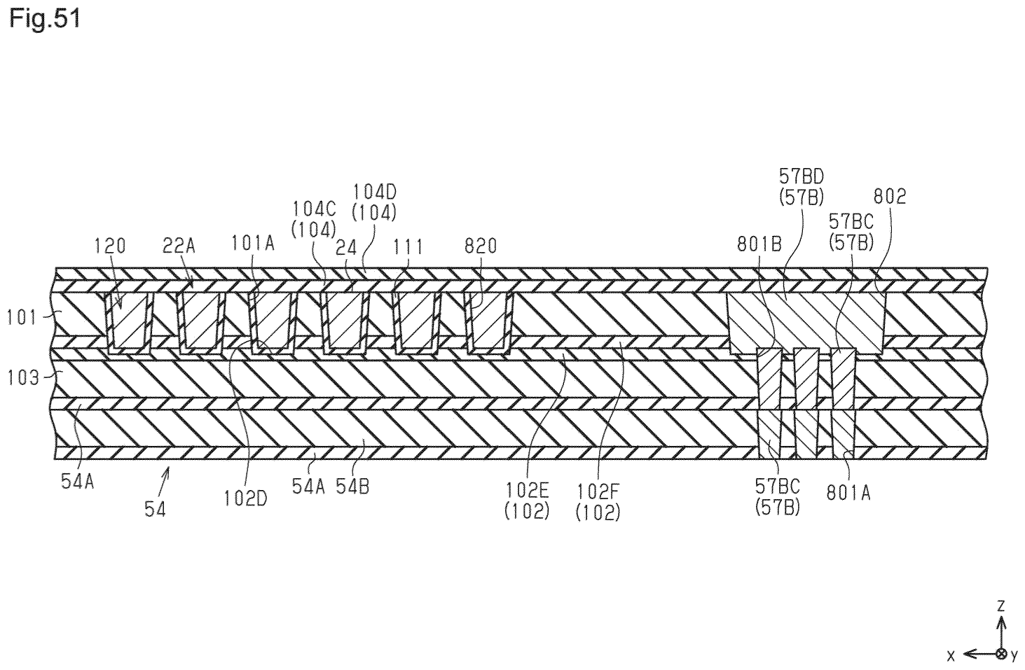

Next, as illustrated in FIG. 51, the high permittivity upper film 104D is formed by being deposited on the high permittivity lower film 104C using, for example, the CVD method. The high permittivity upper film 104D is a SiON film.

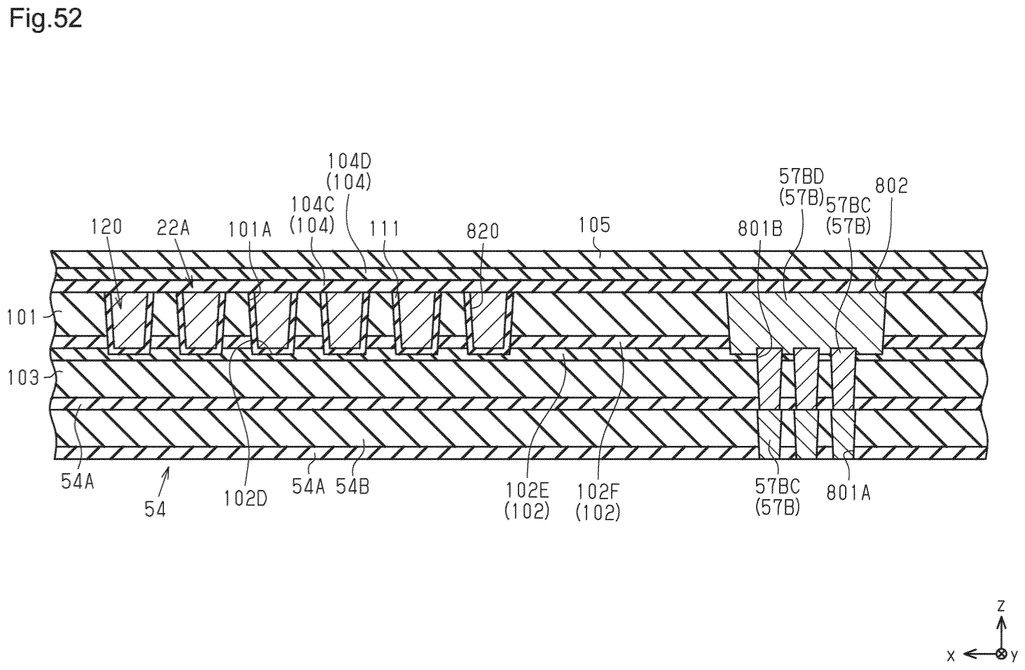

Next, as illustrated in FIG. 52, the fifth insulation layer 105 is formed by being deposited on the high permittivity upper film 104D, using, for example, the CVD method. The fifth insulation layer 105 is a SiO₂ film. Thus, in other words, the fifth insulation layer 105 includes the interlayer insulation film 54B.

Although not illustrated, the low-voltage coil 21A and the element insulation layer 54 around the low-voltage coil 21A are also formed in the same manner as the high-voltage coil 22A and the element insulation layer 54 around the high-voltage coil 22A. The low-voltage coil 21A and the element insulation layer 54 around the low-voltage coil 21A are formed in a step prior to the step of forming the high-voltage coil 22A and the element insulation layer 54 around the high-voltage coil 22A.

Subsequently, although not illustrated, a step of forming the vias 58A and 58B, a step of forming the electrode pads 51 and 52 on the element insulation layer 54, and a step of forming the protective film 55 and the passivation film 56 on the element insulation layer 54 are sequentially performed.

In the step of forming the vias 58A and 58B, a via opening is formed in the element insulation layer 54, and then the via opening is filled with a metal material in the same manner as the step of forming the low-voltage side connection wirings 57A and 57B. One example of the metal material is Cu.

Each of the electrode pads 51 and 52 is arranged on the element head surface 54s of the element insulation layer 54 by, for example, sputtering. Each of the electrode pads 51 and 52 is formed of, for example, Al.

Next, the protective film 55 is formed by being deposited on the element insulation layer 54 and each of the electrode pads 51 and 52 using, for example, the CVD method. The passivation film 56 is then formed by being deposited on the protective film 55 using, for example, the CVD method. For example, etching is performed to form an opening through which the electrode pads 51 and 52 are exposed from both the protective film 55 and the passivation film 56. The transformer chip 50 is manufactured through the steps described above.

### Method of Manufacturing Signal Transmitting Device

A method for manufacturing the signal transmitting device according to the fourth embodiment is the same as that according to the first embodiment; therefore, the description thereof will be omitted.

### Effects

According to the present embodiment, the following effects may be obtained.

(4-1) The transformer chip 50 includes: an element insulation layer 54; high-voltage coils 22A and 22B embedded in the element insulation layer 54; and low-voltage coils 21A and 21B embedded in the element insulation layer 54 and opposed to the respective high-voltage coils 22A and 22B, in the z direction. Each of the high-voltage coils 22A and 22B includes a first end surface 23 facing toward corresponding one of the low-voltage coils 21A and 21B in the z direction, a second end surface 24 located opposite to the first end surface 23, and a first side surface 25. The element insulation layer 54 includes: a first insulation layer 101; a first trench 120 formed in the first insulation layer 101 and having a first trench bottom surface 122 and a first trench side surface 121; and a first coating layer 111 arranged on the first trench bottom surface 122 and the first trench side surface 121, and having a relative permittivity higher than the relative permittivity of the first insulation layer 101. The high-voltage coils 22A and 22B are embedded in the first trench 120 such that the first end surface 23 and the first side surface 25 are in contact with the first coating layer 111.

With this configuration, the first end surface 23 and the first side surface 25 of each of the high-voltage coils 22A and 22B are covered by the first coating layer 111 having a relative permittivity higher than the relative permittivity of the first insulation layer 101. This reduces the intensity of the electric field on the first end surface 23 and the intensity of the electric field on the first side surface 25. Thus, the concentration of an electric field on the end portion of the high-voltage coils 22A and 22B located at the side of the low-voltage coils 21A and 21B is alleviated. In other words, the concentration of an electric field in the region between the high-voltage coil 22A (22B) and the low-voltage coil 21A (21B) is alleviated.

(4-2) The first coating layer 111 covers the lower end portion 25A of the first side surface 25 of each of the high-voltage coils 22A and 22B. The lower end portion 25A forms a corner with the first end surface 23.

With this configuration, the intensity of the electric field tends to be high on the lower end portion 25A, and the first coating layer 111 having a high relative permittivity covers the lower end portion 25A of the high-voltage coils 22A and 22B. This effectively alleviates the concentration of the electric field on the end portion of the high-voltage coils 22A and 22B at the side of the low-voltage coils 21A and 21B.

(4-3) The element insulation layer 54 includes: a second insulation layer 102 having a relative permittivity higher than the relative permittivity of the first insulation layer 101 and in contact with the first insulation layer 101; and a third insulation layer 103 having a relative permittivity lower than the relative permittivity of the second insulation layer 102 and in contact with the second insulation layer 102 at a side opposite to the first insulation layer 101. The second insulation layer 102 forms the first trench bottom surface 122 and is in contact with the first coating layer 111. The second insulation layer 102 includes a first high permittivity film 102E in contact with the third insulation layer 103. The relative permittivity of the first high permittivity film 102E is lower than the relative permittivity of the first coating layer 111.

With this configuration, the first coating layer 111, the first high permittivity film 102E of the second insulation layer 102, and the third insulation layer 103 are sequentially arranged in a direction from the first end surface 23 of the high-voltage coils 22A and 22B toward the low-voltage coils 21A and 21B. The relative permittivity is decreased in the order of the first coating layer 111, the first high permittivity film 102E of the second insulation layer 102, and the third insulation layer 103. That is, the relative permittivity of the element insulation layer 54 gradually decreases as the distance from the first end surface 23 increases in a direction from the high-voltage coils 22A and 22B toward the low-voltage coils 21A and 21B. This further reduces the intensity of the electric field on the first end surface 23 of the high-voltage coils 22A and 22B. Therefore, the concentration of the electric field on the end portion of the high-voltage coils 22A and 22B at the side of the low-voltage coils 21A and 21B is effectively alleviated.

(4-4) The element insulation layer 54 includes: a fourth insulation layer 104 arranged on the first insulation layer 101 so as to contact the second end surface 24 of the high-voltage coils 22A and 22B, and a fifth insulation layer 105 stacked on the fourth insulation layer 104. The fourth insulation layer 104 has a relative permittivity higher than the relative permittivity of the first insulation layer 101, and the fifth insulation layer 105 has a relative permittivity lower than the relative permittivity of the fourth insulation layer 104.

With this configuration, the fourth insulation layer 104 and the fifth insulation layer 105 are sequentially stacked on the second end surface 24 of the high-voltage coils 22A and 22B. The relative permittivity is decreased in the order of the fourth insulation layer 104 and the fifth insulation layer 105. That is, the relative permittivity of the element insulation layer 54 gradually decreases as the distance from the second end surface 24 increases in a direction from the high-voltage coils 22A and 22B toward the element head surface 54s of the element insulation layer 54. This reduces the intensity of the electric field on the second end surface 24 of the high-voltage coils 22A and 22B. Therefore, the concentration of the electric field on the end portion of the high-voltage coils 22A and 22B at the side opposite to the low-voltage coils 21A and 21B is alleviated.

(4-5) The fourth insulation layer 104 includes: a high permittivity lower film 104C in contact with the second end surface 24 of the high-voltage coils 22A and 22B, and a high permittivity upper film 104D formed on the high permittivity lower film 104C and in contact with the fifth insulation layer 105. The high permittivity upper film 104D has a relative permittivity lower than the relative permittivity of the high permittivity lower film 104C.

With this configuration, the fourth insulation layer 104 includes the high permittivity lower film 104C and the high permittivity upper film 104D that are sequentially stacked with respect to the second end surface 24 of the high-voltage coils 22A and 22B. The relative permittivity is decreased in the order of the high permittivity lower film 104C and the high permittivity upper film 104D. That is, the relative permittivity of the fourth insulation layer 104 gradually decreases as the distance from the second end surface 24 increases in a direction from the high-voltage coils 22A and 22B toward the element head surface 54s of the element insulation layer 54. This further reduces the intensity of the electric field on the second end surface 24 of the high-voltage coils 22A and 22B. Therefore, the concentration of the electric field on the end portion of the high-voltage coils 22A and 22B located at the side opposite to the low-voltage coils 21A and 21B is alleviated.

(4-6) The low-voltage coils 21A and 21B includes a third end surface 26 facing toward the high-voltage coils 22A and 22B in the z direction, a fourth end surface 27 located opposite to the third end surface 26, and a second side surface 28. The element insulation layer 54 includes: a sixth insulation layer 106; a seventh insulation layer 107 stacked on the sixth insulation layer 106 and having a relative permittivity higher than the relative permittivity of the sixth insulation layer 106; and an eighth insulation layer 108 stacked on the seventh insulation layer 107 and having a relative permittivity lower than the relative permittivity of the seventh insulation layer 107. The low-voltage coils 21A and 21B is arranged in the sixth insulation layer 106 such that the third end surface 26 is in contact with the seventh insulation layer 107.

With this configuration, the seventh insulation layer 107 having a relative permittivity higher than the relative permittivity of the sixth insulation layer 106 covers the third end surface 26 of the low-voltage coils 21A and 21B, thereby reducing the intensity of the electric field on the third end surface 26. Thus, the concentration of the electric field on the end portion of the low-voltage coils 21A and 21B located at the side of the high-voltage coils 22A and 22B is alleviated. In other words, the concentration of the electric field in the region between the high-voltage coil 22A (22B) and the low-voltage coil 21A (21B) is alleviated.

(4-7) The seventh insulation layer 107 includes: a third high permittivity film 107D in contact with the third end surface 26 of the low-voltage coils 21A and 21B; and a fourth high permittivity film 107E in contact with the eighth insulation layer 108. The relative permittivity of the fourth high permittivity film 107E is lower than the relative permittivity of the third high permittivity film 107D. The eighth insulation layer 108 has a relative permittivity lower than the relative permittivity of the fourth high permittivity film 107E.

With this configuration, the third high permittivity film 107D and the fourth high permittivity film 107E included in the seventh insulation layer 107, and the eighth insulation layer 108 are sequentially disposed with respect to the third end surface 26 of the low-voltage coils 21A and 21B. The relative permittivity is decreased in the order of the third high permittivity film 107D, the fourth high permittivity film 107E, and the eighth insulation layer 108. That is, the relative permittivity of the element insulation layer 54 gradually decreases as the distance from the third end surface 26 increases in a direction from the low-voltage coils 21A and 21B toward the high-voltage coils 22A and 22B. This reduces the electric field intensity on the third end surface 26 of the low-voltage coils 21A and 21B. Therefore, the concentration of the electric field on the end portion of the low-voltage coils 21A and 21B located at the side of the high-voltage coils 22A and 22B is effectively alleviated.

(4-8) The element insulation layer 54 includes: a ninth insulation layer 109 in contact with the fourth end surface 27 of the low-voltage coils 21A and 21B; and a tenth insulation layer 110 located opposite to the sixth insulation layer 106 with respect to the ninth insulation layer 109. The ninth insulation layer 109 has a relative permittivity higher than the relative permittivity of the sixth insulation layer 106. The relative permittivity of the tenth insulation layer 110 is lower than the relative permittivity of the ninth insulation layer 109.

With this configuration, the ninth insulation layer 109 and the tenth insulation layer 110 are sequentially disposed with respect to the fourth end surface 27 of the low-voltage coils 21A and 21B. The relative permittivity is decreased in the order of the ninth insulation layer 109 and the tenth insulation layer 110. That is, the relative permittivity of the element insulation layer 54 gradually decreases as the distance from the fourth end surface 27 increases in a direction from the low-voltage coils 21A and 21B toward the element back surface 54r of the element insulation layer 54. This reduces the intensity of the electric field on the fourth end surface 27 of the low-voltage coils 21A and 21B. Therefore, the concentration of the electric field on the end portion of the low-voltage coils 21A and 21B located at the side of the substrate 53 is alleviated.

(4-9) The signal transmitting device 10 includes a first chip 30 including a primary-side circuit 13, a transformer chip 50, and a second chip 40 including a secondary-side circuit 14 configured to perform at least one of reception of a signal and transmission of a signal with the primary-side circuit 13 through the transformer chip 50. The transformer chip 50 includes an element insulation layer 54, high-voltage coils 22A and 22B embedded in the element insulation layer 54, and low-voltage coils 21A and 21B embedded in the element insulation layer 54 and opposed to the respective high-voltage coils 22A and 22B in the z direction. Each of the high-voltage coils 22A and 22B includes a first end surface 23 facing toward corresponding one of the low-voltage coils 21A and 21B in the z direction, a second end surface 24 located opposite to the first end surface 23, and a first side surface 25. The element insulation layer 54 includes: a first insulation layer 101; a first trench 120 formed in the first insulation layer 101, and having a first trench bottom surface 122 and a first trench side surface 121; and a first coating layer 111 formed on the first trench bottom surface 122 and the first trench side surface 121 and having a relative permittivity higher than the relative permittivity of the first insulation layer 101. The high-voltage coils 22A and 22B are arranged in the first trench 120 such that the first end surface 23 and the first side surface 25 are in contact with the first coating layer 111.

With this configuration, the first end surface 23 and the first side surface 25 of each of the high-voltage coils 22A and 22B are covered by the first coating layer 111 having a relative permittivity higher than the relative permittivity of the first insulation layer 101. This reduces the intensity of the electric field on the first end surface 23 and reduces the intensity of the electric field on the first side surface 25. Thus, the concentration of an electric field on the end portion of the high-voltage coils 22A and 22B located at the side of the low-voltage coils 21A and 21B. is alleviated. In other words, the concentration of an electric field in the region between the high-voltage coil 22A (22B) and the low-voltage coil 21A (21B) is alleviated.

### Fifth Embodiment

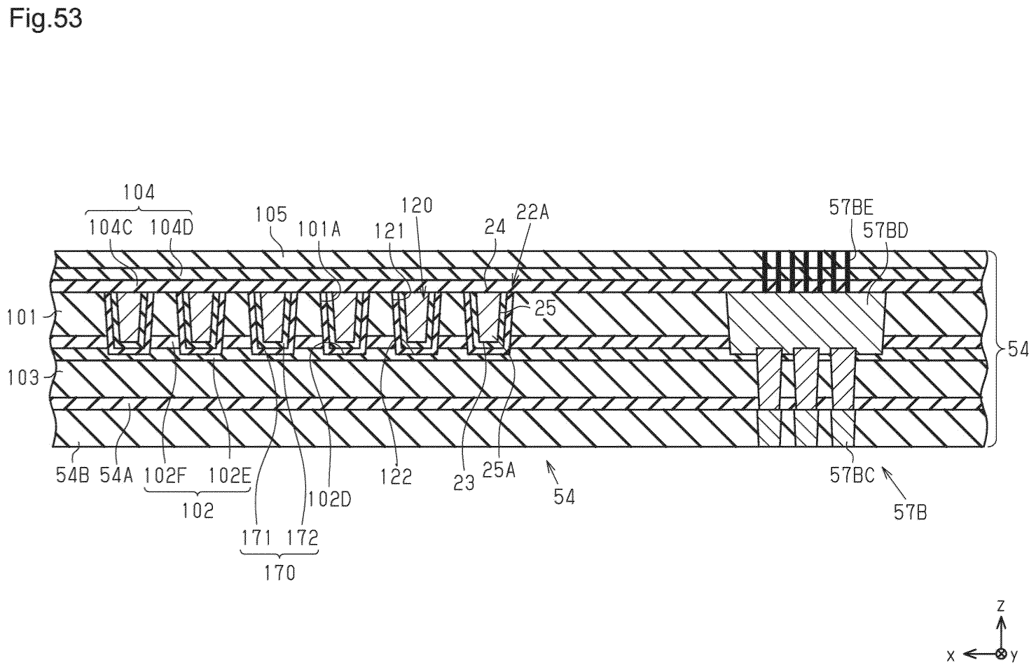

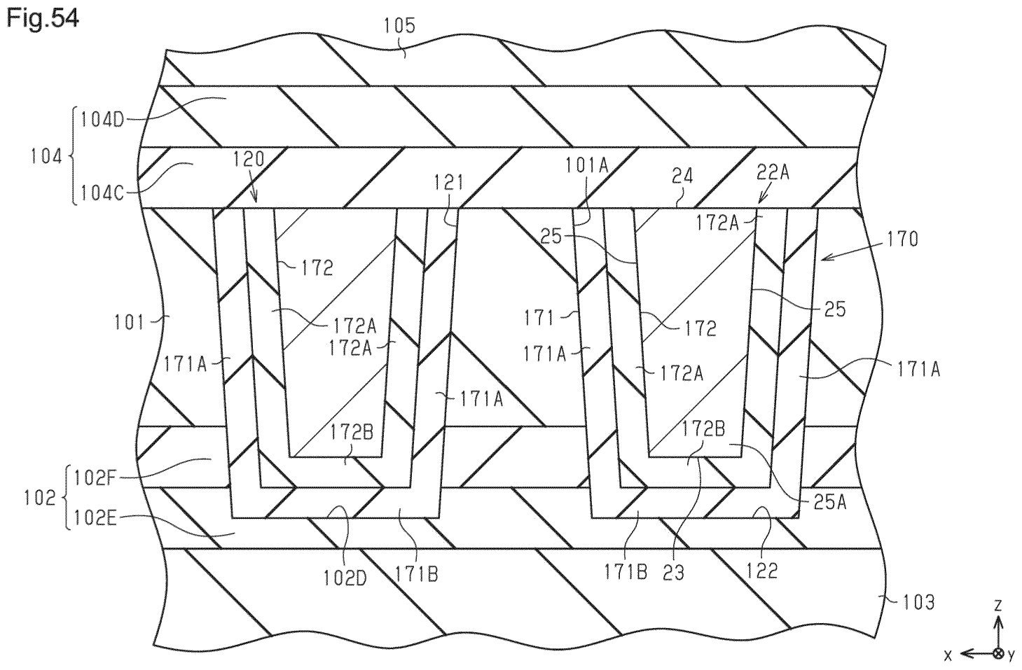

A configuration of a transformer chip 50 according to a fifth embodiment will now be described with reference to FIGS. 53 and 54. The transformer chip 50 according to the present embodiment differs from the transformer chip 50 according to the fourth embodiment in the structure for alleviating the concentration of an electric field on the high-voltage coil 22A and the low-voltage coil 21A. In the following description, the same components as those according to the fourth embodiment are denoted by the same reference signs, and the description thereof will be omitted.

As illustrated in FIG. 53, in the present embodiment, the element insulation layer 54 includes a first coating layer 170 instead of the first coating layer 111 (refer to FIG. 36). The first coating layer 170 has a stacked structure including two insulation films. In the same manner as the first coating layer 111, the first coating layer 170 is arranged on the first trench bottom surface 122 and the first trench side surface 121 of the first trench 120. The high-voltage coil 22A is arranged in the first trench 120 and in contact with the first coating layer 170.

The first coating layer 170 includes a first high permittivity coating film 171 and a second high permittivity coating film 172.

The first high permittivity coating film 171 is in contact with the first trench bottom surface 122 and the first trench side surface 121. That is, the first high permittivity coating film 171 is in contact with the first high permittivity film 102E of the second insulation layer 102 and with the first insulation layer 101. More specifically, as illustrated in FIG. 54, the first high permittivity coating film 171 includes a first side surface portion 171A and a first bottom surface portion 171B. The first side surface portion 171A and the first bottom surface portion 171B are integrally formed. The first side surface portion 171A is in contact with the first trench side surface 121, that is, with the first insulation layer 101. The first bottom surface portion 171B is in contact with the first trench bottom surface 122, that is, with the first high permittivity film 102E.

The first high permittivity coating film 171 has a thickness smaller than the etching stopper film 54A (refer to FIG. 53). The first high permittivity coating film 171 has a thickness equal to the thickness of the second high permittivity coating film 172. It is considered that the thickness of the first high permittivity coating film 171 is equal to the thickness of the second high permittivity coating film 172, for example, when the difference between the thickness of the first high permittivity coating film 171 and the thickness of the second high permittivity coating film 172 is within 20% of the thickness of the first high permittivity coating film 171. The first high permittivity coating film 171 has a relative permittivity higher than the relative permittivity of the first insulation layer 101. In one example, the relative permittivity of the first high permittivity coating film 171 is within a range greater than 3.8 and less than 7. In one example, the relative permittivity of the first high permittivity coating film 171 may be within a range greater than 4 and less than 7. The first high permittivity coating film 171 is formed from a material including SiON. Hence, the relative permittivity of the first high permittivity coating film 171 is adjusted within the range described above in accordance with the concentration of nitrogen in SiON.

The second high permittivity coating film 172 is stacked on the first high permittivity coating film 171. More specifically, the second high permittivity coating film 172 includes a second side surface portion 172A and a second bottom surface portion 172B. The second side surface portion 172A and the second bottom surface portion 172B are integrally formed. The second side surface portion 172A is in contact with the first side surface portion 171A of the first high permittivity coating film 171. The second bottom surface portion 172B is in contact with the first bottom surface portion 171B of the first high permittivity coating film 171.

The second high permittivity coating film 172 covers the first end surface 23 and the lower end portion 25A of the first side surface 25 of the high-voltage coil 22A. More specifically, the first end surface 23 is in contact with the second bottom surface portion 172B, and the first side surface 25 is in contact with the second side surface portion 172A. In other words, the second high permittivity coating film 172 is in contact with both of the first end surface 23 and the lower end portion 25A of the first side surface 25.

The second high permittivity coating film 172 has a relative permittivity higher than the relative permittivity of the first high permittivity coating film 171. The second high permittivity coating film 172 is formed from a material including SiN. Therefore, the second high permittivity coating film 172 has a relative permittivity of approximately 7.

As described above, in the structure for alleviating the concentration of an electric field on the high-voltage coil 22A, the second high permittivity coating film 172 and the first high permittivity coating film 171 of the first coating layer 170, the first high permittivity film 102E of the second insulation layer 102, and the third insulation layer 103 are sequentially arranged in a direction from the first end surface 23 of the high-voltage coil 22A toward the low-voltage coil 21A. That is, the relative permittivity is configured to be decreased in the direction from the first end surface 23 of the high-voltage coil 22A toward the low-voltage coil 21A.

In addition, in the structure for alleviating the concentration of an electric field on the first side surface 25 of the high-voltage coil 22A, the second high permittivity coating film 172 and the first high permittivity coating film 171 of the first coating layer 170 and the first insulation layer 101 are sequentially arranged in a direction extending orthogonal to the z direction away from the first side surface 25 of the high-voltage coil 22A. That is, the relative permittivity is configured to be decreased in the direction extending away from the first side surface 25 of the high-voltage coil 22A.

Although not illustrated, the structure for alleviating the concentration of an electric field on the low-voltage coil 21A may also be changed in the same manner. That is, the configuration of the second coating layer 112 (refer to FIG. 38) according to the fourth embodiment may be changed to have a stacked structure including two high permittivity films in the same manner as the first coating layer 170.

### Effects

According to the present embodiment, the following effects may be obtained.

(5-1) The first coating layer 170 includes: a first high permittivity coating film 171 in contact with the first trench bottom surface 122 and the first trench side surface 121 of the first trench 120; and a second high permittivity coating film 172 stacked on the first high permittivity coating film 171. The first coating layer 170 has a relative permittivity higher than the relative permittivity of the first insulation layer 101 and the relative permittivity of the third insulation layer 103. The relative permittivity of the second high permittivity coating film 172 is higher than the relative permittivity of the first high permittivity coating film 171.

With this configuration, the second high permittivity coating film 172 and the first high permittivity coating film 171 are sequentially arranged with respect to the first end surface 23 of the high-voltage coils 22A and 22B. The relative permittivity is decreased in the order of the second high permittivity coating film 172, the first high permittivity coating film 171, and the third insulation layer 103. That is, the relative permittivity gradually decreases as the distance from the first end surface 23 increases in a direction from the first end surface 23 of the high-voltage coils 22A and 22B toward the low-voltage coils 21A and 21B. This reduces the intensity of the electric field on the first end surface 23 of the high-voltage coils 22A and 22B. Thus, the concentration of the electric field on the end portion of the high-voltage coils 22A and 22B located at the side of the low-voltage coils 21A and 21B is alleviated. That is, the concentration of the electric field in the region between the high-voltage coil 22A (22B) and the low-voltage coil 21A (21B) is alleviated.

In addition, the second high permittivity coating film 172, the first high permittivity coating film 171, and the first insulation layer 101 are sequentially arranged with respect to the first side surface 25 of the high-voltage coils 22A and 22B. That is, the relative permittivity decreases as the distance from the first side surface 25 of the high-voltage coils 22A and 22B increases in the direction orthogonal to the z direction. This reduces the intensity of the electric field on the first side surface 25 of the high-voltage coils 22A and 22B. Thus, the concentration of an electric field on the first side surface 25 of the high-voltage coils 22A and 22B is alleviated more effectively.

### Sixth Embodiment

A signal transmitting device 10 according to a sixth embodiment may be the signal transmitting device 10 according to the fourth embodiment that includes transformers 18A (18B) and 19A (19B) in the same manner as in the third embodiment. The details of the sixth embodiment are the same as those of the third embodiment and thus will not be described.

### MODIFIED EXAMPLES

Each of the embodiments described above may be modified in the manner described below. Each of the embodiments described above and the modified examples described below may be implemented in any combination within a scope in which such a combination is not technically inconsistent. For example, a transformer chip 50 including the transformers 18A (18B) and 19A (19B) according to the sixth embodiment may be applied to the fifth embodiment.

### Modified Example of Transformer Chip

In the fourth and sixth embodiments, the configuration of the second coating layer 112 may be changed to have a stacked structure including a plurality of high permittivity coating films in the same manner as the first coating layer 170 according to the fifth embodiment.

In the fifth embodiment, the structure of the second coating layer 112 may be changed to a single film (high permittivity film) in the same manner as the second coating layer 112 according to the fourth embodiment.

In the fourth and sixth embodiments, the structure for alleviating the concentration of an electric field on the low-voltage coil 21A at the side of the high-voltage coil 22A may be omitted. In one example, the etching stopper film 54A may be used instead of the seventh insulation layer 107. In this structure, the third end surface 26 of the low-voltage coil 21A is in contact with the etching stopper film 54A. In one example, the second trench 130 forming the low-voltage coil 21A in the element insulation layer 54 may be arranged in a manner extending through both of one interlayer insulation film 54B and one etching stopper film 54A. The interlayer insulation film 54B immediately below the etching stopper film 54A includes the second trench bottom surface 132 of the second trench 130. In this structure, the fourth end surface 27 of the low-voltage coil 21A is in contact with the interlayer insulation film 54B immediately below the etching stopper film 54A. In the fifth embodiment, the structure for alleviating the concentration of an electric field on the low-voltage coil 21A at the side of the high-voltage coil 22A may be omitted in the same manner.

In the fourth embodiment, the structure for alleviating the concentration of an electric field on the low-voltage coil 21A at the side of the substrate 53 may be omitted. In one example, the etching stopper film 54A may be used instead of the ninth insulation layer 109. In this structure, the fourth end surface 27 of the low-voltage coil 21A is in contact with the etching stopper film 54A. In the fifth embodiment, the structure for alleviating the concentration of an electric field on the low-voltage coil 21A at the side of the substrate 53 may be omitted in the same manner.

In the fourth and sixth embodiments, the relative permittivity of the first coating layer 111 may be changed to any value higher than the relative permittivity of the first insulation layer 101 (third insulation layer 103). In one example, the first coating layer 111 may have a relative permittivity lower than the relative permittivity of the first coating layer 111 according to the fourth embodiment. In such a case, the first coating layer 111 may be formed from a material including, for example, SiON.

In the fourth and sixth embodiments, the relative permittivity of each of the first high permittivity film 102E and the second high permittivity film 102F of the second insulation layer 102 may be changed to any value higher than the relative permittivity of the first insulation layer 101 (third insulation layer 103). In one example, the second high permittivity film 102F may have a relative permittivity lower than the relative permittivity of the first high permittivity film 102E. In such a case, the second high permittivity film 102F may be formed from a material including, for example, SiON, and the first high permittivity film 102E may be formed from a material including, for example, SiN. In such a case, the second high permittivity film 102F has a relative permittivity of approximately 7, and the first high permittivity film 102E has a relative permittivity higher than 3.8 and lower than 7. In one example, the first high permittivity film 102E may have a relative permittivity higher than 4 and lower than 7. The second high permittivity film 102F may also have a relative permittivity equal to the relative permittivity of the first high permittivity film 102E. In such a case, each of the first high permittivity film 102E and the second high permittivity film 102F may be formed from a material including, for example, any one of SiN, SiC, and SiON.

In the fifth embodiment, the relative permittivity of each of the first high permittivity coating film 171 and the second high permittivity coating film 172 included in the first coating layer 170 may be changed to any value higher than the relative permittivity of the first insulation layer 101 (third insulation layer 103). In one example, the first high permittivity coating film 171 may have a relative permittivity greater than or equal to the relative permittivity of the second high permittivity coating film 172. In such a case, each of the first high permittivity coating film 171 and the second high permittivity coating film 172 may be formed from a material including, for example, SiN. In such a case, each of the first high permittivity coating film 171 and the second high permittivity coating film 172 has a relative permittivity of approximately 7. Each of the first high permittivity coating film 171 and the second high permittivity coating film 172 may be formed from a material including, for example, SiON. In such a case, each of the first high permittivity coating film 171 and the second high permittivity coating film 172 has a relative permittivity higher than 3.8 and lower than 7. In one example, the relative permittivity of each of the first high permittivity coating film 171 and the second high permittivity coating film 172 may be in the range of more than 4 and less than 7. The relative permittivity of each of the first high permittivity coating film 171 and the second high permittivity coating film 172 is adjusted within the range described above in accordance with the concentration of nitrogen in SiON.

In addition, the first high permittivity coating film 171 may be formed from a material including, for example, SiN, and the second high permittivity coating film 172 may be formed from a material including, for example, SiON. In such a case, the first high permittivity coating film 171 has a relative permittivity of approximately 7, and the second high permittivity coating film 172 has a relative permittivity higher than 3.8 and lower than 7. In one example, the second high permittivity coating film 172 may have a relative permittivity within a range greater than 4 and less than 7. The relative permittivity of the second high permittivity coating film 172 is adjusted within the range described above in accordance with the concentration of nitrogen in SiON.

In the fifth embodiment, the thickness of each of the first high permittivity coating film 171 and the second high permittivity coating film 172 of the first coating layer 170 may be changed in any manner. In one example, the first high permittivity coating film 171 may have a thickness greater or smaller than the thickness of the second high permittivity coating film 172. In addition, the thickness of the first coating layer 170, that is, the total thickness including the first high permittivity coating film 171 and the second high permittivity coating film 172 may be greater than the thickness of the etching stopper film 54A.

In the fourth to sixth embodiments, the positional relationship between the second insulation layer 102 and the high-voltage coil 22A in the z direction may be changed in any manner. In one example, the first trench 120 for forming the high-voltage coil 22A does not need to have the groove 102D (refer to FIG. 36) in the second insulation layer 102. That is, the portion of the second insulation layer 102 including the first trench bottom surface 122 of the first trench 120 may have the same thickness as the remaining portion of the second insulation layer 102.

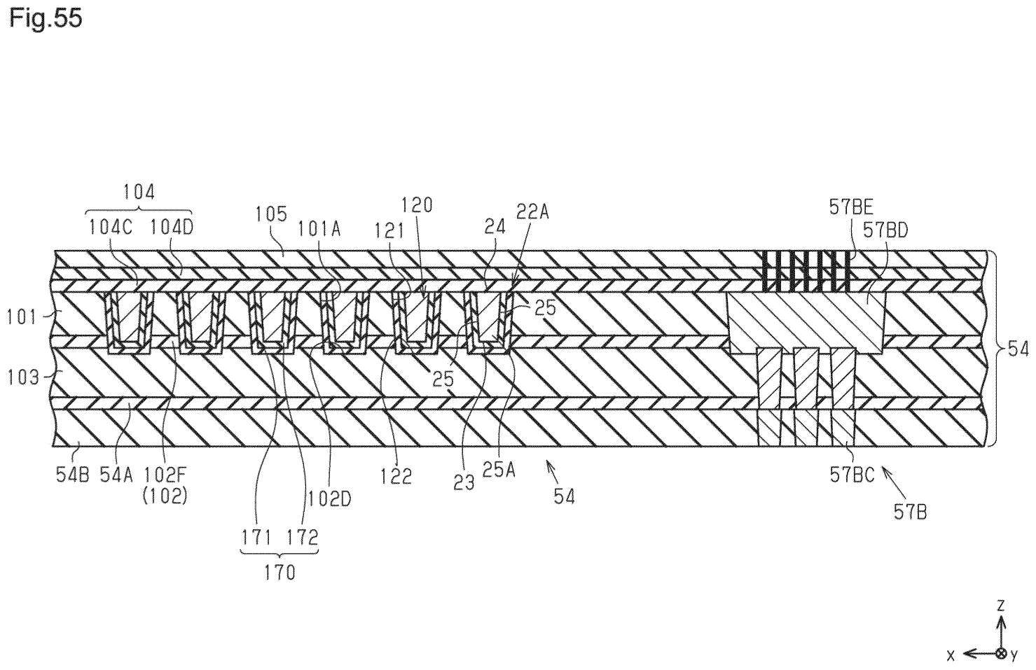

In the fourth to sixth embodiments, the number of high permittivity films included in the second insulation layer 102 may be changed in any manner. In one example, the second insulation layer 102 may be a single film (high permittivity film). In one example, as illustrated in FIG. 55, while not including the first high permittivity film 102E, the second insulation layer 102 may include the second high permittivity film 102F. In such a case, the second insulation layer 102 is formed from a material including, for example, SiN. In other words, the second insulation layer 102 has a relative permittivity higher than the relative permittivity of the third insulation layer 103 (first insulation layer 101). In other words, the second insulation layer 102 includes the etching stopper film 54A. The first coating layer 170 extends through the second insulation layer 102 in the z direction. In the illustrated example, the first coating layer 170 protrudes downwards from the second insulation layer 102. Therefore, the first coating layer 170 is in contact with the third insulation layer 103. In one example, although not illustrated, while not including the second high permittivity film 102F, the second insulation layer 102 may include the first high permittivity film 102E. In such a case, the second insulation layer 102 is formed from a material including, for example, SiON. The second insulation layer 102 is configured to cover the lower end portion of the first coating layer 170. In another example, the second insulation layer 102 may have a stacked structure including four or more high permittivity films.

In the fourth to sixth embodiments, the thickness of each of the first high permittivity film 102E and the second high permittivity film 102F of the second insulation layer 102 may be changed in any manner. In one example, each of the first high permittivity film 102E and the second high permittivity film 102F may have a different thickness. In one example, the thickness of the first high permittivity film 102E may be greater than the thickness of the second high permittivity film 102F. The thickness of the first high permittivity film 102E may be smaller than the thickness of the second high permittivity film 102F.

In the fourth to sixth embodiments, the relative permittivity of each of the high permittivity lower film 104C and the high permittivity upper film 104D of the fourth insulation layer 104 may be changed to any value higher than the relative permittivity of the fifth insulation layer 105. In one example, the relative permittivity of the high permittivity lower film 104C and the relative permittivity of the high permittivity upper film 104D may be equal to each other. In such a case, each of the high permittivity lower film 104C and the high permittivity upper film 104D may be formed from a material including any one of SIN, SiON, and SiC.

In the fourth to sixth embodiments, the number of high permittivity films included in the fourth insulation layer 104 may be changed in any manner. In one example, the fourth insulation layer 104 may be a single film (high permittivity film). In such a case, the fourth insulation layer 104 is formed from a material including any one of SiN, SiON, and SiC. In other words, the fourth insulation layer 104 has a relative permittivity higher than the relative permittivity of the third insulation layer 103. In another example, the fourth insulation layer 104 may have a stacked structure including three or more high permittivity films. Further, an etching stopper film 54A may be arranged instead of the fourth insulation layer 104.

In the fourth to sixth embodiments, the thickness of each of the high permittivity lower film 104C and the high permittivity upper film 104D of the fourth insulation layer 104 may be changed in any manner. In one example, each of the high permittivity lower film 104C and the high permittivity upper film 104D may have a different thickness. For example, the thickness of the high permittivity lower film 104C may be greater than the thickness of the high permittivity upper film 104D. For example, the thickness of the high permittivity lower film 104C may be smaller than the thickness of the high permittivity upper film 104D.

In the fourth to sixth embodiments, the relative permittivity of each of the third high permittivity film 107D and the fourth high permittivity film 107E of the seventh insulation layer 107 may be changed to any value higher than the relative permittivity of the eighth insulation layer 108 (sixth insulation layer 106). In one example, the relative permittivity of the fourth high permittivity film 107E may be higher than the relative permittivity of the third high permittivity film 107D. In such a case, the fourth high permittivity film 107E may be formed from a material including, for example, SiN, and the third high permittivity film 107D may be formed from a material including, for example, SiON. In such a case, the fourth high permittivity film 107E has a relative permittivity of approximately 7, and the third high permittivity film 107D has a relative permittivity higher than 3.8 and lower than 7. In one example, the relative permittivity of the third high permittivity film 107D may be within a range greater than 4 and less than 7. The relative permittivity of the third high permittivity film 107D is adjusted within the range described above in accordance with the concentration of nitrogen in SiON. The relative permittivity of the fourth high permittivity film 107E may be equal to the relative permittivity of the third high permittivity film 107D. In such a case, each of the third high permittivity film 107D and the fourth high permittivity film 107E may be formed from a material including, for example, SiN. In such a case, each of the third high permittivity film 107D and the fourth high permittivity film 107E has a relative permittivity of approximately 7. In addition, each of the high permittivity films 107D and 107E may be formed from a material including SiON. The relative permittivity of each of the high permittivity films 107D and 107E is within a range greater than 3.8 and less than 7. In one example, the relative permittivity of each of the high permittivity films 107D and 107E may be within a range greater than 4 and less than 7. The relative permittivity of each of the high permittivity films 107D and 107E is adjusted within the range described above in accordance with the concentration of nitrogen in SiON.

In the fourth to sixth embodiments, the number of high permittivity films included in the seventh insulation layer 107 may be changed in any manner. In one example, the seventh insulation layer 107 may be a single film (high permittivity film). In such a case, the seventh insulation layer 107 is formed from a material including any one of SIN, SiON, and SiC. In other words, the seventh insulation layer 107 has a relative permittivity higher than the relative permittivity of the eighth insulation layer 108 (sixth insulation layer 106). In another example, the seventh insulation layer 107 may have a stacked structure including four or more high permittivity films.

In the fourth to sixth embodiments, the thickness of each of the third high permittivity film 107D and the fourth high permittivity film 107E of the seventh insulation layer 107 may be changed in any manner. In one example, each of the third high permittivity film 107D and the fourth high permittivity film 107E may have a different thickness. In one example, the thickness of the third high permittivity film 107D may be greater than the thickness of the fourth high permittivity film 107E. In one example, the thickness of the third high permittivity film 107D may be smaller than the thickness of the fourth high permittivity film 107E.

In the fourth to sixth embodiments, the relative permittivity of each of the high permittivity lower film 109D and the high permittivity upper film 109E of the ninth insulation layer 109 may be changed to any value higher than the relative permittivity of the tenth insulation layer 110 (sixth insulation layer 106). In one example, the relative permittivity of the high permittivity lower film 109D and the relative permittivity of the high permittivity upper film 109E may be equal to each other. In such a case, each of the high permittivity lower film 109D and the high permittivity upper film 109E may be formed from a material including any one of SIN, SiON, and SiC. In one example, the relative permittivity of the high permittivity lower film 109D may be lower than the relative permittivity of the high permittivity upper film 109E. In such a case, the high permittivity lower film 109D is formed from a material including SiON, and the high permittivity upper film 109E is formed from a material including SiN.

In the fourth to sixth embodiments, the number of high permittivity films included in the ninth insulation layer 109 may be changed in any manner. In one example, the ninth insulation layer 109 may be a single film (high permittivity film). In such a case, the ninth insulation layer 109 is formed from a material including any one of SIN, SiON, and SiC. In other words, the ninth insulation layer 109 has a relative permittivity higher than the relative permittivity of the tenth insulation layer 110 (sixth insulation layer 106). In another example, the ninth insulation layer 109 may have a stacked structure including three or more high permittivity films.

In the fourth to sixth embodiments, the thickness of each of the high permittivity lower film 109D and the high permittivity upper film 109E of the ninth insulation layer 109 may be changed in any manner. In one example, the thickness of the high permittivity upper film 109E may be greater than the thickness of the high permittivity lower film 109D. In one example, the thickness of the high permittivity upper film 109E may be smaller than the thickness of the high permittivity lower film 109D.

In the sixth embodiment, the insulation member 150 sandwiched between the transformer chip 50 and the secondary-side die pad 70 may be omitted. An example is illustrated in FIG. 33. The transformer chip 50 is different from that of the sixth embodiment in the arrangement configuration of the low-voltage coil 21A, the high-voltage coil 22A, the first high-voltage coil 21C, and the second high-voltage coil 22C.

The details are as described with reference to FIG. 33, and thus the description thereof is omitted.

### Modified Example of Signal Transmitting Device

In the sixth embodiment, the transformer chip 50 may be divided into two transformer chips, namely, a first transformer chip and a second transformer chip. The first transformer chip is a package including the transformers 18A and 18B, and the second transformer chip is a package including the transformers 19A and 19B. The first transformer chip is mounted on the primary-side die pad 60, and the second transformer chip is mounted on the secondary-side die pad 70. The first transformer chip and the second transformer chip are disposed between the first chip 30 and the second chip 40 in the x direction. The first transformer chip is connected to the first chip 30 via a wire W, and the second transformer chip is connected to the second chip 40 via a wire W. The first transformer chip and the second transformer chip are connected via a wire W. Thus, the low-voltage coil 21A (21B) is electrically connected to the primary-side circuit 13; the second high-voltage coil 22C (22D) is electrically connected to the secondary-side circuit 14; and the high-voltage coil 22A (22B) and the first high-voltage coil 21C (21D) are electrically connected to each other.

In the fourth to sixth embodiments, the arrangement configuration of the transformer chip 50 may be changed in any manner. In one example, the transformer chip 50 may be mounted on the primary-side die pad 60. In such a case, both of the first chip 30 and the transformer chip 50 are mounted on the primary-side die pad 60.

Furthermore, as illustrated in FIG. 34, the transformer chip 50 may be mounted on the intermediate die pad 160. The intermediate die pad 160 is disposed between the primary-side die pad 60 and the secondary-side die pad 70 in the x direction. The intermediate die pad 160 is electrically connected neither to the primary-side die pad 60 nor to the secondary-side die pad 70. In other words, the intermediate die pad 160 is in an electrically floating state with respect to the primary-side die pad 60 and the secondary-side die pad 70. The intermediate die pad 160 is formed of, for example, the same material as those of the primary-side die pad 60 and the secondary-side die pad 70. The intermediate die pad 160 corresponds to a “third die pad”.

The transformer chip 50 is also applicable to devices other than the signal transmitting device 10 of the fourth to sixth embodiments.

In a first example, the transformer chip 50 may be applied to, for example, a primary-side circuit module. That is, the primary-side circuit module includes the first chip 30, the transformer chip 50, and the encapsulation resin encapsulating the chips 30 and 50. The primary-side circuit module includes the primary-side die pad 60 on which both of the first chip 30 and the transformer chip 50 are mounted. The first chip 30 is bonded to the primary-side die pad 60 by the primary bonding material 91, and the transformer chip 50 is bonded to the primary-side die pad 60 by the third bonding material 93. In such a case, the primary-side circuit 13 included in the first chip 30 corresponds to the “signal transmitting circuit”, and the first chip 30 corresponds to the “circuit chip”. The primary-side circuit module corresponds to the “insulation module”.

In a second example, the transformer chip 50 may be applied to, for example, a secondary-side circuit module. That is, the secondary-side circuit module includes the second chip 40, the transformer chip 50, and the encapsulation resin encapsulating the chips 40 and 50. The secondary-side circuit module includes the secondary-side die pad 70 on which the second chip 40 and the transformer chip 50 are mounted. The second chip 40 is bonded to the secondary-side die pad 70 by the secondary bonding material 92, and the transformer chip 50 is bonded to the secondary-side die pad 70 by the third bonding material 93. In such a case, the secondary-side circuit 14 included in the second chip 40 corresponds to the “signal transmitting circuit”, and the second chip 40 corresponds to the “circuit chip”. The secondary-side circuit module corresponds to the “insulation module”.

In a third example, only the transformer chip 50 may be put into a module. That is, the insulation module includes the transformer chip 50 and the encapsulation resin encapsulating the transformer chip 50. The insulation module also includes a die pad on which the transformer chip 50 is mounted. The transformer chip 50 is bonded to the die pad by the third bonding material 93.

In the fourth to sixth embodiments, the configuration of the signal transmitting device 10 may be changed in any manner.

In one example, the signal transmitting device 10 may include the primary-side circuit module described above and the second chip 40. In such a case, the second chip 40 may be mounted on the secondary-side die pad 70, and both of the secondary-side die pad 70 and the second chip 40 may be encapsulated by an encapsulation resin and configured as a module. The signal transmitting device 10 includes the primary-side circuit module and the module described above.

In another example, the signal transmitting device 10 may include the secondary-side circuit module described above and the first chip 30. In such a case, the first chip 30 may be mounted on the primary-side die pad 60, and both of the primary-side die pad 60 and the first chip 30 may be encapsulated by an encapsulation resin and configured as a module. The signal transmitting device 10 includes the secondary-side circuit module and the module described above.

In the fourth to sixth embodiments, the direction in which the signal transmitting device 10 transmits a signal may be changed in any manner. In one example, the signal transmitting device 10 may be configured in such a manner that a signal is transmitted from the secondary-side circuit 14 to the primary-side circuit 13 through the transformer 15. More specifically, when a signal (e.g., a feedback signal) from a driving circuit electrically connected to the secondary-side circuit 14 via the secondary-side terminal 12 is input to the secondary-side terminal 12, the signal is transmitted from the secondary-side circuit 14 to the primary-side circuit 13 through the transformer 15. The signal at the primary-side circuit 13 is then output to a control device electrically connected to the primary-side circuit 13 via the primary-side terminal 11. The signal transmitting device 10 may be configured in such a manner that signals are transmitted bidirectionally between the primary-side circuit 13 and the secondary-side circuit 14. In other words, the signal transmitting device 10 may include a primary-side circuit 13 and a secondary-side circuit 14 configured to perform at least one of transmission of a signal and reception of a signal with the primary-side circuit 13 through the transformer 15.

In the present disclosure, the term “on” includes the meaning of “above” in addition to the meaning of “on” unless otherwise clearly indicated in the context. Thus, the phrase “A is formed on B” is intended to mean that A may be disposed directly on B in contact with B in the embodiments and also that A may be disposed above B without contacting B in a modified example. In other words, the term “on” does not exclude a structure in which another member is formed between A and B.

The z-direction as referred to in the present disclosure does not necessarily have to be the vertical direction and does not necessarily have to be fully aligned with the vertical direction. In the structures according to the present disclosure, “upward” and “downward” in the z-direction as referred to in the present description are not limited to “upward” and “downward” in the vertical direction. In an example, the x-direction may be aligned with the vertical direction. In another example, the y-direction may be aligned with the vertical direction.

In this specification, “at least one of A and B” should be understood to mean “only A, only B, or both A and B.”

### CLAUSES

The technical aspects that are understood from the embodiments and the modified examples will be described below. To facilitate understanding without intention to limit, the reference signs of the elements in the embodiments are given to the corresponding elements in the clause with parentheses. The reference signs are used as examples to facilitate understanding, and the components in each reference sign are not limited to those components given with the reference signs.

### [Clause 1-1]

An insulated chip (50), including:
an element insulation layer (54);
a first coil (22A) embedded in the element insulation layer (54); and
a second coil (21A) embedded in the element insulation layer (54) and opposed to the first coil (22A) in a thickness-wise direction (z-direction) of the element insulation layer (54), in which
the first coil (22A) includes a first end surface (23) facing the second coil (21A) in the thickness-wise direction (z-direction) of the element insulation layer (54), a second end surface (24) located opposite to the first end surface (23), and a first side surface (25),
the element insulation layer (54) includes
   a third insulation layer (103),
   a second insulation layer (102) stacked on the third insulation layer (103) and having a higher relative permittivity than the third insulation layer (103), and
   a first insulation layer (101) stacked on the second insulation layer (102) and having a lower relative permittivity than the second insulation layer (102), and
the first coil (22A) is arranged in the first insulation layer (101) such that the first end surface (23) is in contact with the second insulation layer (102).

### [Clause 1-2]

The insulated chip according to clause 1-1, in which
the first side surface (25) has a lower end portion (25A) forming a corner with the first end surface (23), and
the second insulation layer (102) covers the lower end portion (25A).

### [Clause 1-3]

The insulated chip according to clause 1-1 or 1-2, in which the second insulation layer (102) includes
a first high permittivity film (102A) in contact with the first end surface (23), and
a second high permittivity film (102B) having a lower relative permittivity than the first high permittivity film (102A) and in contact with the third insulation layer (103).

### [Clause 1-4]

The insulated chip according to clause 1-3, in which
the second insulation layer (102) includes a third high permittivity film (102C) having a higher relative permittivity than the second high permittivity film (102B), and
the third high permittivity film (102C) is arranged on the first high permittivity film (102A).

### [Clause 1-5]

The insulated chip according to clause 1-1 or 1-2, in which the second insulation layer (102) is a single film.

### [Clause 1-6]

The insulated chip according to any one of clauses 1-1 to 1-5, in which
the first insulation layer (101) and the third insulation layer (103) are formed from a material including SiO₂, and
the second insulation layer (102) is formed from a material including at least one of SIN, SiON, and SiC.

### [Clause 1-7]

The insulated chip according to clause 1-3, in which
the first high permittivity film (102A) is formed from a material including SiN, and
the second high permittivity film (102B) is formed from a material including SiON.

### [Clause 1-8]

The insulated chip according to clause 1-4, in which
the first high permittivity film (102A) is formed from a material including SiN,
the second high permittivity film (102B) is formed from a material including SiON, and
the third high permittivity film (102C) is formed from a material including SiN.

### [Clause 1-9]

The insulated chip according to any one of clauses 1-1 to 1-8, in which the element insulation layer (54) includes
a fourth insulation layer (104) stacked on the first insulation layer (101) so as to be in contact with the second end surface (24) and having a higher relative permittivity than the first insulation layer (101), and
a fifth insulation layer (105) stacked on the fourth insulation layer (104) and having a lower relative permittivity than the fourth insulation layer (104).

### [Clause 1-10]

The insulated chip according to clause 1-9, in which
the fourth insulation layer (104) is formed from a material including SiN, and
the fifth insulation layer (105) is formed from a material including SiO₂.

### [Clause 1-11]

The insulated chip according to any one of clauses 1-1 to 1-10, in which
the second coil (21A) includes a third end surface (26) facing toward the first coil (22A) in the thickness-wise direction (z-direction) of the element insulation layer (54), a fourth end surface (27) located opposite to the third end surface (26), and a second side surface (28),
   the element insulation layer (54) includes
   a sixth insulation layer (106),
   a seventh insulation layer (107) stacked on the sixth insulation layer (106) and having a higher relative permittivity than the sixth insulation layer (106), and
   an eighth insulation layer (108) stacked on the seventh insulation layer (107) and having a lower relative permittivity than the seventh insulation layer (107), and
the second coil (21A) is arranged in the sixth insulation layer (106) such that the third end surface (26) is in contact with the seventh insulation layer (107).

### [Clause 1-12]

The insulated chip according to clause 1-11, in which the seventh insulation layer (107) includes
a fourth high permittivity film (107A) in contact with the third end surface (26), and
a fifth high permittivity film (107B) having a lower relative permittivity than the fourth high permittivity film (107A) and in contact with the eighth insulation layer (108).

### [Clause 1-13]

The insulated chip according to clause 1-12, in which
the seventh insulation layer (107) includes a sixth high permittivity film (107C) having a higher relative permittivity than the fifth high permittivity film (107B), and
the fourth high permittivity film (107A) is arranged between the fifth high permittivity film (107B) and the sixth high permittivity film (107C).

### [Clause 1-14]

The insulated chip according to clause 1-11, in which the seventh insulation layer (107) is a single film.

### [Clause 1-15]

The insulated chip according to any one of clauses 1-11 to 1-14, in which
the sixth insulation layer (106) and the eighth insulation layer (108) are formed from a material including SiO₂, and
the seventh insulation layer (107) is formed from a material including at least one of SiN, SiON, and SiC.

### [Clause 1-16]

A signal transmitting device (10), including:
a first chip (30) including a first circuit (13);
an insulated chip (50); and
a second chip (40) including a second circuit (14) configured to perform at least one of reception of a signal and transmission of a signal with the first circuit (13) through the insulation chip (50), in which
the insulated chip (50) includes
   an element insulation layer (54),
   a first coil (22A) embedded in the element insulation layer (54), and
   a second coil (21A) embedded in the element insulation layer (54) and opposed to the first coil (22A) in a thickness-wise direction (z-direction) of the element insulation layer (54),
the first coil (22A) includes a first end surface (23) facing toward the second coil (21A) in the thickness-wise direction (z-direction) of the element insulation layer (54), a second end surface (24) located opposite to the first end surface (23), and a first side surface (25),
   the element insulation layer (54) includes
   a third insulation layer (103),
   a second insulation layer (102) stacked on the third insulation layer (103) and having a higher relative permittivity than the third insulation layer (103), and
   a first insulation layer (101) stacked on the second insulation layer (102) and having a lower relative permittivity than the second insulation layer (102), and
the first coil (22A) is arranged in the first insulation layer (101) such that the first end surface (23) is in contact with the second insulation layer (102).

### [Clause 1-17]

The signal transmitting device according to clause 1-16, further including:
a first die pad (60) on which the first chip (30) is mounted; and
a second die pad (70) on which the second chip (40) is mounted,
in which the insulated chip (50) is mounted on the first die pad (60) or the second die pad (70).

### [Clause 1-18]

The signal transmitting device according to clause 1-16, further including:
a first die pad (60) on which the first chip (30) is mounted;
a second die pad (70) on which the second chip (40) is mounted; and
a third die pad (160) on which the insulated chip (50) is mounted,
in which the third die pad (160) is electrically floating with respect to the first die pad (60) and the second die pad (70).

### [Clause 1-19]

The insulated chip according to clause 1-9, in which the fourth insulation layer (104) includes
a high permittivity lower film (104A) in contact with the second end surface (24) of the first coil (22A), and
a high permittivity upper film (104B) formed on the high permittivity lower film (104A) and having a lower relative permittivity than the high permittivity lower film (104A).

### [Clause 1-20]

The insulated chip according to clause 1-19, in which
the high permittivity lower film (104A) is formed from a material including SiN, and
the high permittivity upper film (104B) is formed from a material including SiON.

### [Clause 1-21]

The insulated chip according to any one of clauses 1-11 to 1-15, in which the element insulation layer (54) includes
a ninth insulation layer (109) in contact with the fourth end surface (27) of the second coil (21A) and having a higher relative permittivity than the sixth insulation layer (106), and
a tenth insulation layer (110) located opposite to the sixth insulation layer (106) with respect to the ninth insulation layer (109) and having a lower relative permittivity than the ninth insulation layer (109).

### [Clause 1-22]

The insulated chip according to clause 1-21, in which the ninth insulation layer (109) includes
a high permittivity upper film (109A) in contact with the fourth end surface (27), and
a high permittivity lower film (109B) sandwiched between the high permittivity upper film (109A) and the tenth insulation layer (110).

### [Clause 1-23]

The insulated chip according to clause 1-22, in which
the high permittivity upper film (109A) is formed from a material including SiN, and
the high permittivity lower film (109B) is formed from a material including SiON.

### [Clause 1-24]

The signal transmitting device according to any one of clauses 1-16 to 1-18, in which
the insulated chip (50) includes
   a first transformer (18A) including the first coil (22A) and the second coil (21A), and
   a second transformer (19A) embedded in the element insulation layer (54) and including a third coil (21C) and a fourth coil (22C) opposed to each other, and
the first circuit (13) and the second circuit (14) are connected by the first transformer (18A) and the second transformer (19A) connected in series to transmit a signal through the first transformer (18A) and the second transformer (19A).

### [Clause 1-25]

The signal transmitting device according to clause 1-24, in which
the first coil (22A) is electrically connected to the third coil (21C), and
in the thickness-wise direction (z-direction) of the element insulation layer (54), the first coil (22A) is aligned with the third coil (21C).

### [Clause 1-26]

The signal transmitting device according to clause 1-25, in which in the thickness-wise direction (z-direction) of the element insulation layer (54), the second coil (21A) is aligned with the fourth coil (22C).

### [Clause 1-27]

The signal transmitting device according to any one of clauses 1-24 to 1-26, in which
the insulated chip (50) includes a substrate (53),
the element insulation layer (54) is formed on the substrate (53), and
an insulation member (150) is arranged at a side of the substrate (53) opposite to the element insulation layer (54).

### [Clause 1-28]

The signal transmitting device according to any one of clauses 1-16 to 1-18, in which
the signal transmitting device (10) is configured to transmit a signal from the first circuit (13) toward the second circuit (14) through a transformer (15A, 15B) including the first coil (22A, 22B) and the second coil (21A, 21B),
the transformer (15A, 15B) includes a first signal transformer (15A) and a second signal transformer (15B),
the signal transmitted through the transformer (15A, 15B) includes a first signal and a second signal,
the first signal is transmitted from the first circuit (13) toward the second circuit (14) through the first signal transformer (15A), and
the second signal is transmitted from the first circuit (13) toward the second circuit (14) through the second signal transformer (15B).

### [Clause 1-29]

The insulated chip according to any one of clauses 1-1 to 1-15, in which the insulated chip (50) includes
a first transformer (18A) including the first coil (22A) and the second coil (21A),
a second transformer (19A) embedded in the element insulation layer (54) and including a third coil (21C) and a fourth coil (22C) opposed to each other, and
the first transformer (18A) and the second transformer (19A) are connected in series in the element insulation layer (54).

### [Clause 1-30]

An isolation module, including:
the insulated chip (50) according to any one of clauses 1-1 to 1-15; and
a circuit chip (30/40) including a signal transmission circuit (13/14) electrically connected to the insulated chip (50).

### [Clause 1-31]

An isolation module, including:
the insulated chip (50) according to any one of clauses 1-1 to 1-15; and
an encapsulation resin that encapsulates the insulated chip.

### [Clause 2-1]

An insulated chip (50), including:
an element insulation layer (54);
a first coil (22A) embedded in the element insulation layer (54); and
a second coil (21A) embedded in the element insulation layer (54) and opposed to the first coil (22A) in a thickness-wise direction (z-direction) of the element insulation layer (54), in which
the first coil (22A) includes a first end surface (23) facing toward the second coil (21A) in the thickness-wise direction (z-direction) of the element insulation layer (54), a second end surface (24) located opposite to the first end surface (23), and a first side surface (25),
   the element insulation layer (54) includes
   a first insulation layer (101),
   a first trench (120) formed in the first insulation layer (101) and including a first trench bottom surface (122) and a first trench side surface (121), and
   a first coating layer (111) formed on the first trench bottom surface (122) and the first trench side surface (121) and having a higher relative permittivity than the first insulation layer (101), and
the first coil (22A) is arranged in the first trench (120) such that the first end surface (23) and the first side surface (25) are in contact with the first coating layer (111).

### [Clause 2-2]

The insulated chip according to clause 2-1, in which
the element insulation layer (54) includes
   a second insulation layer (102) in contact with the first insulation layer (101) and having a higher relative permittivity than the first insulation layer (101), and
   a third insulation layer (103) in contact with the second insulation layer (102) at a side opposite to the first insulation layer (101) and having a lower relative permittivity than the second insulation layer (102), and
the second insulation layer (102) includes the first trench bottom surface (122) and is in contact with the first coating layer (111).

### [Clause 2-3]

The insulated chip according to clause 2-2, in which
the second insulation layer (102) includes a first high permittivity film (102E) in contact with the third insulation layer (103), and
the first high permittivity film (102E) has a lower relative permittivity than the first coating layer (111).

### [Clause 2-4]

The insulated chip according to clause 2-3, in which
the first high permittivity film (102E) is formed from a material including SiON.

### [Clause 2-5]

The insulated chip according to clause 2-4, in which
the second insulation layer (102) includes a second high permittivity film (102F) formed on the first high permittivity film (102E) and having a higher relative permittivity than the first high permittivity film (102E), and
the second high permittivity film (102F) and the first coating layer (111) are equal in relative permittivity.

### [Clause 2-6]

The insulated chip according to clause 2-5, in which the second high permittivity film (102F) is formed from a material including SiN.

### [Clause 2-7]

The insulated chip according to any one of clauses 2-1 to 2-6, in which
the first insulation layer (101) is formed from a material including SiO₂, and
the first coating layer (111) is formed from a material including at least one of SiN,

### SiON, and SiC.

### [Clause 2-8]

The insulated chip according to any one of clauses 2-1 to 2-7, in which the element insulation layer (54) includes
a fourth insulation layer (104) stacked on the first insulation layer (101) to be in contact with the second end surface (24) and having a higher relative permittivity than the first insulation layer (101), and
a fifth insulation layer (105) stacked on the fourth insulation layer (104) and having a lower relative permittivity than the fourth insulation layer (104).

### [Clause 2-9]

The insulated chip according to any one of clauses 2-1 to 2-8, in which the first coating layer (170) includes
a first high permittivity coating film (171) in contact with the first trench bottom surface (122) and the first trench side surface (121), and
a second high permittivity coating film (172) stacked on the first high permittivity coating film (171).

### [Clause 2-10]

The insulated chip according to clause 2-9, in which the second high permittivity coating film (172) has a higher relative permittivity than the first high permittivity coating film (171).

### [Clause 2-11]

The insulated chip according to any one of clauses 2-1 to 2-10, in which
the second coil (21A) includes a third end surface (26) facing toward the first coil (22A) in the thickness-wise direction (z-direction) of the element insulation layer (54), a fourth end surface (27) located opposite to the third end surface (26), and a second side surface (28),
   the element insulation layer (54) includes
   a sixth insulation layer (106),
   a second trench (130) formed in the sixth insulation layer (106) and including a second trench bottom surface (132) and a second trench side surface (131), and
   a second coating layer (112) formed on the second trench bottom surface (132) and the second trench side surface (131) and having a higher relative permittivity than the first insulation layer (106), and
the second coil (21A) is arranged in the second trench (130) such that the fourth end surface (27) and the second side surface (28) are in contact with the second coating layer (112).

### [Clause 2-12]

The insulated chip according to clause 2-11, in which
the element insulation layer (54) includes a seventh insulation layer (107) in contact with the sixth insulation layer (106) and having a higher relative permittivity than the sixth insulation layer (106), and
the seventh insulation layer (107) is in contact with the second coating layer (112).

### [Clause 2-13]

The insulated chip according to clause 2-12, in which the seventh insulation layer (107) has a lower relative permittivity than the second coating layer (112).

### [Clause 2-14]

The insulated chip according to clause 2-12 or 2-13, in which the element insulation layer (54) includes an eighth insulation layer (108) stacked on the seventh insulation layer (107) and having a lower relative permittivity than the seventh insulation layer (107).

### [Clause 2-15]

The insulated chip according to any one of clauses 2-1 to 2-14, in which
the element insulation layer (54) includes an element head surface (54s) and an element back surface (54r) located opposite to the element head surface (54s),
the first coil (22A) is disposed closer to the element head surface (54s) than the second coil (21A), and
the element insulation layer (54) is partially disposed between the first coil (22A) and the second coil (21A).

### [Clause 2-16]

The insulated chip according to clause 2-15, further including:
a substrate (53) formed on the element back surface (54r), in which
the first coil is a high-voltage coil (22A), and
the second coil is a low-voltage coil (21A).

### [Clause 2-17]

A signal transmitting device (10), including:
a first chip (30) including a first circuit (13);
an insulated chip (50); and
a second chip (40) including a second circuit (14) configured to perform at least one of reception of a signal and transmission of a signal with the first circuit (13) through the insulation chip (50), in which
the insulated chip (50) includes
   an element insulation layer (54),
   a first coil (22A) embedded in the element insulation layer (54), and
   a second coil (21A) embedded in the element insulation layer (54) and opposed to the first coil (22A) in a thickness-wise direction (z-direction) of the element insulation layer (54),
the first coil (22A) includes a first end surface (23) facing toward the second coil (21A) in the thickness-wise direction (z-direction) of the element insulation layer (54), a second end surface (24) located opposite to the first end surface (23), and a first side surface (25),
   the element insulation layer (54) includes
   a first insulation layer (101),
   a first trench (120) formed in the first insulation layer (101) and including a first trench bottom surface (122) and a first trench side surface (121), and
   a first coating layer (111) formed on the first trench bottom surface (122) and the first trench side surface (121) and having a higher relative permittivity than the first insulation layer (101), and
the first coil (22A) is arranged in the first trench (120) such that the first end surface (23) and the first side surface (25) are in contact with the first coating layer (111).

### [Clause 2-18]

The signal transmitting device according to clause 2-17, further including:
a first die pad (60) on which the first chip (30) is mounted; and
a second die pad (70) on which the second chip (40) is mounted,
in which the insulated chip (50) is mounted on the first die pad (60) or the second die pad (70).

### [Clause 2-19]

The signal transmitting device according to clause 2-17, further including:
a first die pad (60) on which the first chip (30) is mounted;
a second die pad (70) on which the second chip (40) is mounted; and
a third die pad (160) on which the insulated chip (50) is mounted, in which
the third die pad (160) is electrically floating with respect to the first die pad (60) and the second die pad (70).

### [Clause 2-20]

The insulated chip according to clause 2-8, in which the fourth insulation layer (104) includes
a high permittivity lower film (104C) in contact with the second end surface (24) of the first coil (22A), and
a high permittivity upper film (104D) formed on the high permittivity lower film (104C) and having a lower relative permittivity than the high permittivity lower film (104C).
   [Clause 2-21] The insulated chip according to clause 2-20, in which
the high permittivity lower film (104C) is formed from a material including SiN, and
the high permittivity upper film (104D) is formed from a material including SiON.

### [Clause 2-22]

The insulated chip according to any one of clauses 2-12 to 2-14, in which the element insulation layer (54) includes
a ninth insulation layer (109) in contact with the fourth end surface (27) of the second coil (21A) and having a higher relative permittivity than the sixth insulation layer (106), and
a tenth insulation layer (110) located opposite to the sixth insulation layer (106) with respect to the ninth insulation layer (109) and having a lower relative permittivity than the ninth insulation layer (109).

### [Clause 2-23]

The insulated chip according to clause 2-22, in which the ninth insulation layer (109) includes
a high permittivity upper film (109E) in contact with the fourth end surface (27), and
a high permittivity lower film (109D) sandwiched between the high permittivity upper film (109E) and the tenth insulation layer (110).

### [Clause 2-24]

The insulated chip according to clause 2-23, in which
the high permittivity upper film (109E) is formed from a material including SiN, and
the high permittivity lower film (109D) is formed from a material including SiON.

### [Clause 2-25]

The signal transmitting device according to any one of clauses 2-17 to 2-19, in which
the insulated chip (50) includes
   a first transformer (18A) including the first coil (22A) and the second coil (21A), and
   a second transformer (19A) embedded in the element insulation layer (54) and including a third coil (21C) and a fourth coil (22C) opposed to each other, and
the first circuit (13) and the second circuit (14) are connected by the first transformer (18A) and the second transformer (19A) connected in series to transmit a signal through the first transformer (18A) and the second transformer (19A).

### [Clause 2-26]

The signal transmitting device according to clause 2-25, in which
the first coil (22A) is electrically connected to the third coil (21C), and
in the thickness-wise direction (z-direction) of the element insulation layer (54), the first coil (22A) is aligned with the third coil (21C).

### [Clause 2-27]

The signal transmitting device according to clause 2-26, in which in the thickness-wise direction (z-direction) of the element insulation layer (54), the second coil (21A) is aligned with the fourth coil (22C).

### [Clause 2-28]

The signal transmitting device according to any one of clauses 2-25 to 2-27, in which
the insulated chip (50) includes a substrate (53),
the element insulation layer (54) is formed on the substrate (53), and
an insulation member (150) is arranged at a side of the substrate (53) opposite to the element insulation layer (54).

### [Clause 2-29]

The signal transmitting device according to any one of clauses 2-17 to 2-19, in which
the signal transmitting device (10) is configured to transmit a signal from the first circuit (13) toward the second circuit (14) through a transformer (15A, 15B) including the first coil (22A, 22B) and the second coil (21A, 21B),
the transformer (15A, 15B) includes a first signal transformer (15A) and a second signal transformer (15B),
the signal transmitted through the transformer (15A, 15B) includes a first signal and a second signal,
the first signal is transmitted from the first circuit (13) toward the second circuit (14) through the first signal transformer (15A), and
the second signal is transmitted from the first circuit (13) toward the second circuit (14) through the second signal transformer (15B).

### [Clause 2-30]

The insulated chip according to any one of clauses 2-1 to 2-16, in which
the insulated chip (50) includes
   a first transformer (18A) including the first coil (22A) and the second coil (21A), and
   a second transformer (19A) embedded in the element insulation layer (54) and including a third coil (21C) and a fourth coil (22C) opposed to each other, and
the first transformer (18A) and the second transformer (19A) are connected in series in the element insulation layer (54).

### [Clause 2-31]

An isolation module, including:
the insulated chip (50) according to any one of clauses 2-1 to 2-16; and
a circuit chip (30/40) including a signal transmission circuit (13/14) electrically connected to the insulated chip (50).

### [Clause 2-32]

An isolation module, including:
the insulated chip (50) according to any one of clauses 2-1 to 2-16; and
an encapsulation resin that encapsulates the insulated chip.

The description above illustrates examples. One skilled in the art may recognize further possible combinations and replacements of the elements and methods (manufacturing processes) in addition to those listed for purposes of describing the techniques of the present disclosure. The present disclosure is intended to include any substitute, modification, changes included in the scope of the disclosure including the claims and the clauses.

1. An insulated chip, comprising:
an element insulation layer;
a first coil embedded in the element insulation layer; and
a second coil embedded in the element insulation layer and opposed to the first coil in a thickness-wise direction of the element insulation layer, wherein
the first coil includes
a first end surface facing the second coil in the thickness-wise direction of the element insulation layer,
a second end surface located opposite to the first end surface, and
a first side surface,
the element insulation layer includes
a third insulation layer,
a second insulation layer stacked on the third insulation layer and having a higher relative permittivity than the third insulation layer, and
a first insulation layer stacked on the second insulation layer and having a lower relative permittivity than the second insulation layer, and
the first coil is arranged in the first insulation layer such that the first end surface is in contact with the second insulation layer.

2. The insulated chip according to claim 1, wherein
the first side surface has a lower end portion forming a corner with the first end surface, and
the second insulation layer covers the lower end portion.

3. The insulated chip according to claim 1, wherein the second insulation layer includes
a first high permittivity film in contact with the first end surface, and
a second high permittivity film having a lower relative permittivity than the first high permittivity film and in contact with the third insulation layer.

4. The insulated chip according to claim 3, wherein
the second insulation layer includes a third high permittivity film having a higher relative permittivity than the second high permittivity film, and
the third high permittivity film is arranged on the first high permittivity film.

5. The insulated chip according to claim 1, wherein the second insulation layer is a single film.

6. The insulated chip according to claim 1, wherein
the first insulation layer and the third insulation layer are formed from a material including SiO₂, and
the second insulation layer is formed from a material including at least one of SiN, SiON, and SiC.

7. The insulated chip according to claim 3, wherein
the first high permittivity film is formed from a material including SiN, and
the second high permittivity film is formed from a material including SiON.

8. The insulated chip according to claim 4, wherein
the first high permittivity film is formed from a material including SiN,
the second high permittivity film is formed from a material including SiON, and
the third high permittivity film is formed from a material including SiN.

9. The insulated chip according to claim 1, wherein the element insulation layer includes
a fourth insulation layer stacked on the first insulation layer so as to be in contact with the second end surface and having a higher relative permittivity than the first insulation layer, and
a fifth insulation layer stacked on the fourth insulation layer and having a lower relative permittivity than the fourth insulation layer.

10. The insulated chip according to claim 9, wherein
the fourth insulation layer is formed from a material including SiN, and
the fifth insulation layer is formed from a material including SiO₂.

11. The insulated chip according to claim 1, wherein
the second coil includes a third end surface facing toward the first coil in the thickness-wise direction of the element insulation layer, a fourth end surface located opposite to the third end surface, and a second side surface,
the element insulation layer includes
a sixth insulation layer,
a seventh insulation layer stacked on the sixth insulation layer and having a higher relative permittivity than the sixth insulation layer, and
an eighth insulation layer stacked on the seventh insulation layer and having a lower relative permittivity than the seventh insulation layer, and
the second coil is arranged in the sixth insulation layer such that the third end surface is in contact with the seventh insulation layer.

12. The insulated chip according to claim 11, wherein the seventh insulation layer includes
a fourth high permittivity film in contact with the third end surface, and
a fifth high permittivity film having a lower relative permittivity than the fourth high permittivity film and in contact with the eighth insulation layer.

13. The insulated chip according to claim 12, wherein
the seventh insulation layer includes a sixth high permittivity film having a higher relative permittivity than the fifth high permittivity film, and
the fourth high permittivity film is arranged between the fifth high permittivity film and the sixth high permittivity film.

14. The insulated chip according to claim 11, wherein the seventh insulation layer is a single film.

15. The insulated chip according to claim 11, wherein
the sixth insulation layer and the eighth insulation layer are formed from a material including SiO₂, and
the seventh insulation layer is formed from a material including at least one of SiN, SiON, and SiC.

16. A signal transmitting device, comprising:
a first chip including a first circuit;
an insulated chip; and
a second chip including a second circuit configured to perform at least one of reception of a signal and transmission of a signal with the first circuit through the insulation chip, wherein
the insulated chip includes
an element insulation layer,
a first coil embedded in the element insulation layer, and
a second coil embedded in the element insulation layer and opposed to the first coil in a thickness-wise direction of the element insulation layer,
the first coil includes a first end surface facing toward the second coil in the thickness-wise direction of the element insulation layer, a second end surface located opposite to the first end surface, and a first side surface,
the element insulation layer includes
a third insulation layer,
a second insulation layer stacked on the third insulation layer and having a higher relative permittivity than the third insulation layer, and
a first insulation layer stacked on the second insulation layer and having a lower relative permittivity than the second insulation layer, and
the first coil is arranged in the first insulation layer such that the first end surface is in contact with the second insulation layer.

17. The signal transmitting device according to claim 16, further comprising:
a first die pad on which the first chip is mounted; and
a second die pad on which the second chip is mounted,
wherein the insulated chip is mounted on the first die pad or the second die pad.

18. The signal transmitting device according to claim 16, further comprising:
a first die pad on which the first chip is mounted;
a second die pad on which the second chip is mounted; and
a third die pad on which the insulated chip is mounted,
wherein the third die pad is electrically floating with respect to the first die pad and the second die pad.
